(19) United States
(12) Patent Application Publication
(10) Pub. No.: US 2025/0361339 A1
(43) Pub. Date: Nov. 27, 2025

(54) PHOTO-ALIGNMENT POLYMER, BINDER COMPOSITION, BINDER LAYER, OPTICAL LAMINATE, OPTICAL LAMINATE MANUFACTURING METHOD, AND IMAGE DISPLAY DEVICE

(71) Applicant: FUJIFILM Corporation, Tokyo (JP)

(72) Inventors: Takashi IIZUMI, Kanagawa (JP); Akio TAMURA, Kanagawa (JP); Tomonori MIMURA, Kanagawa (JP)

(73) Assignee: FUJIFILM Corporation, Tokyo (JP)

(21) Appl. No.: 19/287,184

(22) Filed: Jul. 31, 2025

Related U.S. Application Data
(63) Continuation of application No. PCT/JP2024/009566, filed on Mar. 12, 2024.

(30) Foreign Application Priority Data
Mar. 13, 2023 (JP) 2023-038302
May 19, 2023 (JP) 2023-083433

(51) Int. Cl. C08F 16/36

(52) U.S. Cl. CPC C08F 16/36

(57) ABSTRACT

A photo-alignment polymer, a binder composition, a binder layer, an optical laminate, an optical laminate manufacturing method, and an image display device, in which the liquid crystal alignment properties of an optically-anisotropic layer provided on an upper layer can be improved. The photo-alignment polymer including a repeating unit A having a photo-aligned group, and a repeating unit B, in which the repeating unit B is a repeating unit represented by Formula (1) or a repeating unit having a polymer chain including the repeating unit represented by Formula (1).

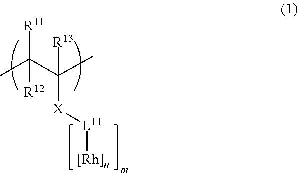

### CROSS-REFERENCE TO RELATED APPLICATIONS

This application is a Continuation of PCT International Application No. PCT/JP2024/009566 filed on Mar. 12, 2024, which was published under PCT Article 21(2) in Japanese, and which claims priority under 35 U.S.C. § 119(a) to Japanese Patent Application No. 2023-038302 filed on Mar. 13, 2023 and Japanese Patent Application No. 2023-083433 filed on May 19, 2023. The above applications are hereby expressly incorporated by reference, in their entirety, into the present application.

### BACKGROUND OF THE INVENTION

### 1. Field of the Invention

The present invention relates to a photo-alignment polymer, a binder composition, a binder layer, an optical laminate, an optical laminate manufacturing method, and an image display device.

### 2. Description of the Related Art

Optical films such as an optical compensation sheet and a phase difference film are used in various image display devices from the viewpoints of image coloration elimination, viewing angle expansion, and the like.

A stretched birefringence film has been used as an optical film, but in recent years, it has been proposed to use an optically-anisotropic layer formed of a liquid crystal compound in place of the stretched birefringence film.

In a case of forming such an optically-anisotropic layer, a photo-alignment film obtained by subjecting a photo-alignment polymer to a photo-alignment treatment may be used in order to align a liquid crystal compound.

As the photo-alignment polymer, “a polymer represented by the following structural formula (1)” is described in KR10-2022-0039405A.

### SUMMARY OF THE INVENTION

In recent years, in an optically-anisotropic layer formed of a liquid crystal compound, further improvement of aligning properties of the liquid crystal compound (hereinafter, also referred to as “liquid crystal alignment properties”) is required.

As a result of studying the photo-alignment polymer described in KR10-2022-0039405A, the present inventors have found that further improvement is required in the liquid crystal alignment properties of the optically-anisotropic layer provided on the upper layer of the layer formed of the photo-alignment polymer in order to satisfy the recent higher level of requirements.

Therefore, an object of the present invention is to provide a photo-alignment polymer, a binder composition, a binder layer, an optical laminate, an optical laminate manufacturing method, and an image display device, which can improve the liquid crystal alignment properties of an optically-anisotropic layer provided in an upper layer.

The present inventors have found that the above-described objects can be achieved by the following configurations.

[1]

A photo-alignment polymer including a repeating unit A having a photo-aligned group, and a repeating unit B, in which the repeating unit B is a repeating unit represented by Formula (1) described later or a repeating unit having a polymer chain including the repeating unit represented by Formula (1) described later.

[2]

The photo-alignment polymer according to [1], in which L¹¹ is a hydrocarbon group having 1 to 20 carbon atoms or a linking group selected from Formulae (B1) to (B6) described later.

[3]

The photo-alignment polymer according to [1] or [2], in which the repeating unit A is a repeating unit represented by Formula (A) described later.

[4]

The photo-alignment polymer according to [3], in which L^{A1} represents a single bond or a divalent linking group selected from a cyclic alkylene group having 3 to 10 carbon atoms, which may have a substituent, a divalent heterocyclic group, —O—, —S—, —N(Q)-, —CO—, and a group obtained by combining these groups, where Q represents a hydrogen atom or a substituent.

[5]

The photo-alignment polymer according to any one of [1] to [4], further including a repeating unit represented by Formula (C) described later.

[6]

A photo-alignment polymer including a repeating unit represented by Formula (A) described later or a repeating unit represented by Formula (AK2).

[7]

The photo-alignment polymer according to any one of [1] to [6], in which a weight-average molecular weight of the photo-alignment polymer is 10,000 to 500,000.

[8]

A binder composition including the photo-alignment polymer according to any one of [1] to [7], and a binder.

[9]

The binder composition according to [8], in which the binder is a polymerizable liquid crystal compound.

[10]

A binder layer formed of the binder composition according to [8] or [9], in which a surface of the binder layer has an alignment controllability.

[11]

An optical laminate including the binder layer according to [10], and an optically-anisotropic layer disposed on the binder layer.

[12]

An optical laminate manufacturing method including a step of subjecting a coating film formed of the binder composition according to claim 8 to a photo-alignment treatment to form a binder layer, and a step of applying a polymerizable liquid crystal composition containing a polymerizable liquid crystal compound onto the binder layer to form an optically-anisotropic layer.

[13]

An image display device including the binder layer according to [10].

According to the present invention, it is possible to provide a photo-alignment polymer, a binder composition, a binder layer, an optical laminate, an optical laminate manufacturing method, and an image display device, in which the liquid crystal alignment properties of an optically-anisotropic layer provided in an upper layer can be improved.

### DESCRIPTION OF THE PREFERRED EMBODIMENTS

Hereinafter, the present invention will be described in detail.

The following description of configuration requirements is based on typical embodiments of the present invention, but the present invention is not limited thereto.

In the present specification, the numerical value range indicated by “to” means a range including numerical values before and after “to” as a lower limit value and an upper limit value, respectively.

In the present specification, as various components, one kind of substance corresponding to various components may be used alone, or two or more kinds thereof may be used in combination. Here, in a case where two or more substances are used in combination for various components, the content of the components means the total content of the substances used in combination, unless otherwise specified.

In addition, the bonding direction of a divalent group (for example, —O—CO—) described in this specification is not particularly limited, and for example, in a case where L² in a “L¹-L²-L³” bond is —O—CO—, and a bonding position on the L¹ side is represented by *1 and a bonding position on the L³ side is represented by *2, L² may be *1-O—CO-*2 or *1-CO—O—*2.

The compounds described in the present specification may include isomers unless otherwise specified. The isomers may be any of structural isomers, geometrical isomers, or optical isomers that each of the compounds can have. In addition, in a case where only a specific isomer of a compound is shown, it indicates that the specific isomer is preferable among isomers that the compound can have.

In the present specification, (meth)acryl includes the concepts of both acrylic and methacrylic.

In the present specification, Re(λ) and Rth(λ) represent an in-plane retardation and a thickness direction retardation at a wavelength k, respectively. Unless otherwise specified, the wavelength λ refers to 550 nm.

In addition, in this specification, Re(λ) and Rth(λ) are values measured at a wavelength λ using AxoScan OPMF-1 (manufactured by OPTO SCIENCE, Inc.).

Specifically, by inputting an average refractive index ((nx+ny+nz)/3) and a film thickness (d (μm)) in AxoScan OPMG-1, a slow axis direction (°), Re (λ)=R0 (λ), and Rth (λ)=((nx+ny)/2−nz)×d are calculated.

In addition, R0(λ) is expressed in a numerical value calculated with AxoScan OPMF-1, and means Re(λ).

### [Photo-Alignment Polymer]

The photo-alignment polymer of the present invention is a photo-alignment copolymer including a repeating unit A having a photo-aligned group and a repeating unit B.

In addition, in the photo-alignment polymer according to the present invention, the repeating unit B is a repeating unit represented by Formula (1) or a repeating unit (hereinafter, also referred to as a “repeating unit BP”) having a polymer chain including the repeating unit represented by Formula (1) (hereinafter, also referred to as a “polymer chain B”).

In addition, the photo-alignment polymer according to the present invention is a photo-alignment polymer including a repeating unit (A) or (AK2) described later.

In a case where the photo-alignment polymer according to the present invention is used, the liquid crystal alignment properties are improved. A reason for this is not clear in detail, but is presumed to be as follows by the present inventors.

First, in the binder layer obtained by applying a composition (for example, a binder composition) containing the photo-alignment polymer according to the present invention and subjecting the composition to a photo-alignment treatment, the photo-alignment polymer according to the present invention is likely to be localized on the air interface side of the binder layer due to the two or more groups represented by Formula (S) in the photo-alignment polymer according to the present invention, and the photo-alignment polymer according to the present invention has alignment controllability due to the photo-aligned group included in the repeating unit A at the air interface. Therefore, it is presumed that the liquid crystal alignment properties of the optically-anisotropic layer provided on the binder layer are excellent.

### [Repeating Unit A]

The photo-alignment polymer of the present invention includes a repeating unit A having a photo-aligned group.

Here, the photo-aligned group refers to a group having a photo-alignment function in which rearrangement or an anisotropic chemical reaction is induced by irradiation with light having anisotropy (for example, plane-polarized light), and from the viewpoint of excellent alignment uniformity and improved thermal stability and chemical stability, a photo-aligned group in which at least one of dimerization or isomerization is caused by an action of light is preferable.

Examples of the photo-aligned group to be dimerized by the action of light include a group having a skeleton of at least one derivative selected from the group consisting of a cinnamic acid derivative, a coumarin derivative, a chalcone derivative, a maleimide derivative, and a benzophenone derivative.

Examples of the photo-aligned group that is isomerized by the action of light include a group having a skeleton of at least one compound selected from the group consisting of an azobenzene compound, a stilbene compound, a spiropyran compound, a cinnamic acid compound, and a hydrazono-β-ketoester compound.

As the photo-aligned group, a group having a skeleton of at least one derivative selected from the group consisting of cinnamic acid derivatives, coumarin derivatives, chalcone derivatives, and maleimide derivatives, or a group having a skeleton of at least one compound selected from the group consisting of azobenzene compounds, stilbene compounds, and spiropyran compounds is preferable, and a group having a skeleton of a cinnamic acid derivative or a coumarin derivative is more preferable.

Examples of the structure of the main chain of the repeating unit A having a photo-aligned group include known structures.

Among these, as the structure of the main chain of the repeating unit A having a photo-aligned group, a skeleton selected from the group consisting of a (meth)acrylic skeleton, a styrene skeleton, a siloxane skeleton, a cycloolefin skeleton, a methylpentene skeleton, an amide skeleton, and an aromatic ester skeleton is preferable, a skeleton selected from the group consisting of a (meth)acrylic skeleton, a siloxane skeleton, and a cycloolefin skeleton is more preferable, and a (meth)acrylic skeleton is still more preferable.

From the viewpoint of further improving the liquid crystal alignment properties, the repeating unit A is preferably a repeating unit represented by Formula (A) or Formula (AK2) and more preferably a repeating unit represented by Formula (A).

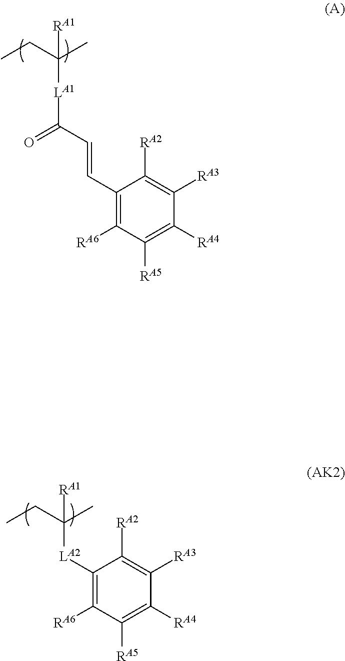

In Formula (A) and Formula (AK2), R^{A1} represents a hydrogen atom or a substituent.

L^{A1} and L^{A2} each independently represent a single bond or a divalent linking group.

R^{A2}, R^{A3}, R^{A4}, R^{A5}, and R^{A6} each independently represent a hydrogen atom or a substituent. Two adjacent groups of R^{A2}, R^{A3}, R^{A4}, R^{A5}, and R^{A6} may be bonded to each other to form a ring.

However, at least one of R^{A2}, . . . , or R^{A6} in Formula (AK2) represents —CH═CH—CO—O—R^{A7} or —CH═CH—CO—NH—R^{A7}. R^{A7} represents a substituent.

The type of the substituent represented by one aspect of R^{A1} is not particularly limited, and examples thereof include known substituents (monovalent substituents).

Examples of the substituent represented by one aspect of R^{A1} include a monovalent aliphatic hydrocarbon group and a monovalent aromatic hydrocarbon group, and more specific examples thereof include an alkyl group, an alkenyl group, an alkynyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, an aromatic heterocyclic thio group, a sulfonyl group, a sulfinyl group, a ureido group, a phosphoric acid amide group, a hydroxy group, a mercapto group, a halogen atom, a cyano group, a sulfo group, a carboxyl group, a nitro group, a hydroxamic acid group, a sulfino group, a hydrazino group, an imino group, a heterocyclic group (such as a heteroaryl group), a silyl group, and a group obtained by combining these groups. Furthermore, the substituent may be further substituted with the above-described substituent.

Among these, as the substituent represented by one aspect of R^{A1}, an alkyl group having 1 to 6 carbon atoms is preferable, and a methyl group is more preferable.

Examples of the divalent linking group represented by one aspect of L^{A1} and L^{A2} include a divalent hydrocarbon group which may have a substituent, a divalent heterocyclic group which may have a substituent, —O—, —S—, —N(Q)-, —CO—, and a group formed by combination of these groups. Q represents a hydrogen atom or a substituent.

The divalent hydrocarbon group may be linear, branched, or cyclic.

Examples of the divalent hydrocarbon group include a divalent aliphatic hydrocarbon group such as an alkylene group having 1 to 10 carbon atoms (preferably 1 to 5 carbon atoms), an alkenylene group having 1 to 10 carbon atoms, or an alkynylene group having 1 to 10 carbon atoms, and a divalent aromatic hydrocarbon group such as an arylene group.

Examples of the divalent heterocyclic group include divalent alicyclic heterocyclic groups such as an oxolane-diyl group, an oxane-diyl group, a piperidine-diyl group, and a piperazine-diyl group; and divalent aromatic heterocyclic groups such as a pyridylene group (pyridine-diyl group), a pyridazine-diyl group, an imidazole-diyl group, a thienylene group (thiophene-diyl group), and a quinolylene group (quinoline-diyl group). The number of carbon atoms in the divalent heterocyclic group is preferably 1 to 12.

In addition, examples of the group obtained by combining these groups include a group obtained by combining at least two or more selected from the group consisting of a divalent hydrocarbon group which may have a substituent, a divalent heterocyclic group which may have a substituent, —O—, —S—, —N(Q) (Q represents a hydrogen atom or a substituent), and —CO—, which are described above, and specific examples thereof include —(COO-divalent hydrocarbon group)ₚ-O— (p represents an integer of 1 or more), —CO—NH-divalent hydrocarbon group-O—, —COO-divalent hydrocarbon group-NH—, —COO-divalent heterocyclic group-, —CO-divalent heterocyclic group-, —COO-divalent hydrocarbon group-divalent heterocyclic group-, —CO-divalent heterocyclic group-divalent hydrocarbon group-O—, —CO—NH-divalent hydrocarbon group-divalent heterocyclic group-, —CO-divalent heterocyclic group-divalent hydrocarbon group-NH—, and -divalent hydrocarbon group-O—.

Here, examples of the substituent that the alkylene group and the arylene group may have and the substituent represented by Q include a halogen atom, an alkyl group, an alkoxy group, an aryl group, an aryloxy group, a cyano group, a carboxy group, an alkoxycarbonyl group, and a hydroxyl group.

Among these, as L^{A1} and L^{A2}, from the viewpoint of further improving the liquid crystal alignment properties, a divalent linking group obtained by combining at least two (preferably 2 to 6) groups selected from the group consisting of a linear alkylene group having 1 to 10 carbon atoms which may have a substituent, a branched alkylene group having 3 to 10 carbon atoms which may have a substituent, a cyclic alkylene group having 3 to 10 carbon atoms which may have a substituent, a divalent aliphatic heterocyclic group which may have a substituent, an arylene group having 6 to 12 carbon atoms which may have a substituent, —O—, —CO—, and —N(Q)— is preferable, and a divalent linking group obtained by combining at least two (preferably 2 to 6) groups selected from the group consisting of a cyclic alkylene group having 3 to 10 carbon atoms which may have a substituent, a divalent aliphatic heterocyclic group which may have a substituent, an arylene group having 6 to 12 carbon atoms which may have a substituent, —O—, —CO—, and —N(Q)- is more preferable. Q represents a hydrogen atom or a substituent.

In addition, from the viewpoint of further improving the liquid crystal alignment properties, L^{A1} and L^{A} are also preferably a single bond or a divalent linking group selected from a cyclic alkylene group having 3 to 10 carbon atoms, which may have a substituent, a divalent heterocyclic group, —O—, —S—, —N(Q)-, —CO—, and a group formed by combination of these.

In addition, L^{A2} is also preferably a divalent linking group which does not include —CO—CH═CH—.

Examples of the substituent represented by one aspect of R^{A2}, R^{A3}, R^{A4}, R^{A5}, and R^{A6} include known substituents, and examples thereof include the groups exemplified as the substituent represented by one aspect of R^{A1}.

However, at least one of R^{A2}, . . . , or R^{A6} in Formula (AK2) represents —CH═CH—CO—O—R^{A7} or —CH═CH—CO—NH—R^{A7}. R^{A7} represents a substituent.

As the substituent of R^{A7}, a hydrogen atom, an alkyl group having 1 to 18 carbon atoms, or a phenyl group is preferable. In addition, as the substituent of R^{A7}, -L¹¹-(Rh)ₙ is also preferable. L¹¹, Rh, and n will be described later.

From the reason that the liquid crystal alignment properties are further improved, the substituent represented by one aspect of R^{A2}, R^{A3}, R^{A4}, R^{A5}, and R^{A6} is preferably each independently a halogen atom, a linear alkyl group having 1 to 20 carbon atoms (preferably 1 to 6 carbon atoms), a branched or cyclic alkyl group having 3 to 20 carbon atoms (preferably 3 to 6 carbon atoms), a linear halogenated alkyl group having 1 to 20 carbon atoms (preferably 1 to 12 carbon atoms), an alkoxy group having 1 to 20 carbon atoms (preferably 3 to 18 carbon atoms), an aryl group having 6 to 20 carbon atoms (preferably 6 to 12 carbon atoms), an aryloxy group having 6 to 20 carbon atoms (preferably 6 to 12 carbon atoms), a hydroxy group, a cyano group, an amino group, or an —O—CO-hydrocarbon group (as the hydrocarbon group, an alkyl group having 1 to 20 carbon atoms is preferable). Further, the substituent may contain a linking group represented by —(CH₂)ₙₐ— or —O—(CH₂)ₙₐ—. na represents an integer of 1 to 10.

Examples of the halogen atom include a fluorine atom, a chlorine atom, a bromine atom, and an iodine atom, and the fluorine atom or the chlorine atom is preferable.

An alkyl group having 1 to 6 carbon atoms is preferable as the linear alkyl group having 1 to 20 carbon atoms, and examples thereof include a methyl group, an ethyl group, and an n-propyl group.

An alkyl group having 3 to 6 carbon atoms is preferable as the branched chain-like alkyl group having 3 to 20 carbon atoms, and examples thereof include an isopropyl group and a tert-butyl group.

As the cyclic alkyl group, an alkyl group having 3 to 6 carbon atoms is preferable, and examples thereof include a cyclopropyl group, a cyclopentyl group, and a cyclohexyl group.

As the linear alkyl halide group having 1 to 20 carbon atoms, a fluoroalkyl group having 1 to 4 carbon atoms is preferable, and examples thereof include a trifluoromethyl group, a perfluoroethyl group, a perfluoropropyl group, and a perfluorobutyl group, and a trifluoromethyl group is preferable.

As the alkoxy group having 1 to 20 carbon atoms, an alkoxy group having 1 to 18 carbon atoms is preferable, an alkoxy group having 3 to 18 carbon atoms is more preferable, and an alkoxy group having 6 to 18 carbon atoms is still more preferable. Examples of the alkoxy group having 1 to 20 carbon atoms include a methoxy group, an ethoxy group, an n-butoxy group, a methoxyethoxy group, an n-hexyloxy group, an n-octyloxy group, an n-decyloxy group, an n-dodecyloxy group, and an n-tetradecyloxy group.

As the aryl group having 6 to 20 carbon atoms, an aryl group having 6 to 12 carbon atoms is preferable, and examples thereof include a phenyl group, an α-methylphenyl group, and a naphthyl group.

An aryloxy group having 6 to 12 carbon atoms is preferable as the aryloxy group having 6 to 20 carbon atoms, and examples thereof include a phenyloxy group and a 2-naphthyloxy group.

Examples of the amino group include primary amino groups (—NH₂); secondary amino groups such as a methylamino group; tertiary amino groups such as a dimethylamino group, a diethylamino group, a dibenzylamino group, and a group having a nitrogen atom of a nitrogen-containing heterocyclic compound (for example, pyrrolidine, piperidine, and piperazine) as a bond.

From the reason that the photo-aligned group easily interacts with the liquid crystal compound and the liquid crystal alignment properties are improved, it is preferable that at least R^{A4} among R^{A2}, R^{A3}, R^{A4}, R^{A5}, and R^{A6} in Formula (A) represents the above-described substituent (preferably an alkoxy group having 1 to 20 carbon atoms), and from the reason that the linearity of the obtained photo-alignment polymer is improved, the liquid crystal compound easily interacts, and the liquid crystal alignment properties are further improved, it is more preferable that all of R^{A2}, R^{A3}, R^{A5}, and R^{A6} represent a hydrogen atom.

In addition, the photo-alignment polymer according to the embodiment of the present invention may have a surface-segregating group. Examples of the surface-segregating group include a substituent having two or more groups represented by Formula (S) described later. By having such a surface-segregating group, the surface segregation of the photo-alignment polymer can be improved, and the liquid crystal alignment properties can be improved.

Furthermore, it is also preferable that a structure (preferably a cleavable group) that reacts with light, heat, or acid and is cleaved (decomposed) is provided between the substituent having a group represented by two or more of Formula (S) described later and the polymer main chain. The photo-alignment polymer having such a structure can improve the upper layer coating property.

As the photo-alignment polymer having a cleavable group and a surface-segregating group, a photo-alignment polymer in which at least one (preferably one to three) of R^{A} to R^{A6} in Formula (A) is a substituent having -L¹¹-(Rh)ₙ is preferable. In addition, in Formula (AK2), it is preferable that at least one (preferably one to three) of R^{A} to R^{A6} is a substituent having —CH═CH—CO—O-L¹¹-(Rh)ₙ or —CH═CH—CO—NH-L¹¹-(Rh)ₙ, where the substituent is a photo-alignment polymer.

L¹¹ represents a single bond or an (n+1)-valent linking group. The preferred structure of L¹¹ is the same as that of L¹¹ in Formula (1) described later. However, in a case where there are a plurality of L¹¹'s, the plurality of L¹¹'s may be the same as or different from each other.

Rh represents a substituent having two or more groups represented by Formula (S). The preferred structure of Rh is the same as that of Rhin Formula (1) described later. However, in a case where there are a plurality of Rh's, the plurality of Rh's may be the same as or different from each other.

n represents an integer of 1 to 4.

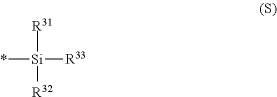

In Formula (S), * represents a bonding position.

R³¹, R³², and R³³ each independently represent an alkyl group, an alkenyl group, an aryl group, or an alkylene aryl group.

However, in the substituent represented by Rh, a plurality of R³¹'s may be the same or different from each other, a plurality of R³²'s may be the same as or different from each other, and a plurality of R³³'s may be the same as or different from each other.

Examples of the repeating unit A having a photo-aligned group include the following repeating units. TMS represents a trimethylsilyl group. Me represents a methyl group.

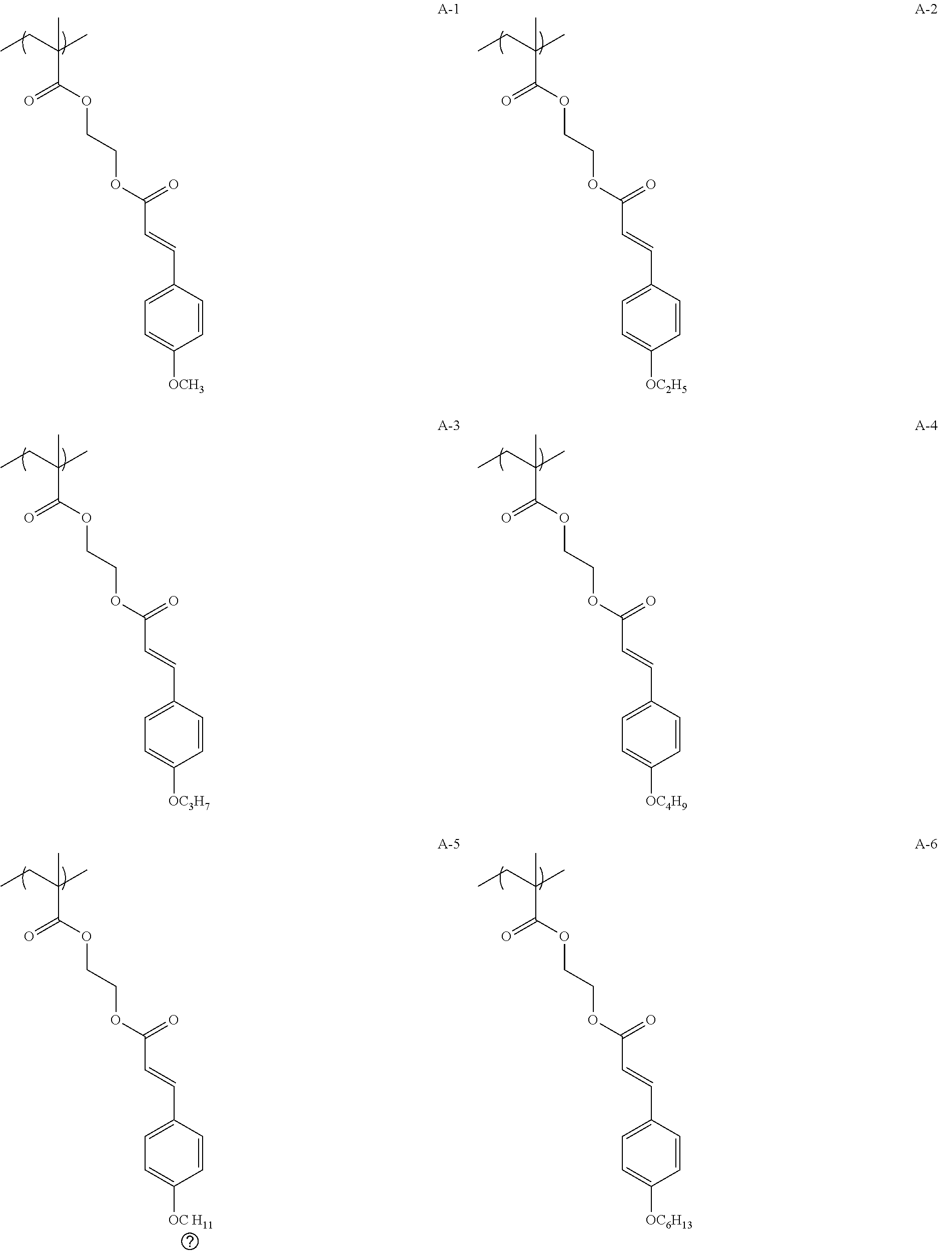

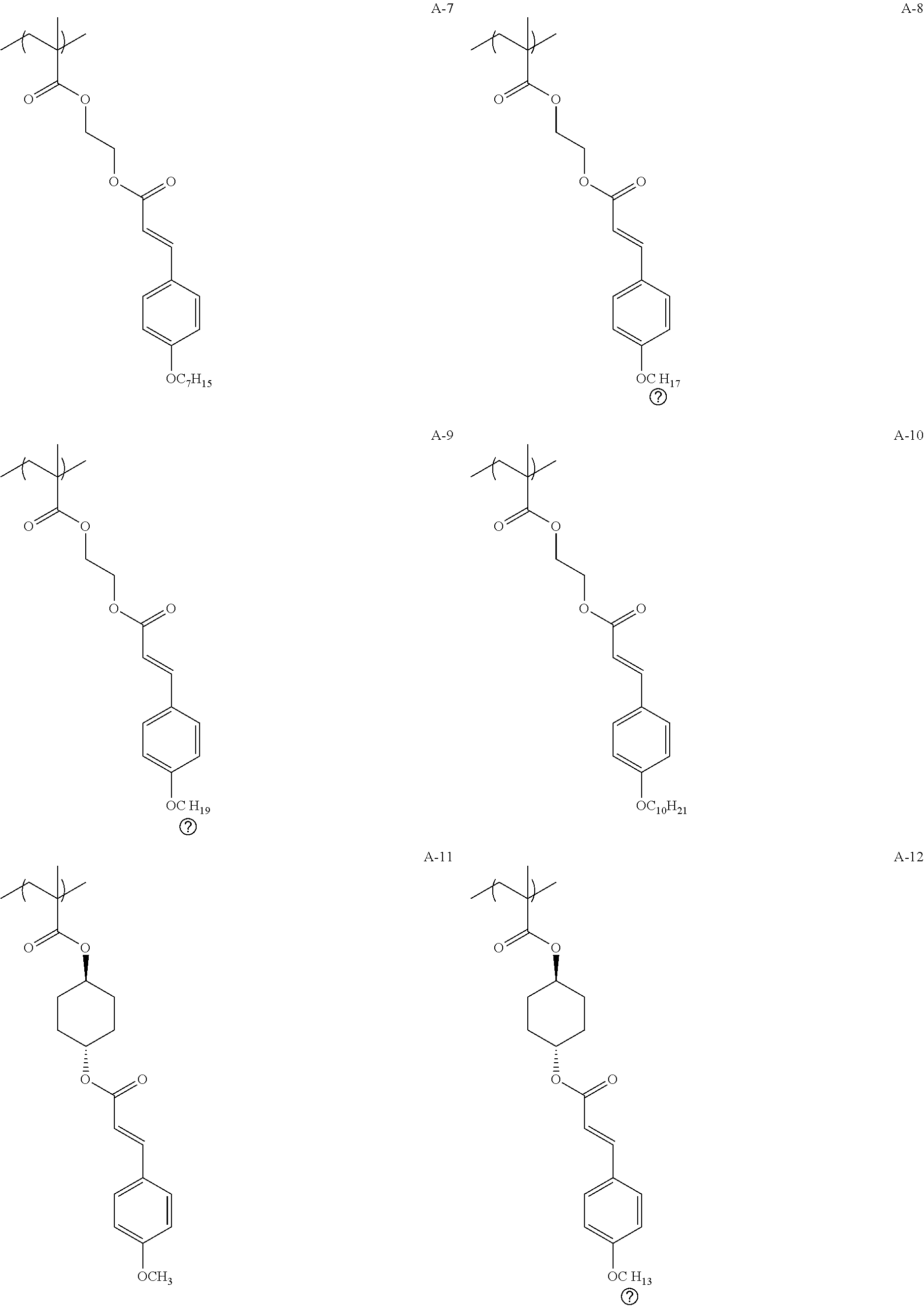

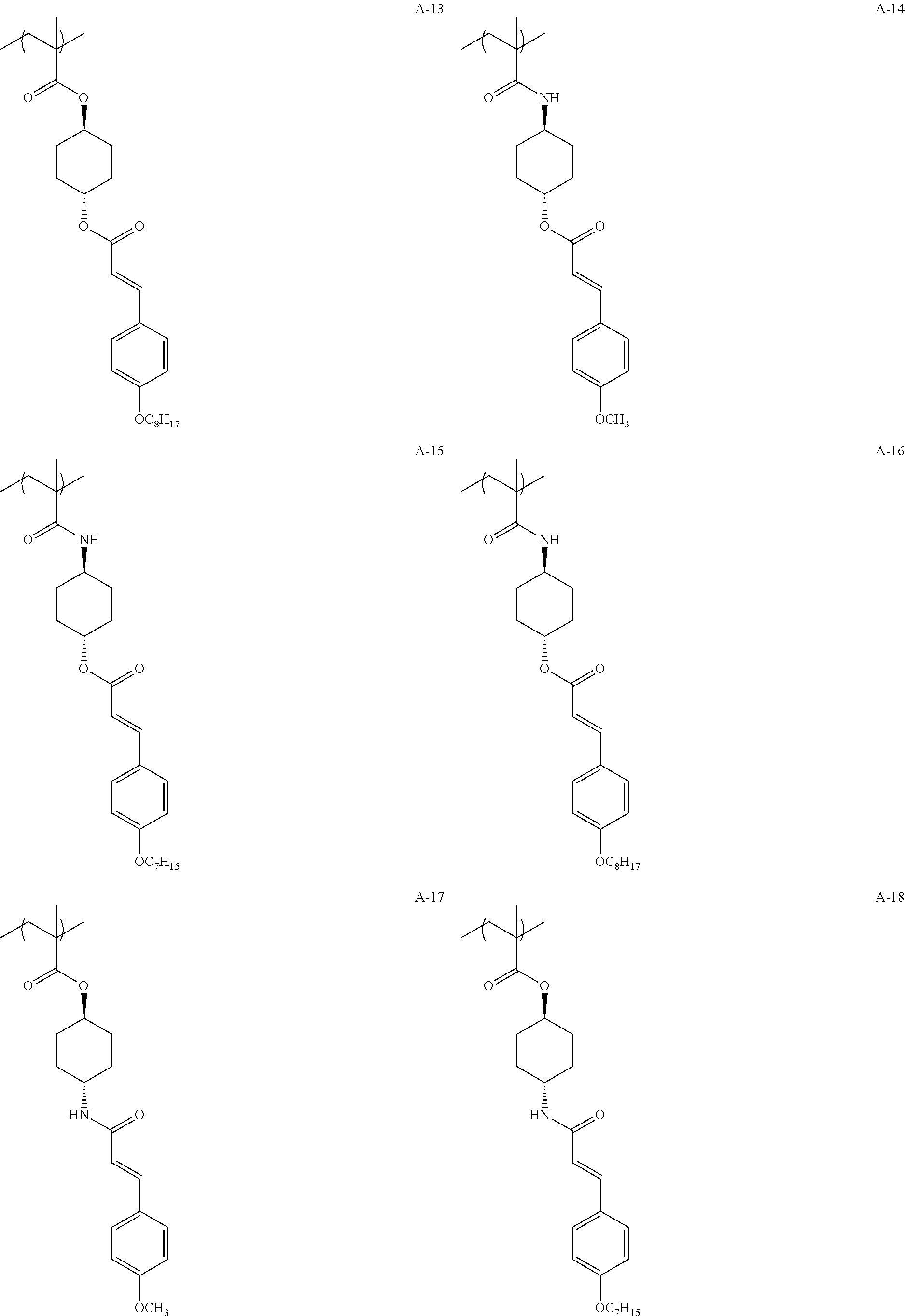

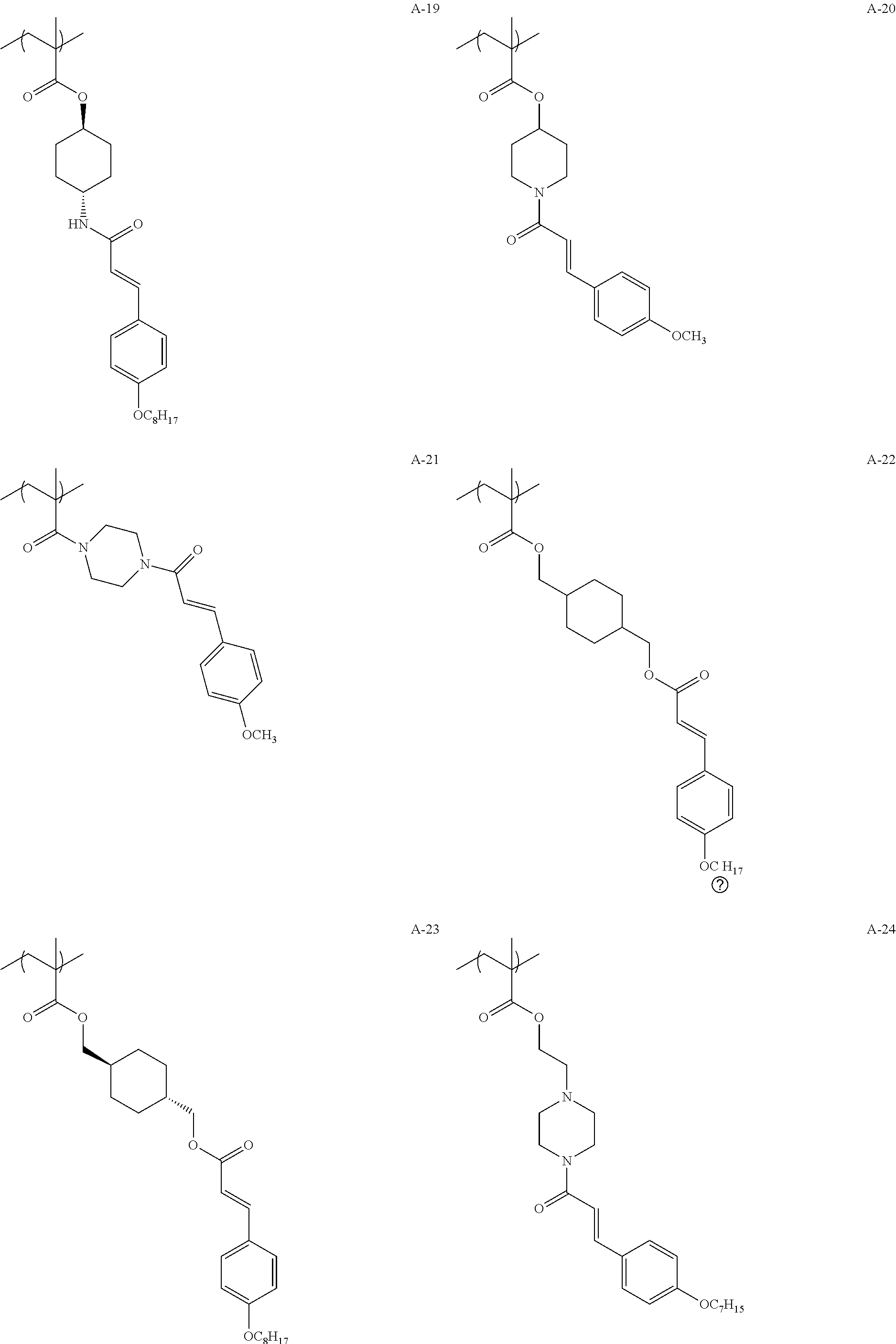

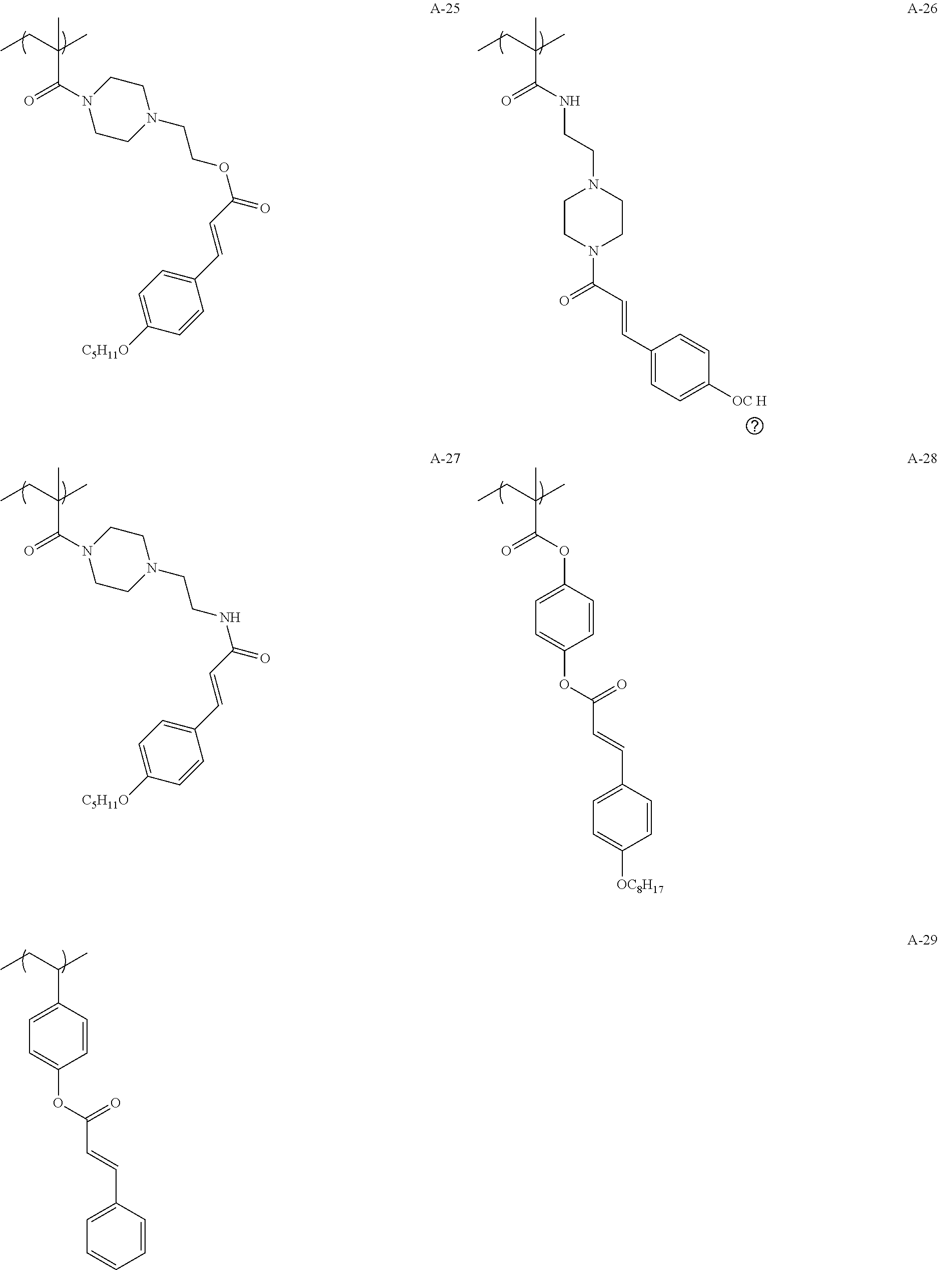

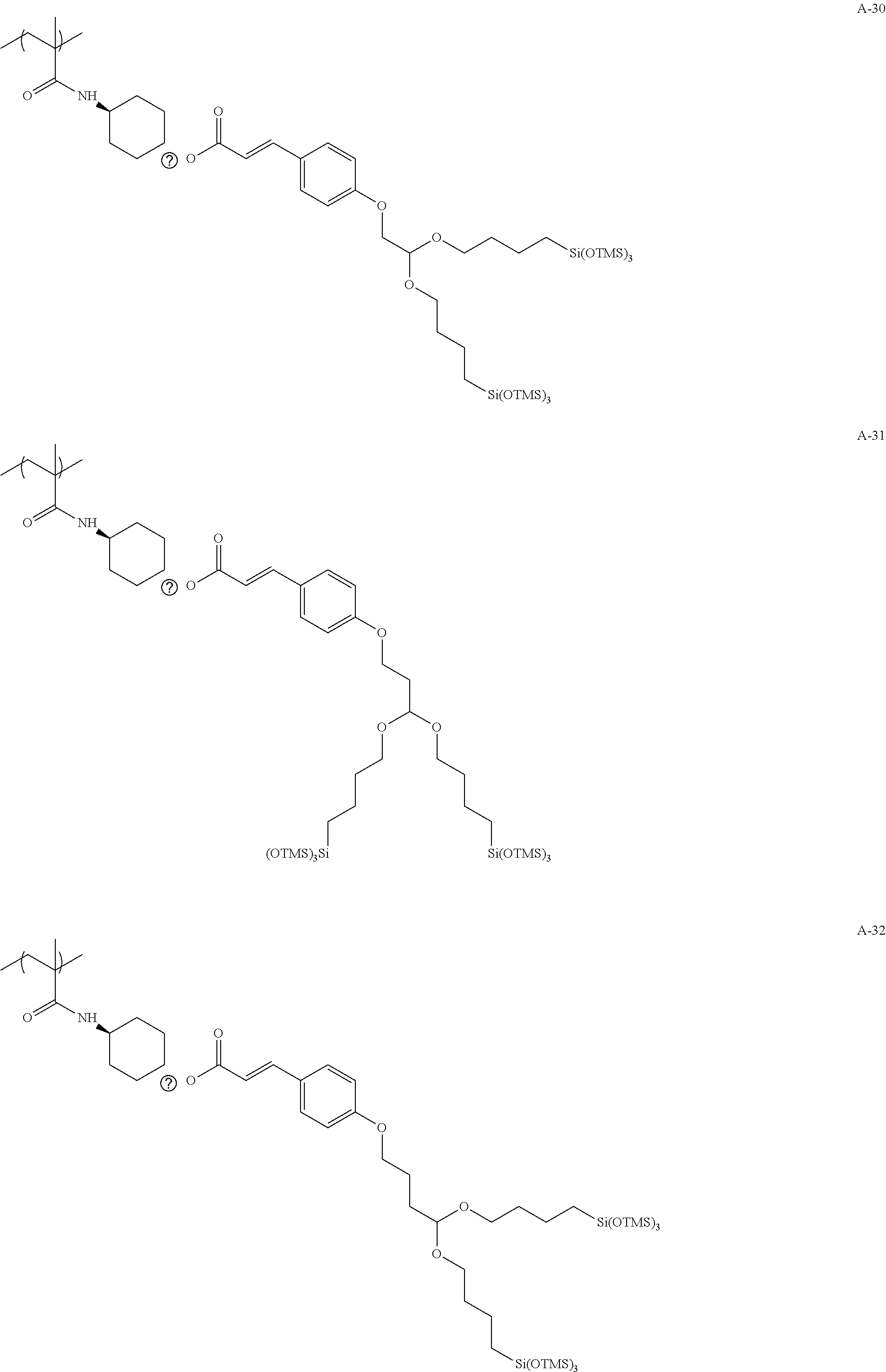

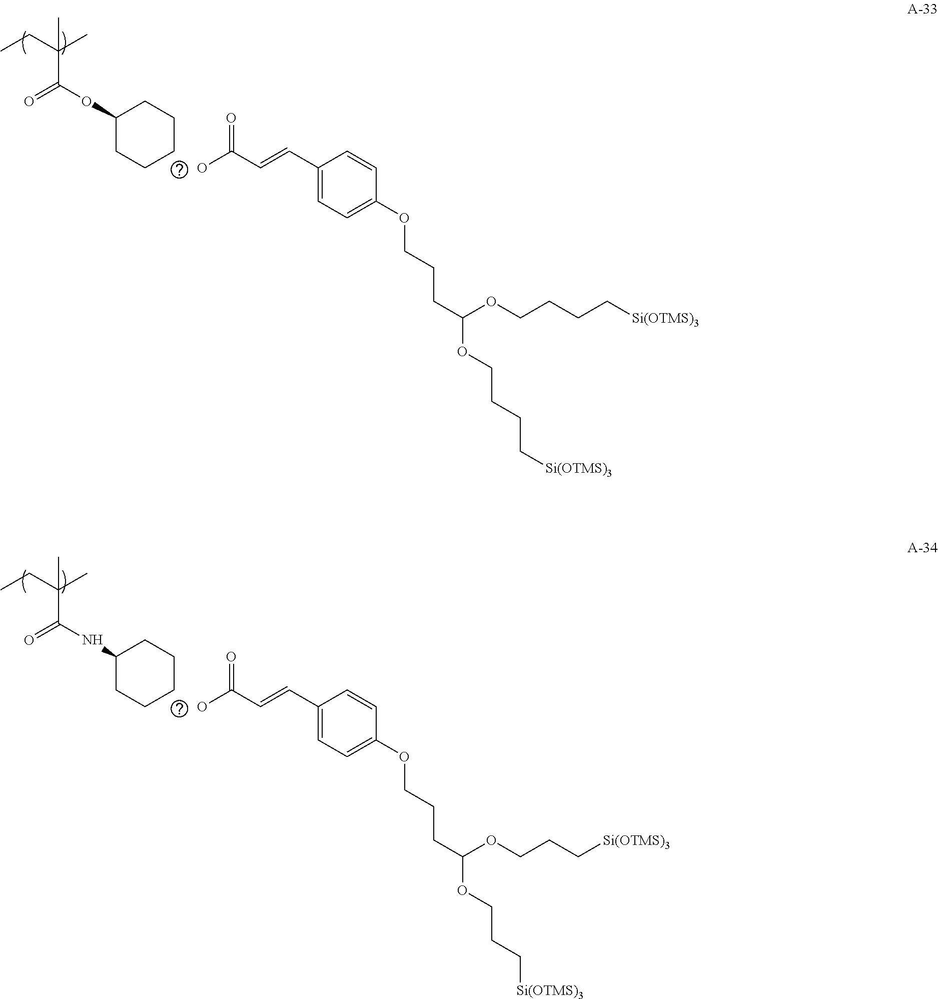

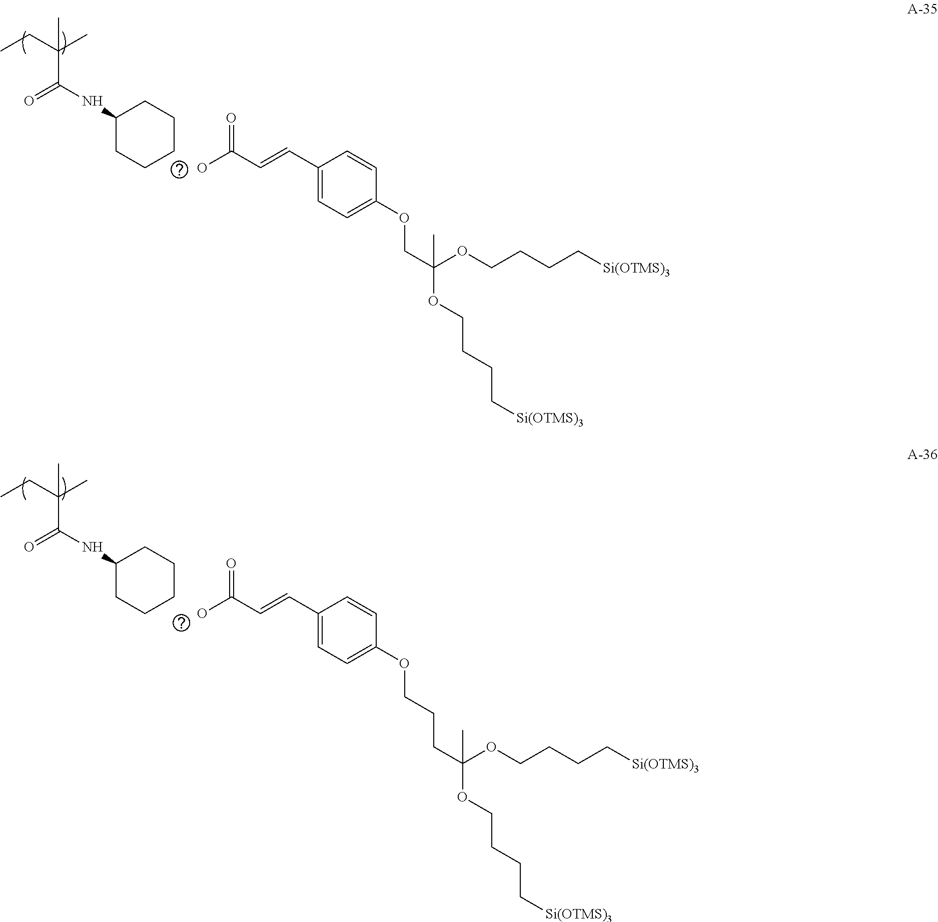

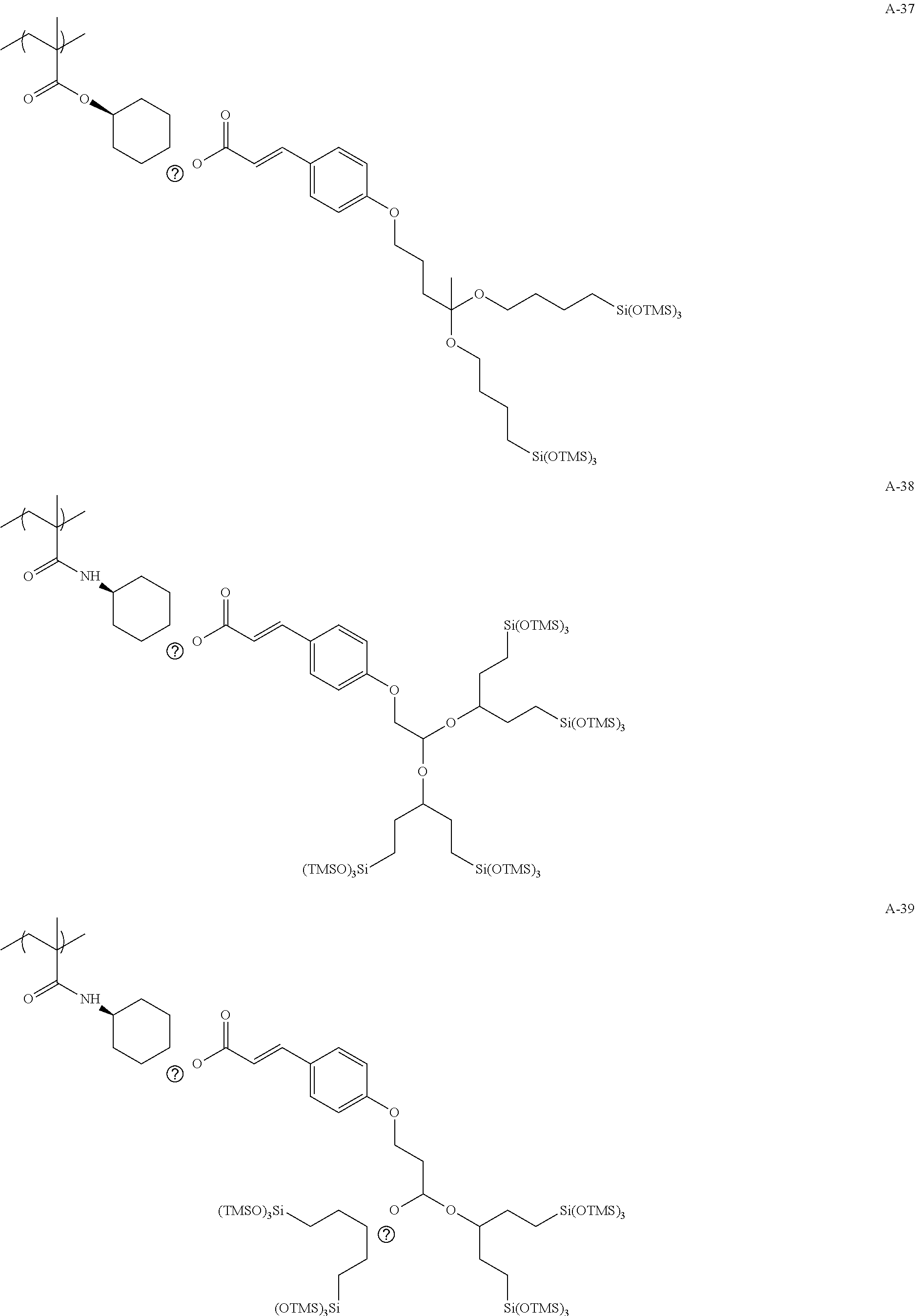

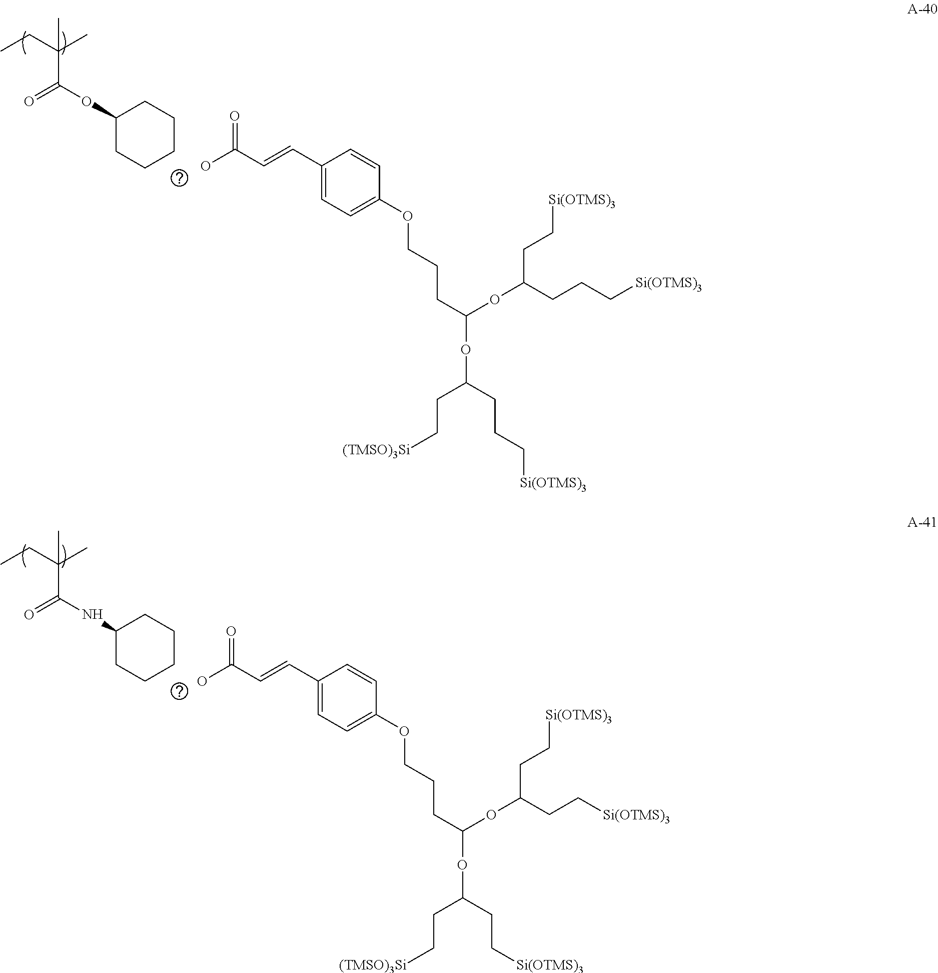

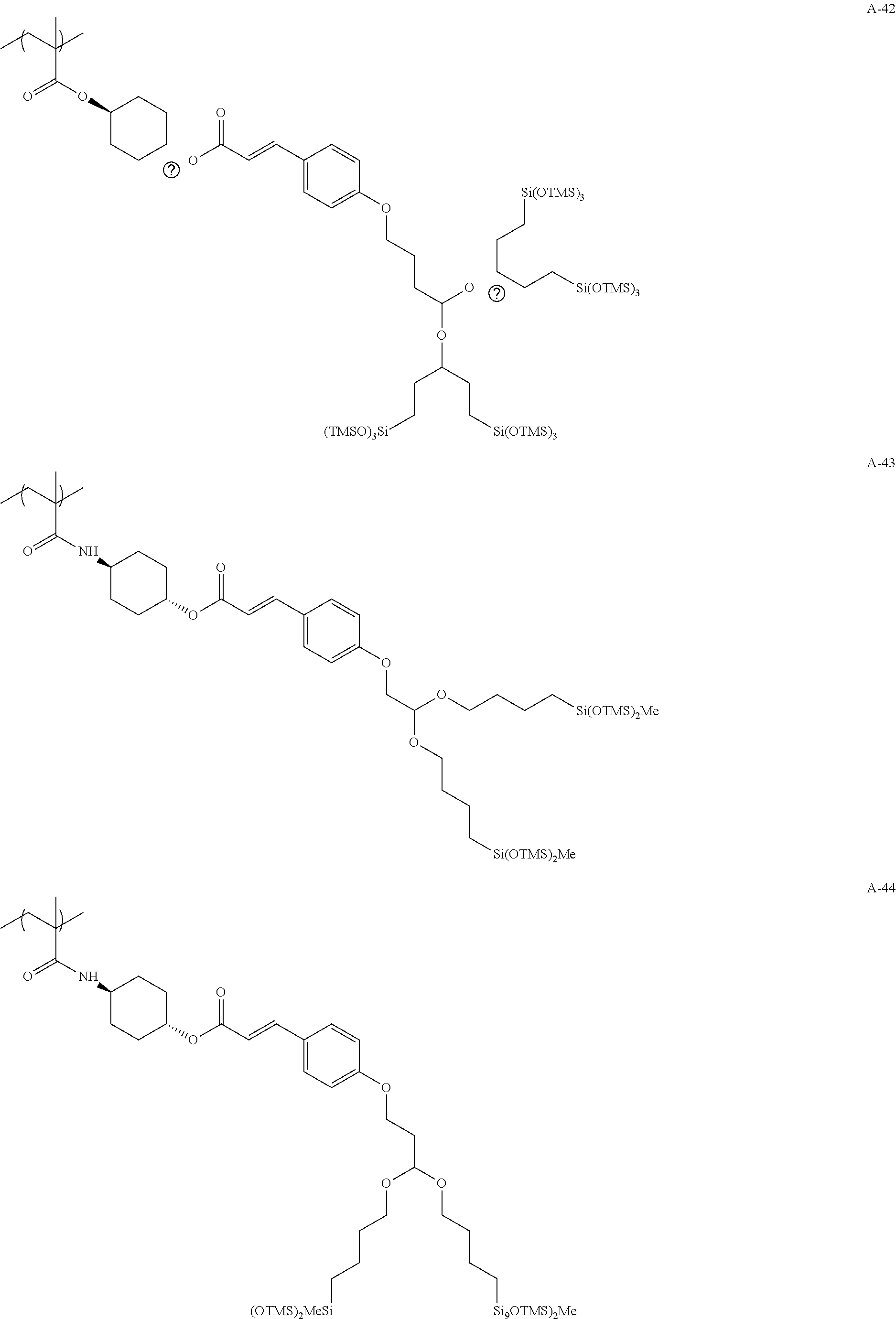

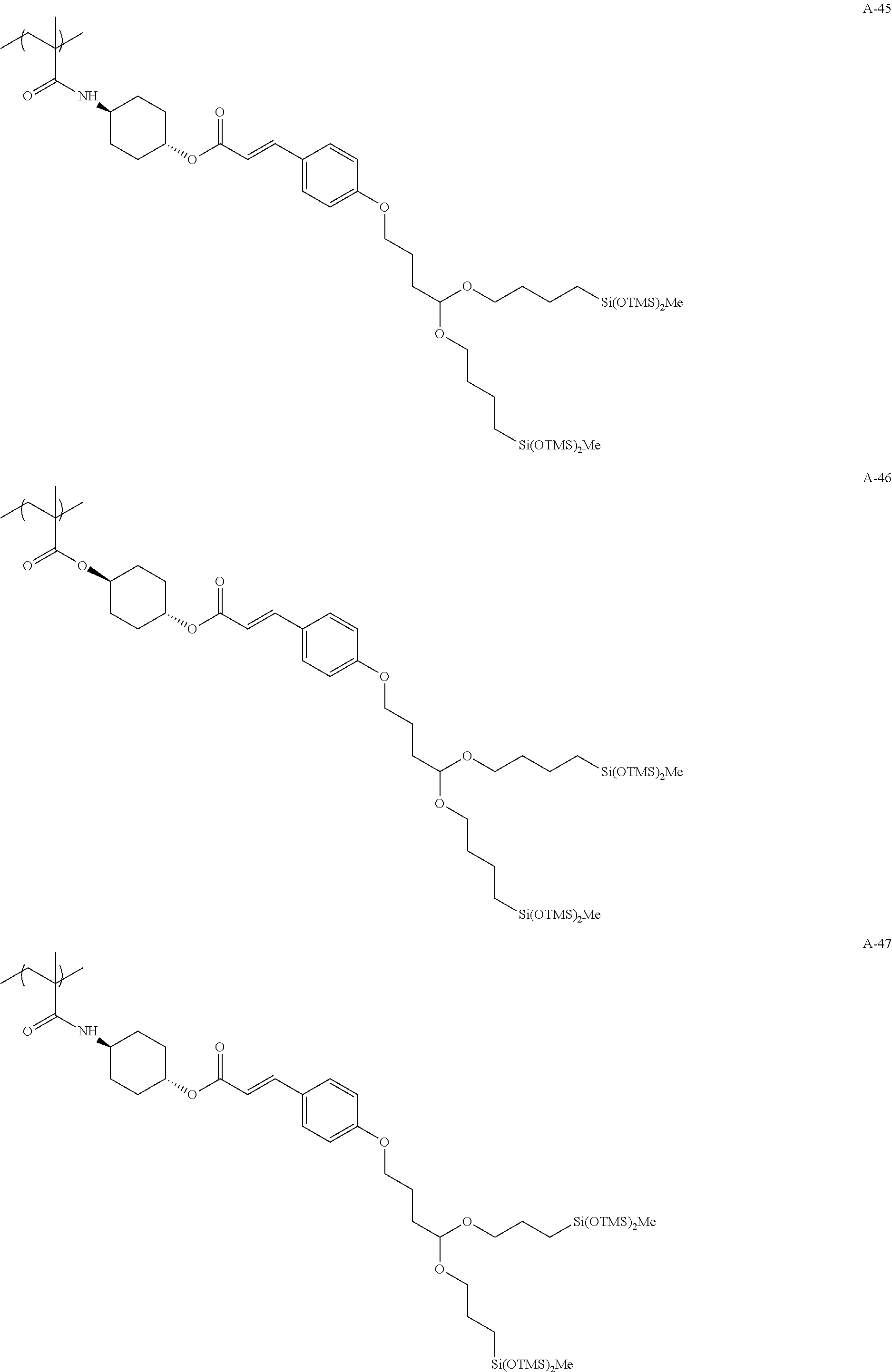

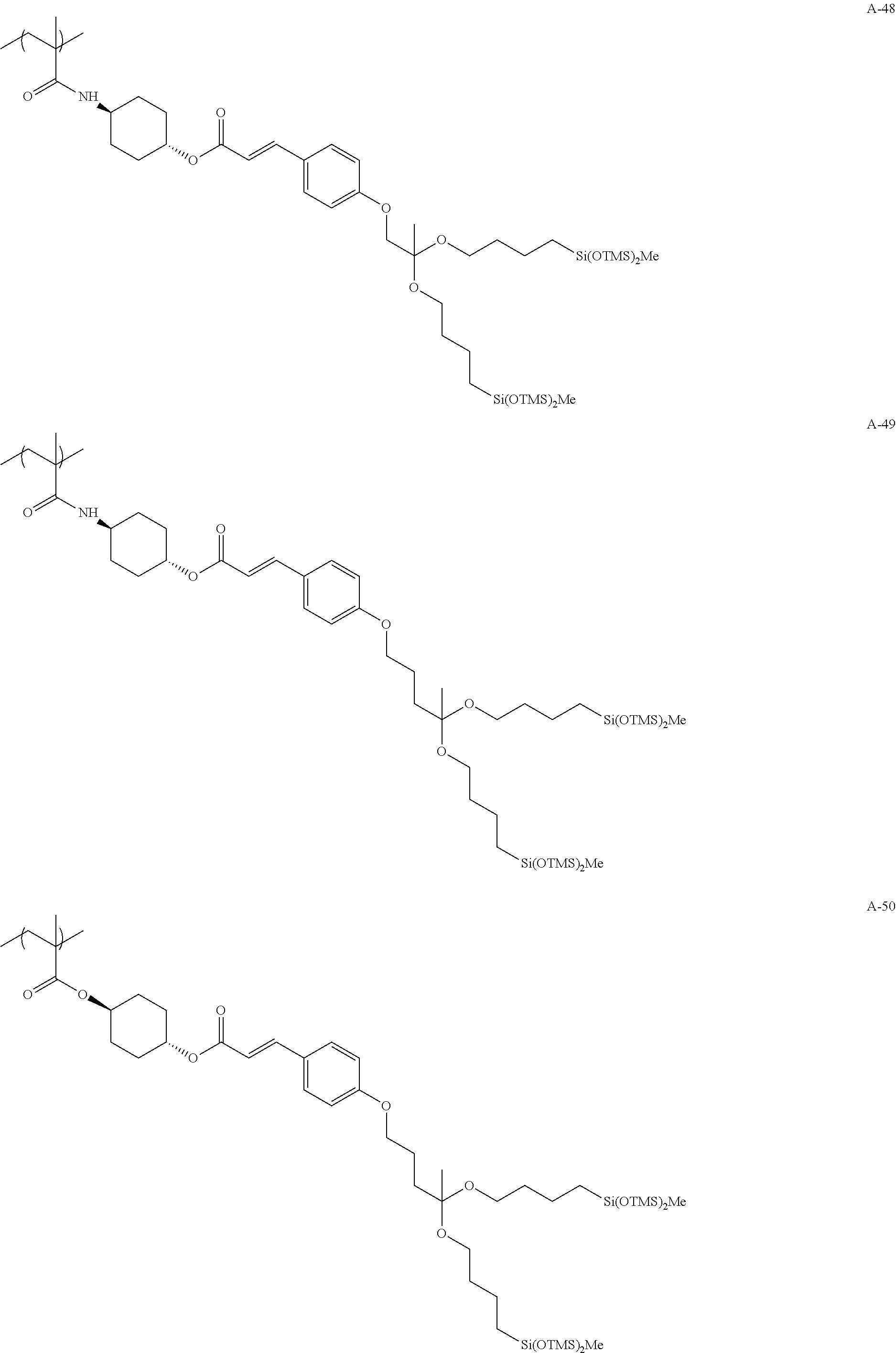

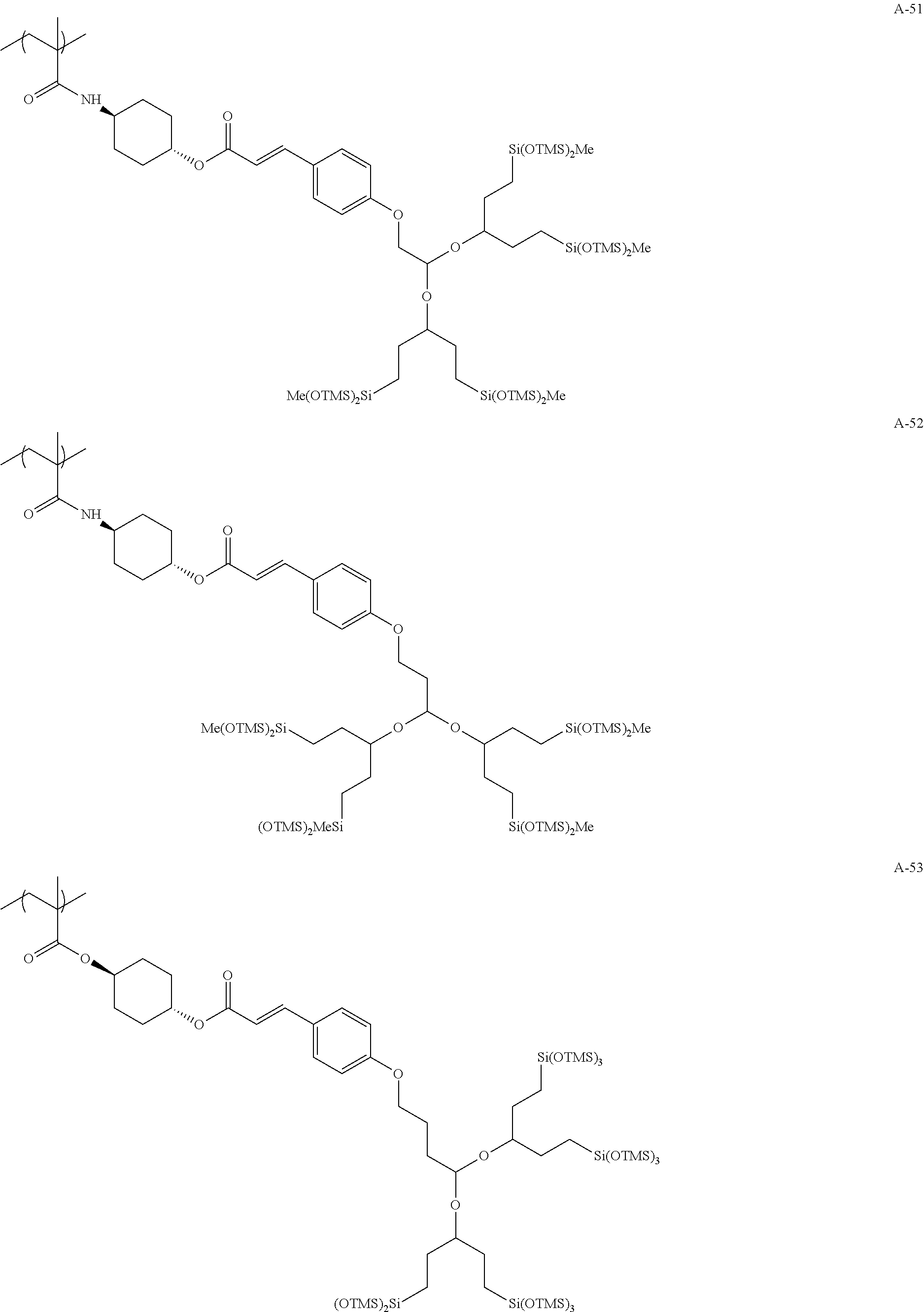

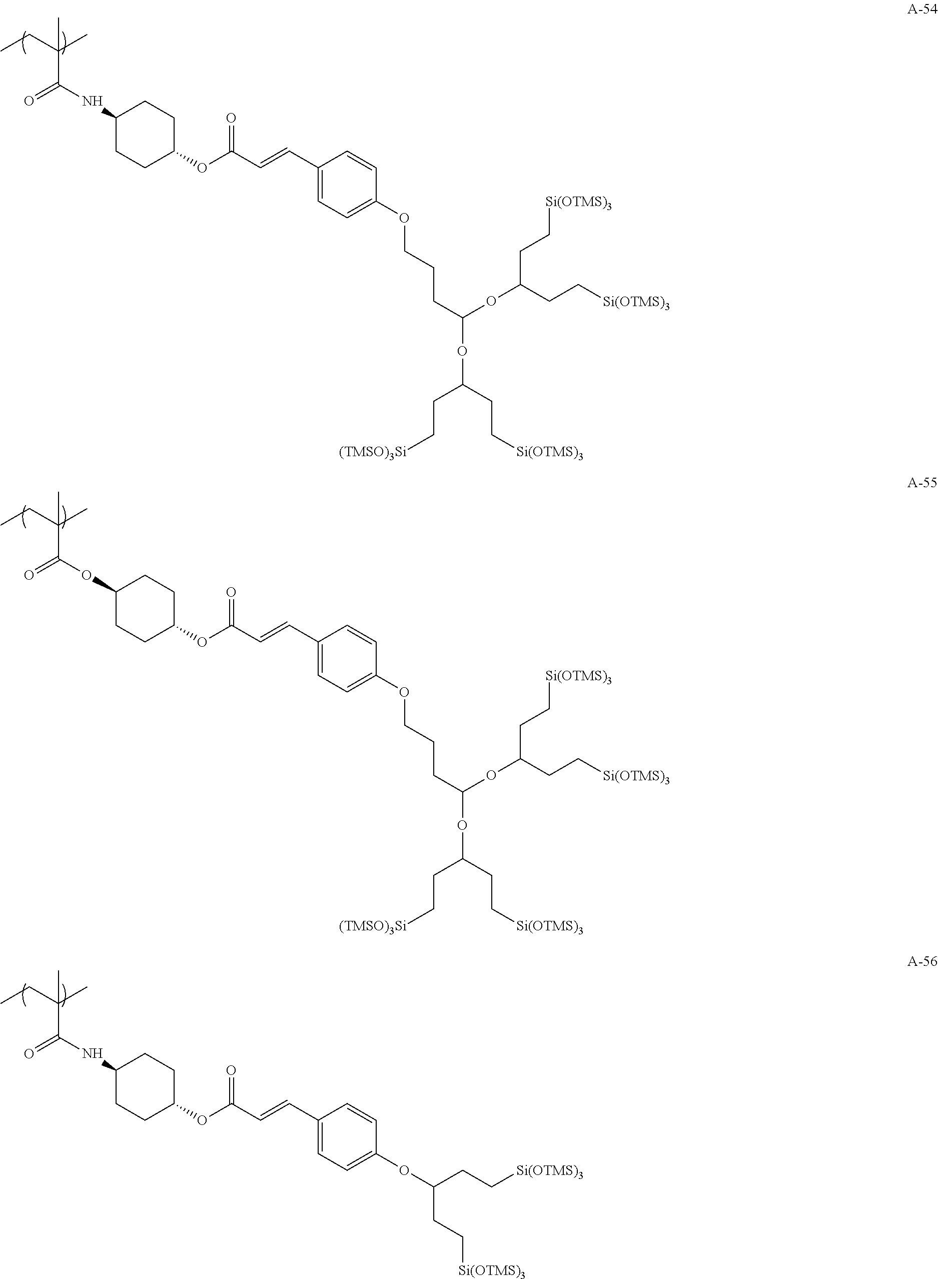

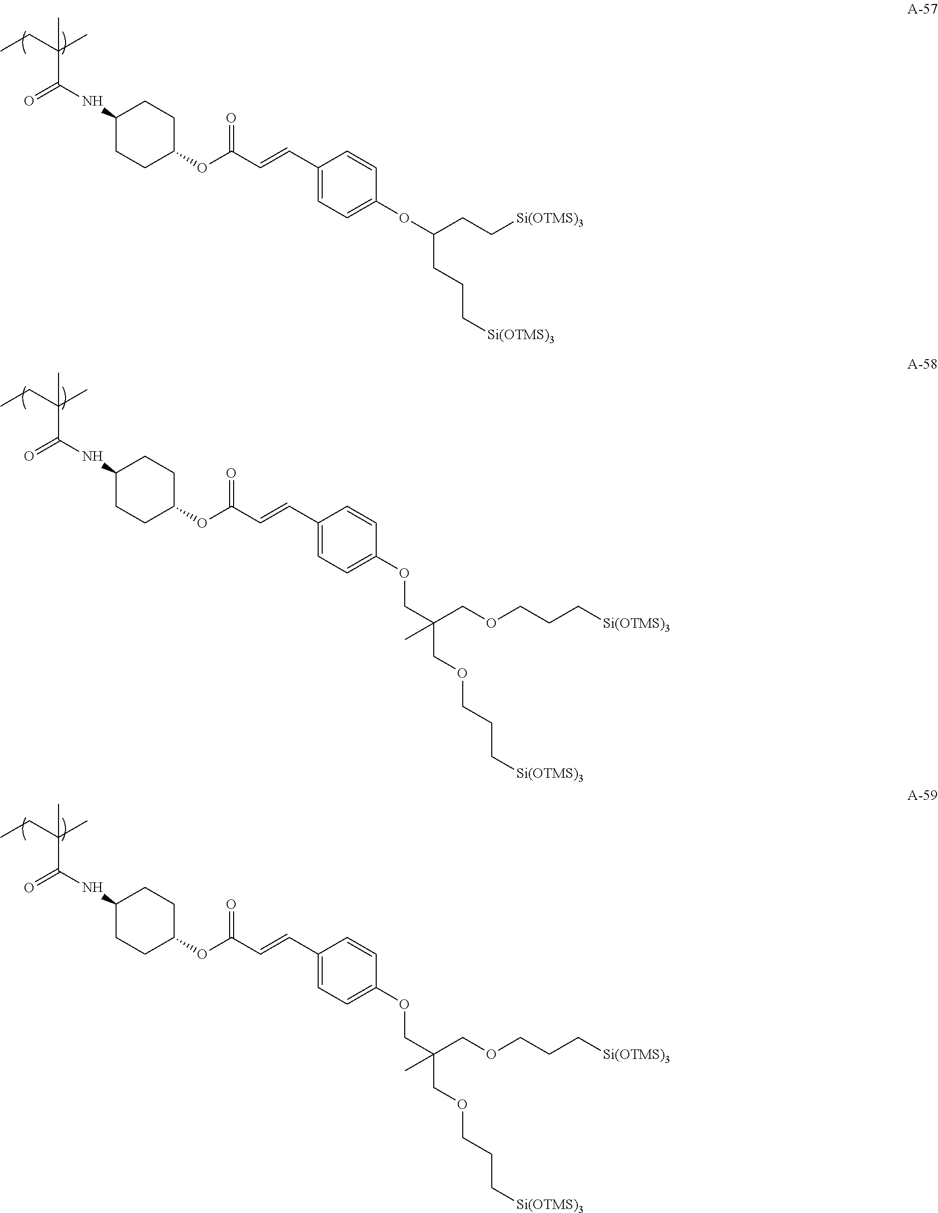

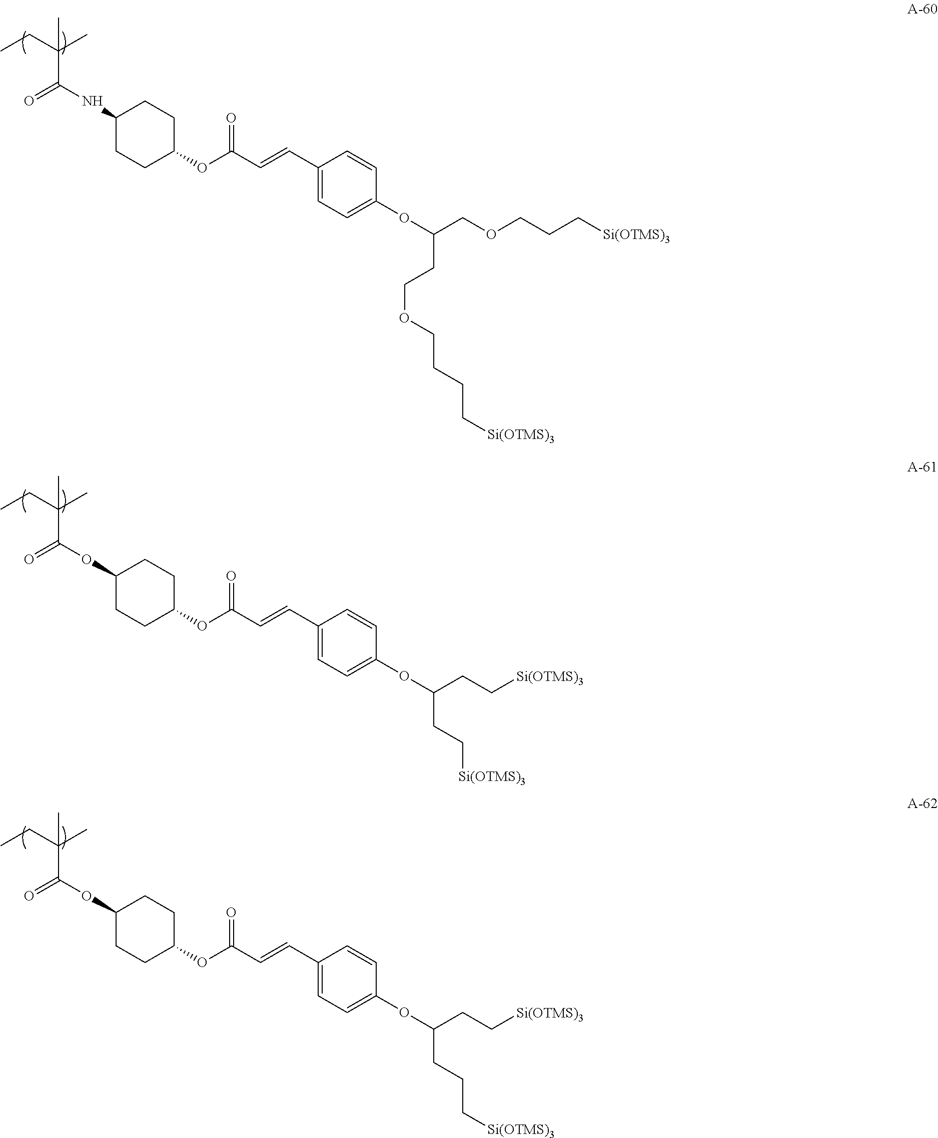

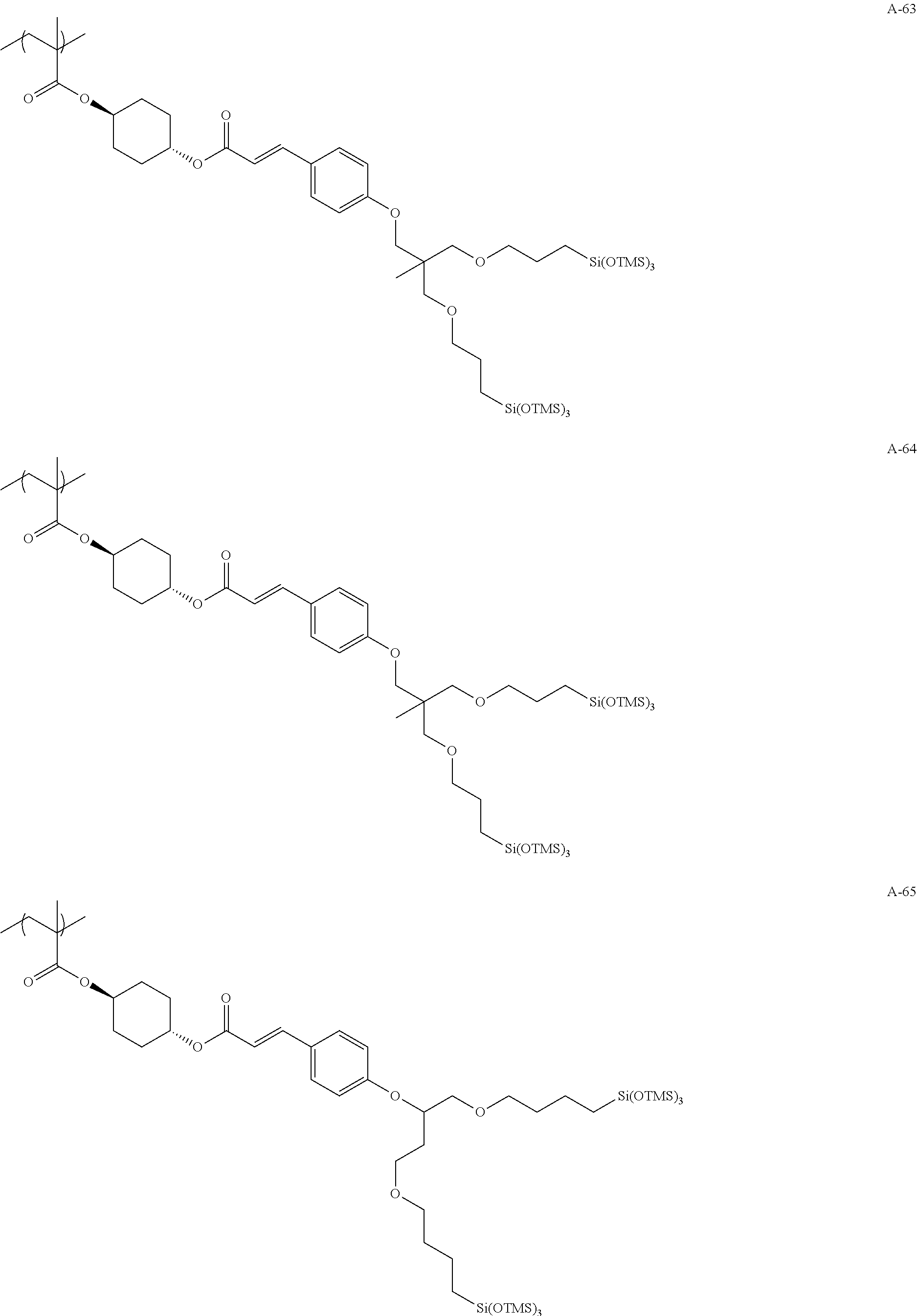

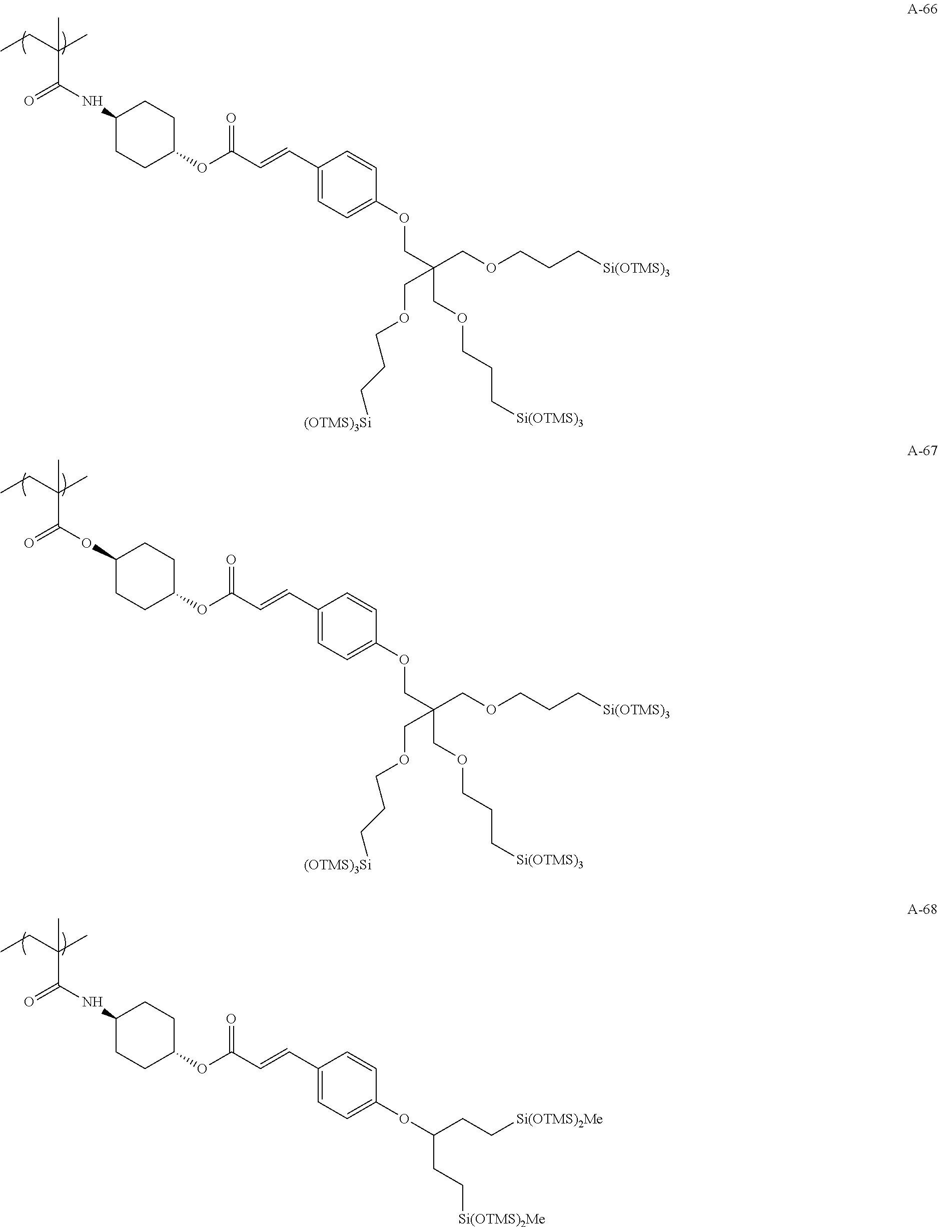

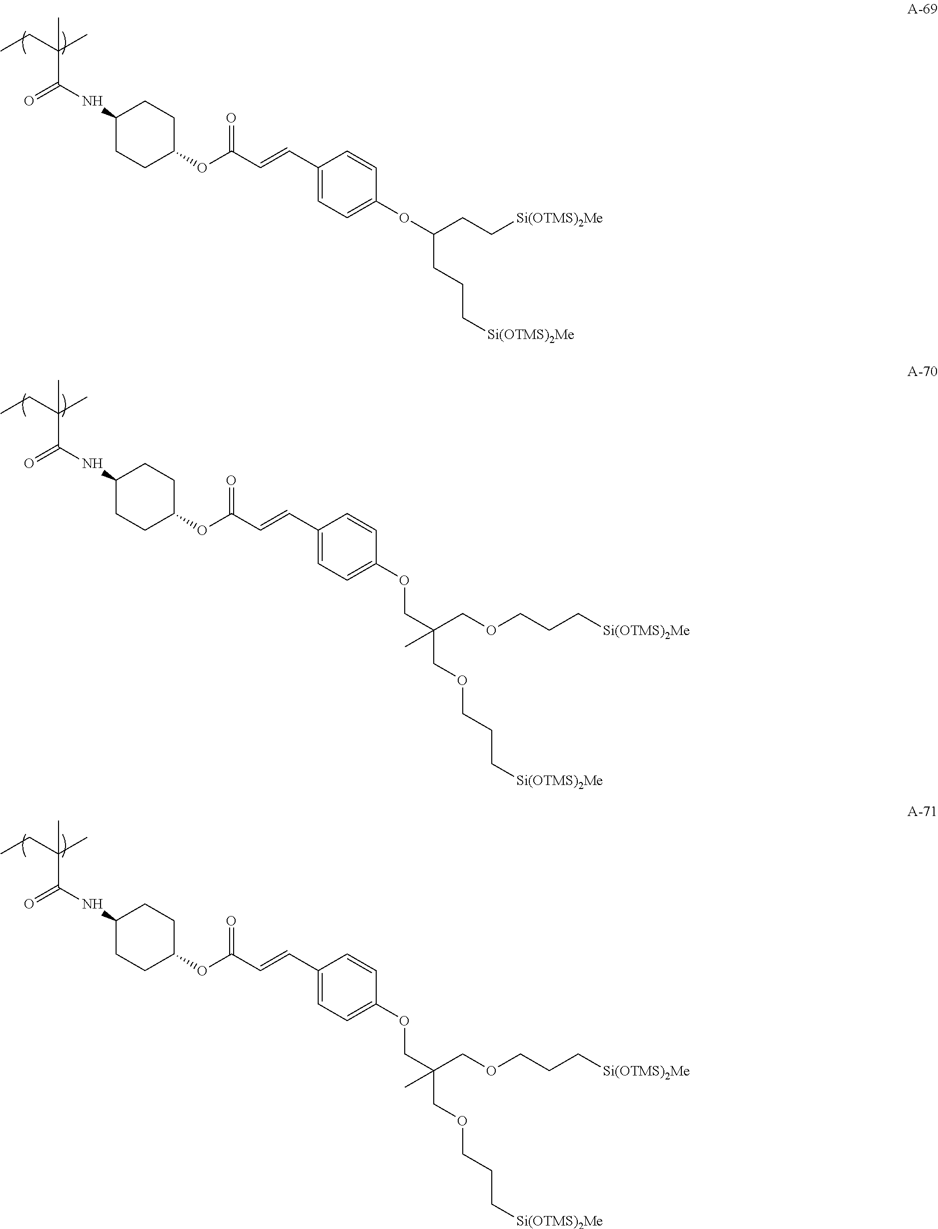

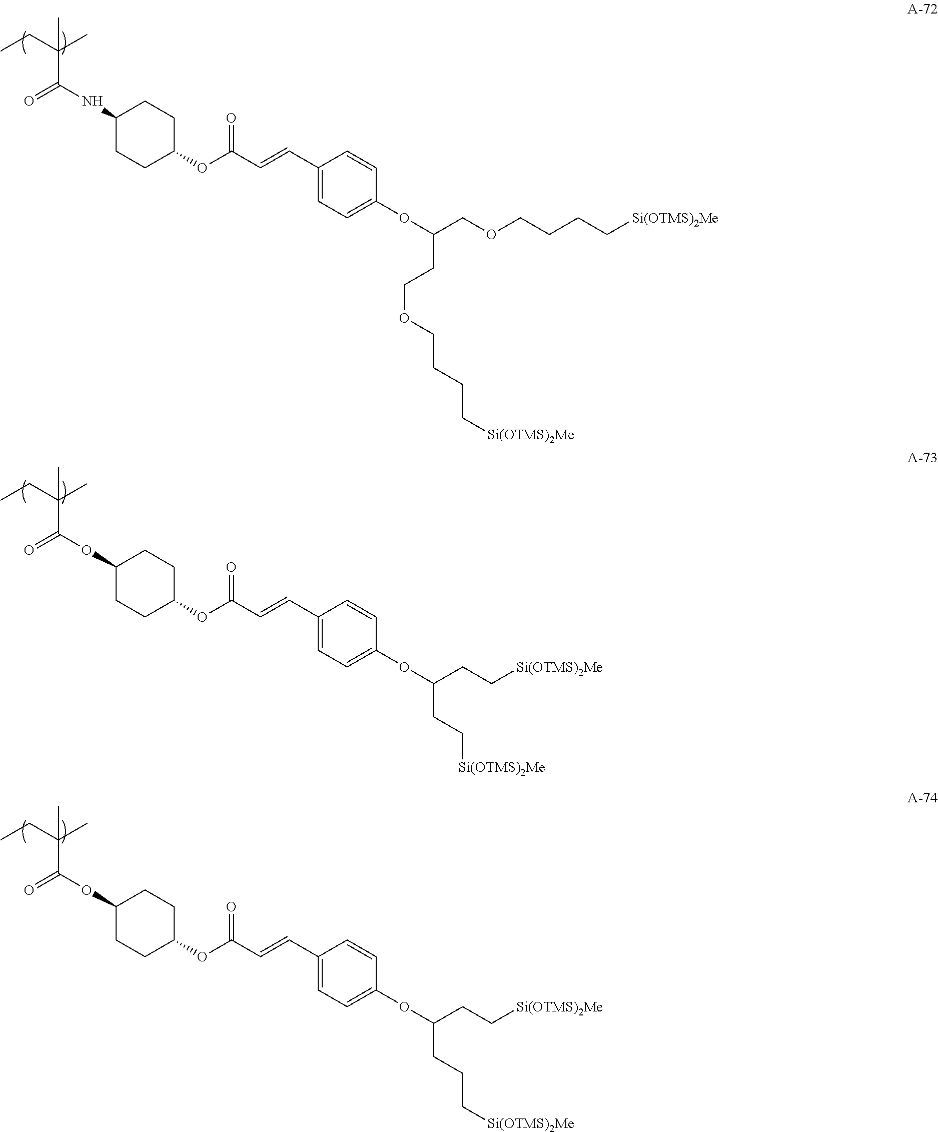

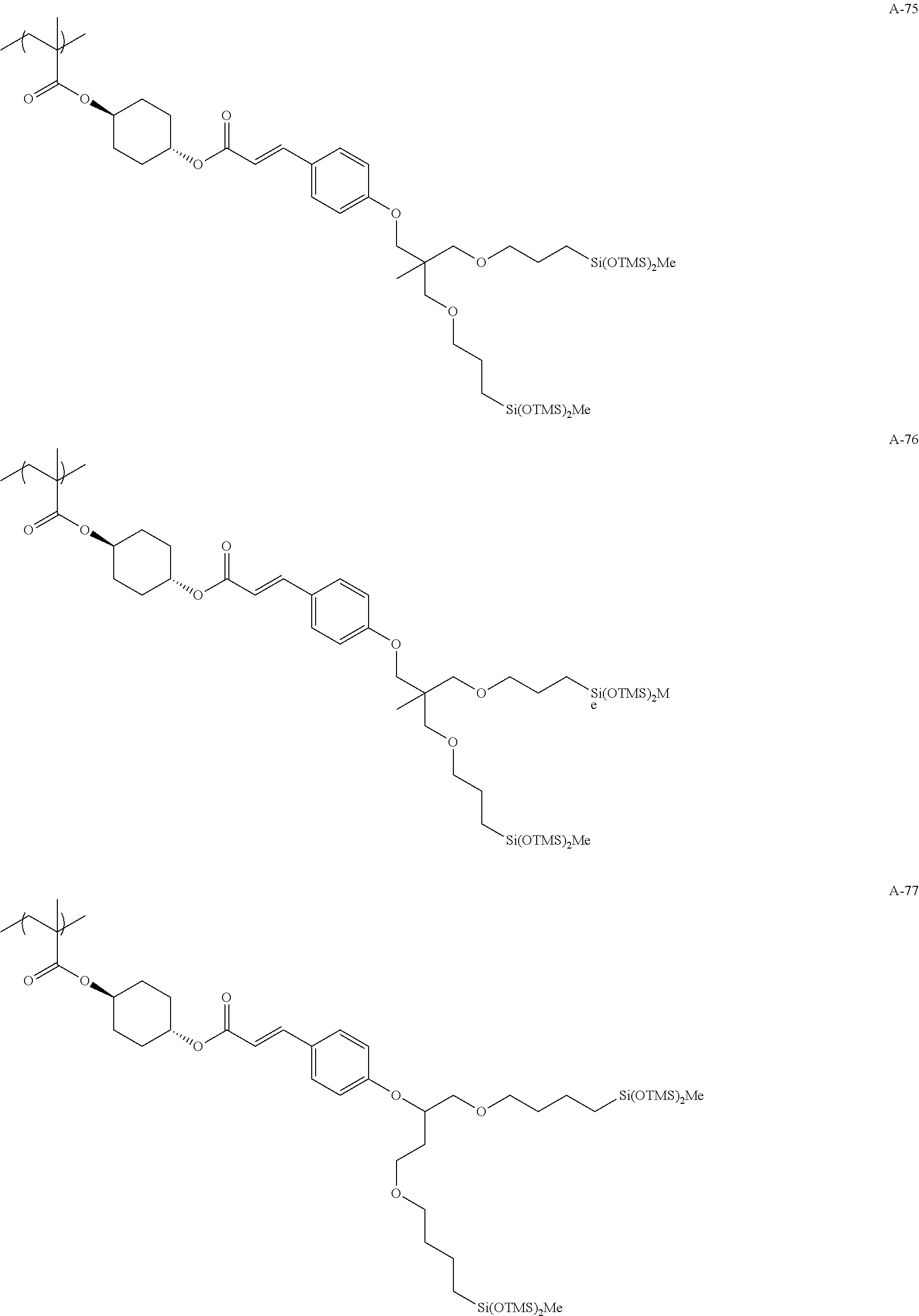

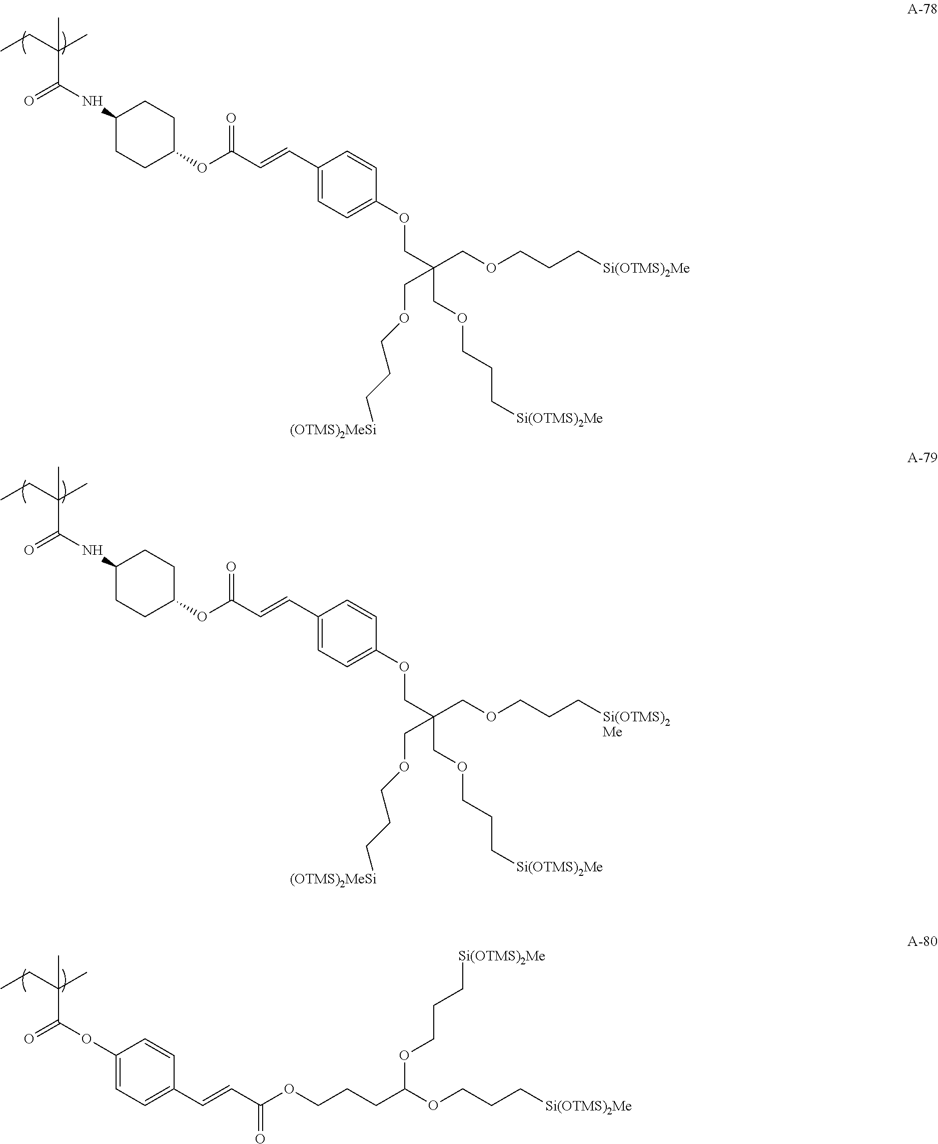

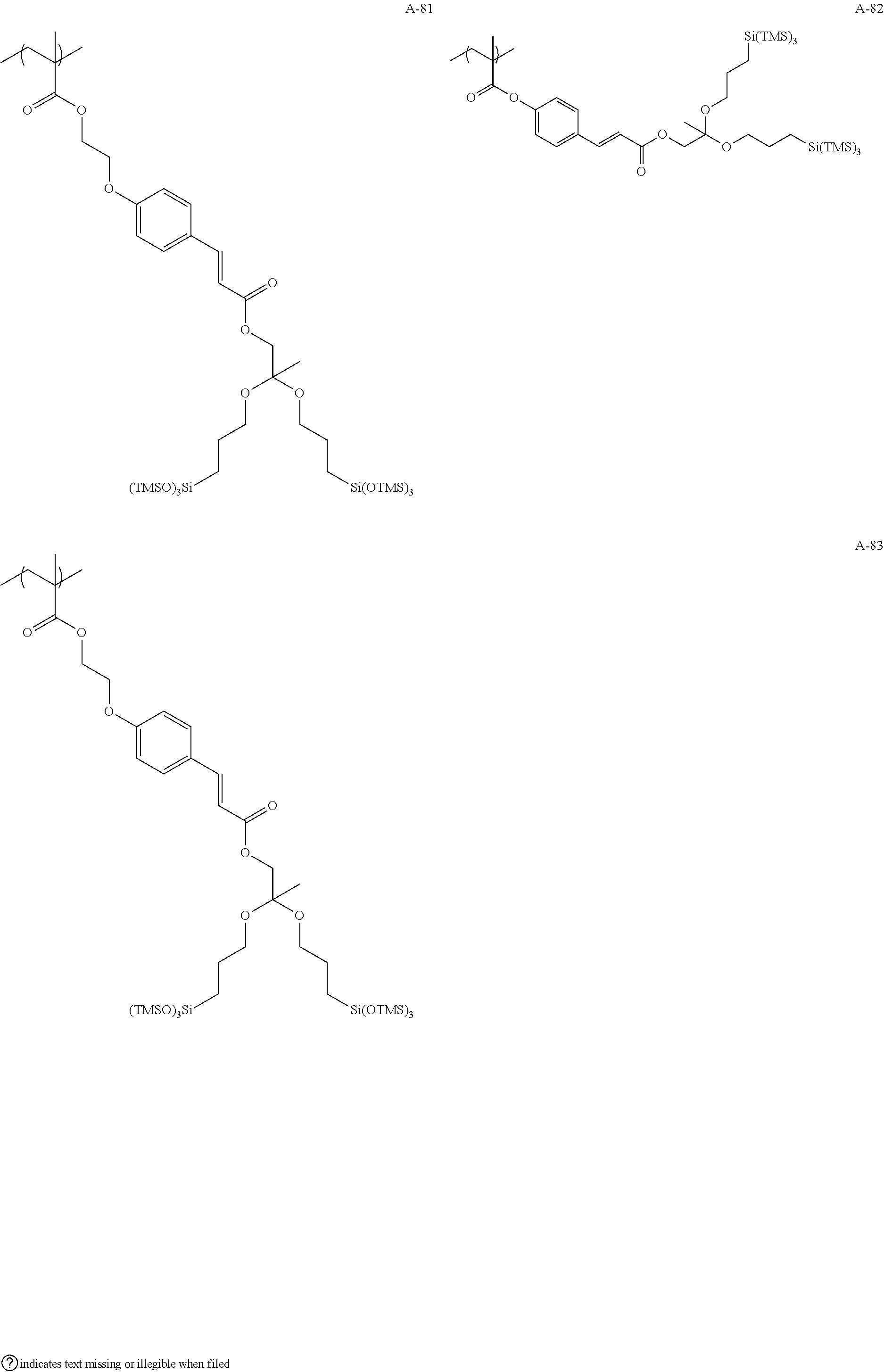

From the viewpoint of further improving the liquid crystal alignment properties, the content of the repeating unit A in the photo-alignment polymer of the present invention is preferably 5% to 50% by mass and more preferably 10% to 40% by mass with respect to all the repeating units of the photo-alignment polymer.

### [Repeating Unit B]

The photo-alignment polymer according to the embodiment of the present invention includes the repeating unit B.

The repeating unit B is a repeating unit represented by Formula (1) or a repeating unit BP having a polymer chain including a repeating unit represented by Formula (1).

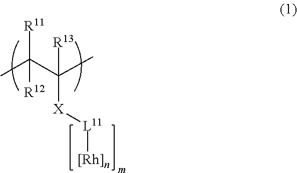

In Formula (1), R¹¹ and R¹² each independently represent a hydrogen atom or an alkyl group.

R¹³ represents a hydrogen atom or a substituent.

X represents —COO—, —CONH—, or an (m+1)-valent aromatic ring. However, in a case where m represents 1, X represents —COO—, —CONH—, or a divalent aromatic ring, and in a case where m represents an integer of 2 to 5, X represents an (m+1)-valent aromatic ring.

L¹¹ represents a single bond or an (n+1)-valent linking group. However, in a case where there are a plurality of L¹¹'s, the plurality of L¹¹'s may be the same as or different from each other.

n represents 1 to 4. However, in a case where there are a plurality of n's, the plurality of n's may be the same as or different from each other.

m represents 1 to 5.

Rh represents a substituent having two or more groups represented by Formula (S) (hereinafter, also referred to as a “substituent SI”). However, in a case where there are a plurality of Rh's, the plurality of Rh's may be the same as or different from each other.

Examples of the alkyl group represented by one aspect of R¹¹ and R¹² include a linear alkyl group having 1 to 18 carbon atoms, a branched alkyl group having 3 to 18 carbon atoms, and a cyclic alkyl group, and specific examples thereof include a methyl group, an ethyl group, a propyl group, an isopropyl group, a butyl group (for example, an n-butyl group, a sec-butyl group, an iso-butyl group, and a tert-butyl group), and a cyclohexyl group.

R¹¹ and R¹² are preferably a hydrogen atom.

Examples of the substituent represented by one aspect of R¹³ include a hydroxy group, an alkyl group, an alkenyl group, and an aryl group.

In addition, examples of the substituent represented by one aspect of R¹³ also include a -L^{R}-hydroxy group, a -L^{R}-alkyl group, a -L^{R}-alkenyl group, and a -L^{R}-aryl group. L^{R} represents a divalent linking group. Examples of the divalent linking group represented by L^{R} include —O—, —S—, —CO—, —NR^{N}—, —CH═CH—, —C≡C—, a divalent cyclic group, an alkylene group, and a divalent group obtained by combining these groups, and a —CH₂—COO-alkylene group-hydroxy group is preferable. R^{N} represents a hydrogen atom or an alkyl group having 1 to 12 carbon atoms.

As the alkyl group represented by one aspect of R¹³, a linear alkyl group having 1 to 4 carbon atoms is preferable, and a methyl group or an ethyl group is more preferable.

R¹³ is preferably a hydrogen atom or a methyl group.

The (m+1)-valent aromatic ring represented by one aspect of X may be monocyclic or polycyclic.

The (m+1)-valent aromatic ring preferably has 6 to 20 carbon atoms, and more preferably has 6 to 8 carbon atoms.

As the (m+1)-valent aromatic ring, a group formed by removing (m+1) hydrogen atoms from an aromatic ring is preferable, and a group formed by removing (m+1) hydrogen atoms from a benzene ring is more preferable. For example, in a case where m is 1, examples of the group formed by removing (m+1) hydrogen atoms from a benzene ring include a phenyl group.

The (n+1)-valent linking group represented by one aspect of L¹¹ is an (m+1)-valent hydrocarbon group having 1 to 24 carbon atoms which may have a substituent, preferably a hydrocarbon group in which some of the carbon atoms constituting the hydrocarbon group may be substituted with heteroatoms, and more preferably an aliphatic hydrocarbon group having 1 to 10 carbon atoms which may contain an oxygen atom or a nitrogen atom.

In addition, the (n+1)-valent linking group is preferably a divalent linking group.

Examples of the divalent linking group ((n+1)-valent linking group in which n is 2) include a hydrocarbon group having 1 to 20 carbon atoms, and an alkylene group having 1 to 20 carbon atoms is preferable, and a linear alkylene group having 1 to 18 carbon atoms, a branched alkylene group having 3 to 18 carbon atoms, or a cyclic alkylene group having 3 to 20 carbon atoms is more preferable.

L¹¹ is preferably a single bond or a linear alkylene group having 1 to 18 carbon atoms, and more preferably a single bond, a methylene group, an ethylene group, or a propylene group.

The substituent SI represented by Rh is not particularly limited as long as it is a substituent having two or more groups represented by Formula (S).

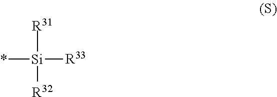

In Formula (S), * represents a bonding position.

R³¹, R³², and R³³ each independently represent an alkyl group, an alkenyl group, an aryl group, or an alkylene aryl group.

However, in the substituent represented by Rh, a plurality of R³¹'s may be the same or different from each other, a plurality of R³²'s may be the same or different from each other, and a plurality of R³³'s may be the same or different from each other.

Examples of the alkyl group represented by one aspect of R³¹, R³², and R³³ include a linear alkyl group having 1 to 18 carbon atoms, a branched alkyl group having 3 to 18 carbon atoms, and a cyclic alkyl group.

Examples of the alkenyl group represented by one aspect of R³¹, R³², and R³³ include an alkenyl group having 2 to 12 carbon atoms.

Examples of the aryl group represented by one aspect of R³¹, R³², and R³³ include an aryl group having 6 to 12 carbon atoms. Specific examples thereof include a phenyl group, an α-methylphenyl group, and a naphthyl group.

Examples of the alkylene aryl group represented by one aspect of R³¹, R³², and R³³ include an alkylene aryl group having 7 to 30 carbon atoms.

From the viewpoint of reducing the surface tension of the liquid crystal composition and suppressing unevenness during the formation of the liquid crystal cured layer, R³¹, R³², and R³³ in Formula (S) are each preferably an alkyl group, and more preferably a linear alkyl group having 1 to 18 carbon atoms.

The number of groups represented by Formula (S) included in the substituent SI is 2 or more, and from the reason that the surface tension of the liquid crystal composition is reduced and unevenness can be suppressed during the formation of the liquid crystal cured layer, the number of groups represented by Formula (S) is preferably 3 to 8, more preferably 3 to 6, and still more preferably 3 to 5. From the viewpoint of easy synthesis, the number of groups represented by Formula (S) may be 2.

As the substituent SI, a group represented by Formula (S1) is preferable.

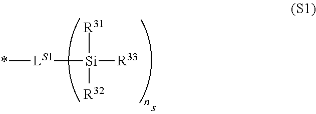

In Formula (S1), * represents a bonding position.

R³¹, R³², and R³³ each independently represent an alkyl group, an alkenyl group, an aryl group, or an alkylene aryl group. Provided that a plurality of R³¹'s may be the same as or different from each other, a plurality of R³²'s may be the same as or different from each other, and a plurality of R³³'s may be the same as or different from each other.

L^{S1} represents an (n_{S}+1)-valent linking group.

nₛ represents an integer of 3 or more.

R³¹, R³², and R³³ in Formula (S1) have the same meanings as R³¹, R³², and R³³ in Formula (S), respectively, and suitable aspects thereof are also the same.

The (n_{S}+1)-valent linking group represented by L^{S1} is, for example, preferably an (n_{S}+1)-valent hydrocarbon group having 1 to 15 carbon atoms, which may have a substituent, and in which a part of carbon atoms constituting the hydrocarbon group may be substituted with a heteroatom. For example, in a case where the (n_{S}+1)-valent linking group is a tetravalent hydrocarbon group, one or two or more non-adjacent —CH₂-'s of —CH₂-'s constituting a part of the tetravalent hydrocarbon group may each independently be substituted with —O—, —CO—, —S—, —NH—, or —N(Q_{S})-. Q_{S} represents a substituent, and as the substituent represented by Q_{S}, an alkyl group is preferable, a linear alkyl group having 1 to 4 carbon atoms is more preferable, and a methyl group or an ethyl group is still more preferable.

As the substituent that the hydrocarbon group can have, an alkyl group is preferable, a linear alkyl group having 1 to 4 carbon atoms is more preferable, and a methyl group or an ethyl group is still more preferable.

In addition, examples of the heteroatom include a silicon atom, an oxygen atom, and a nitrogen atom, and a silicon atom or an oxygen atom is preferable.

As L^{S1}, an (n_{S}+1) linking group having a heteroatom is also preferable.

Examples of the (n_{S}+1)-valent linking group represented by one aspect of L^{S1} include a tetravalent or higher valent linking group consisting of a combination of a group selected from an ether group and a thioether group, an alkylene group, and a quaternary carbon atom bonded to the alkylene group.

The (n_{S}+1)-valent linking group is preferably a tetravalent linking group consisting of a combination of an alkylene group having 1 to 6 carbon atoms, a quaternary carbon atom bonded to the alkylene group, and three ether groups bonded to the quaternary carbon atom.

The above-described alkylene group may be linear, branched, or cyclic, and is preferably linear.

As the (n_{S}+1)-valent linking group, a group represented by Formula (LS-1) or a group represented by Formula (LS-2) is preferable, and a group represented by Formula (LS-1) is more preferable.

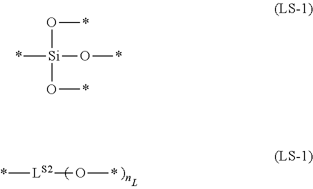

In Formula (LS-1), * represents a bonding position.

In Formula (LS-2), * represents a bonding position.

L^{S2} represents an (n_{L}+1)-valent hydrocarbon group in which a part of carbon atoms may be substituted with a heteroatom. n_{L} represents an integer of 3 or more.

The (n_{L}+1)-valent hydrocarbon group represented by L^{S2} is preferably an (n_{L}+1)-valent linking group consisting of a combination of a group selected from an ether group and a thioether group, and an alkylene group. The above-described alkyl group may be linear, branched, or cyclic.

In addition, it is also preferable that the (n_{L}+1)-valent hydrocarbon group does not have a silicon atom.

n_{L} preferably represents an integer of 3 to 8, more preferably represents an integer of 3 to 6, and even more preferably represents an integer of 3 to 5.

As Rh (substituent SI), a group represented by Formula (S2) or Formula (S3) is more preferable.

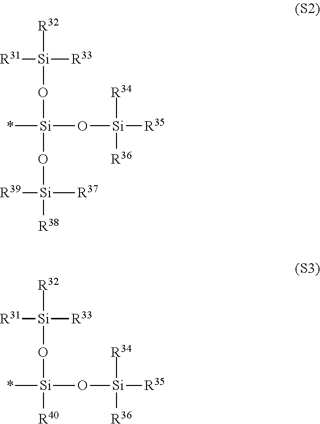

* represents a bonding position.

R³¹ to R³⁹ each independently represent an alkyl group, an alkenyl group, an aryl group, or an alkylene aryl group. R³¹ to R³⁹ are each preferably an alkyl group (preferably an alkyl group having 1 to 3 carbon atoms) and more preferably a methyl group.

R⁴⁰ represents an alkyl group having 1 to 6 carbon atoms, and a methyl group is preferable.

The polymer chain B is preferably a so-called graft chain.

In addition, in a case where the repeating unit B is the repeating unit BP, from the viewpoint of synthetic simplicity, the repeating unit B preferably includes a sulfur atom.

The repeating unit BP is preferably a repeating unit represented by Formula (b1).

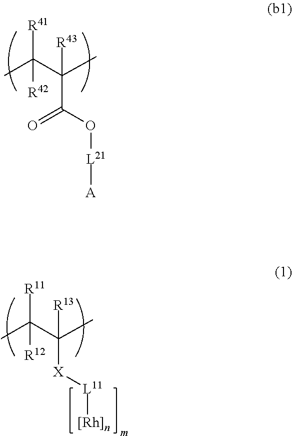

In Formula (b1), R⁴¹ and R⁴² each independently represent a hydrogen atom or an alkyl group.

R⁴³ represents a hydrogen atom or a substituent.

L²¹ represents a single bond or a divalent linking group.

A represents a repeating unit represented by Formula (1).

R⁴¹ and R⁴² have the same definitions as R¹¹ and R¹² in Formula (1), and suitable aspects thereof are also the same.

R⁴³ has the same definition as R¹³ in Formula (1), and a suitable aspect thereof is also the same.

The repeating unit represented by Formula (1) represented by A is as described above.

Examples of the divalent linking group represented by one aspect of L²¹ include —O—, —S—, —CO—, —NR^{N}—, —CH═CH—, —C≡C—, a divalent cyclic group, an alkylene group which may have a hydroxyl group, and a divalent linking group formed by a combination of these groups. R^{N} represents a hydrogen atom or an alkyl group having 1 to 12 carbon atoms.

Among these, as L²¹, a divalent linking group including -alkylene group-NH—COO— or a divalent linking group including -alkylene group-COO— is preferable, and -alkylene group-NH—COO-alkylene group-S— or -alkylene group-COO-alkylene group-S— is more preferable.

The weight-average molecular weight of the monomer from which the repeating unit BP is derived is preferably 1,000 to 50,000, more preferably 2,000 to 20,000, and still more preferably 4,000 to 10,000.

The weight-average molecular weight of the monomer from which the repeating unit BP is derived can be measured, for example, by the same method as the weight-average molecular weight of the photo-alignment polymer described later.

The monomer from which the repeating unit BP is derived refers to a monomer with which the repeating unit BP can be formed by polymerization. Examples of the monomer from which the repeating unit BP is derived include a monomer having a polymer chain including a repeating unit represented by Formula (1) (so-called macromonomer).

In Formula (1), as the divalent linking group represented by L¹¹, a linking group selected from Formulae (B1) to (B6) is also preferable.

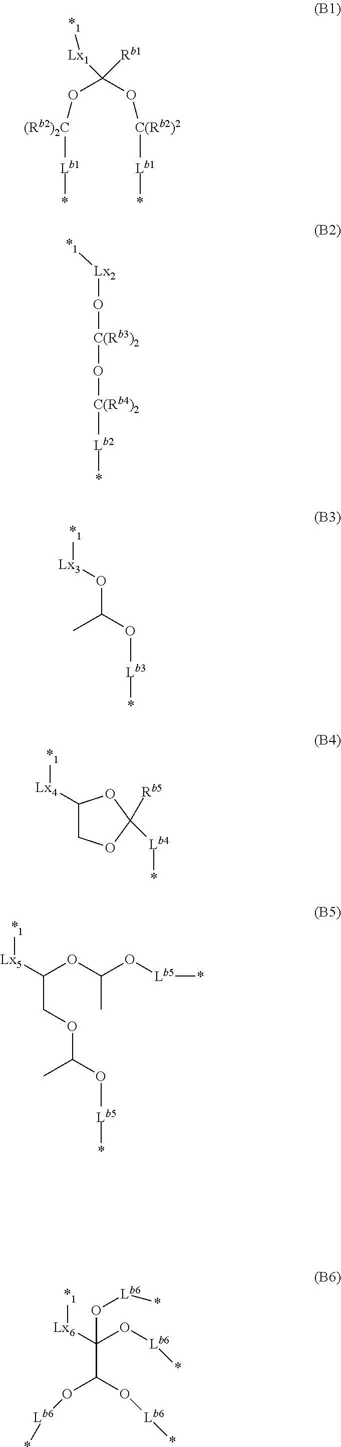

In Formulae (B1) to (B6), *1 represents a bonding position to X.

* represents a bonding position to Rh.

Lx₁, Lx₂, Lx₃, Lx₄, Lx₅, and Lx₆ each independently represent a single bond, or a linking group selected from an alkylene group having 1 to 20 carbon atoms, which may have —O—, an aryl group having 6 to 18 carbon atoms, which may have —O—, and a group obtained by combining these groups.

R^{b1}, R^{b2}, R^{b3}, R^{b4}, and R^{b5} each independently represent a hydrogen atom or a substituent.

In this regard, the two R^{b3}'s may be bonded to each other to form a ring, the plurality of R^{b2}'s may be the same as or different from each other, the plurality of R^{b3}'s may be the same as or different from each other, and the plurality of R^{b}4's may be the same as or different from each other.

L^{b1}, L^{b2}, L^{b3}, L^{b4}, L^{b5}, and L^{b6} each independently represent a divalent linking group. However, a plurality of L^{b1}'s may be the same as or different from each other, a plurality of L^{b5}'s may be the same as or different from each other, and a plurality of L^{b6}'s may be the same as or different from each other.

In a case where L¹¹ is Formula (B1) or Formula (B5), n in Formula (1) represents 2. In a case where L¹¹ is Formula (B2), Formula (B3), or Formula (B4), n in Formula (1) represents 1. In a case where L¹¹ is represented by Formula (B6), n represents 4.

Lx₁, Lx₂, Lx₃, Lx₄, Lx₅, and Lx₆ are each preferably an alkylene group having 1 to 20 carbon atoms. Here, the alkylene group may be a branched alkylene group, and is preferably a linear alkylene group.

R¹, R^{b2}, R^{b3}, R^{b4}, and R^{b}s are preferably a hydrogen atom or a methyl group. L^{b1}, L^{b2}, L^{b3}, L^{b4}, L^{b5}, and L^{b6} are each preferably a linking group selected from an alkylene group having 1 to 20 carbon atoms, which may have —O—, an aryl group having 6 to 18 carbon atoms, which may have —O—, or a group obtained by combining these groups, more preferably an alkylene group having 1 to 20 carbon atoms, which may have —O—, and still more preferably an alkylene group having 1 to 8 carbon atoms.

Examples of the repeating unit B include the following repeating units.

In the following formulae, * represents a bonding position. TMS represents a trimethylsilyl group. Me represents a methyl group.

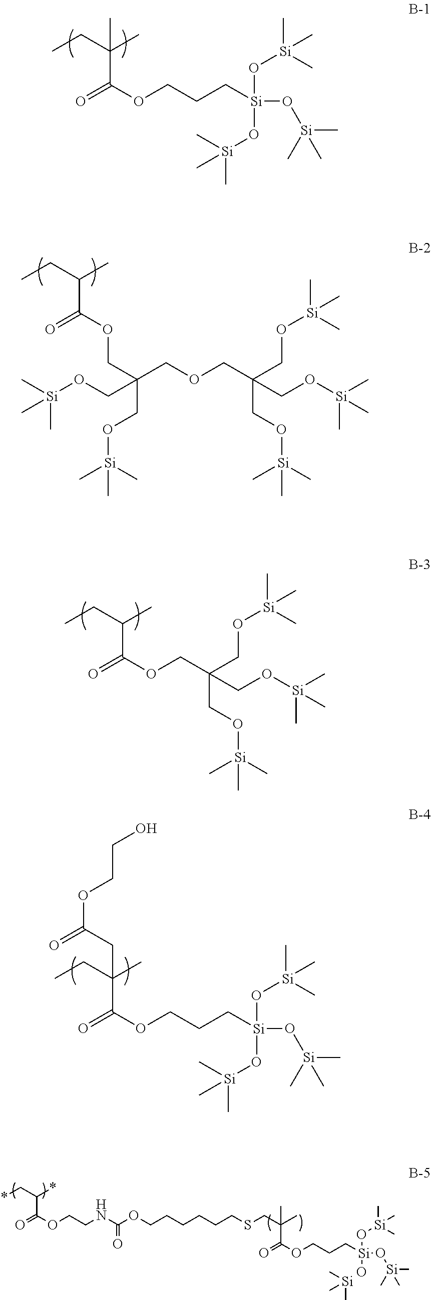

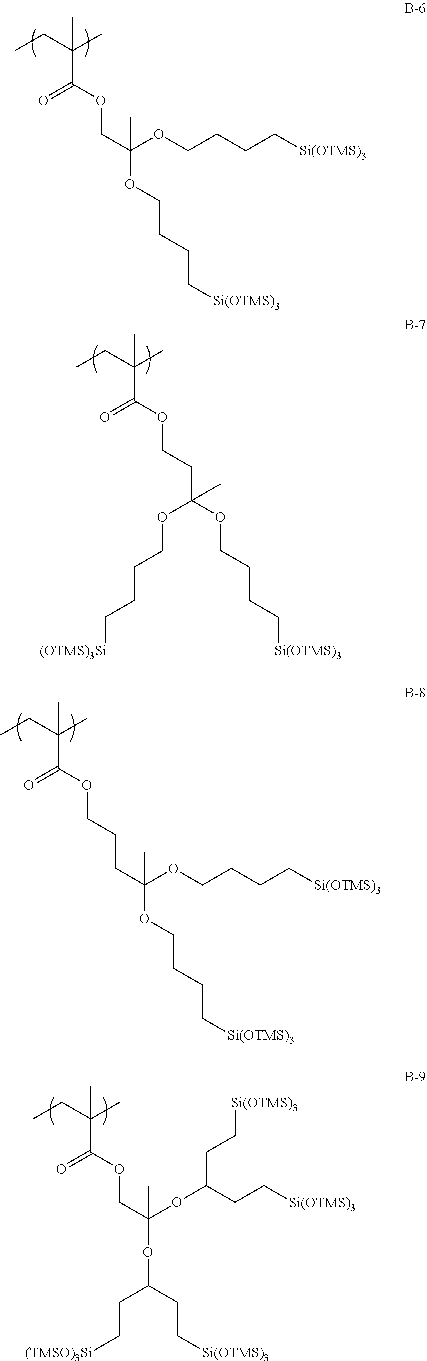

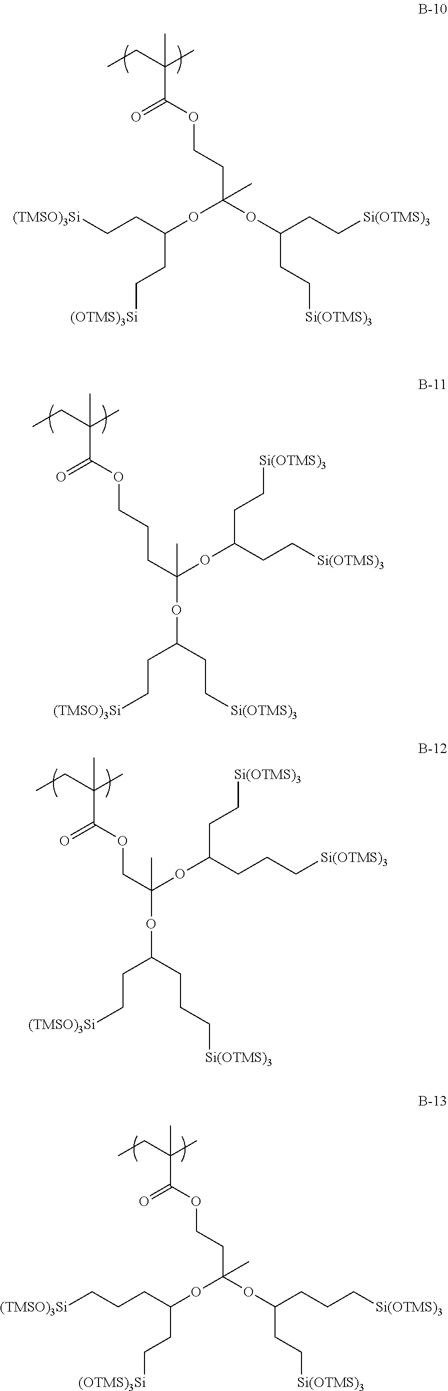

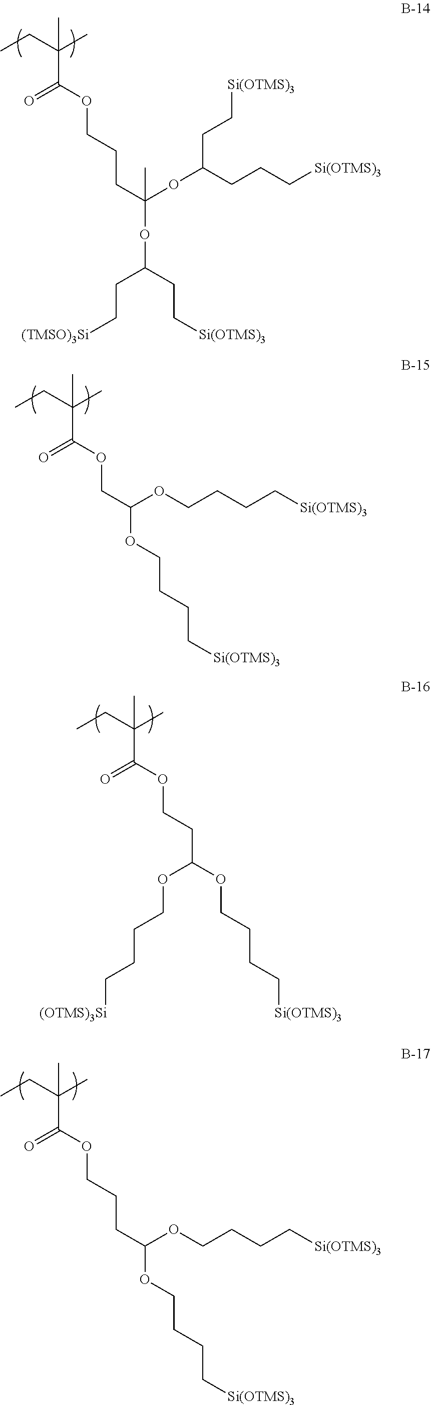

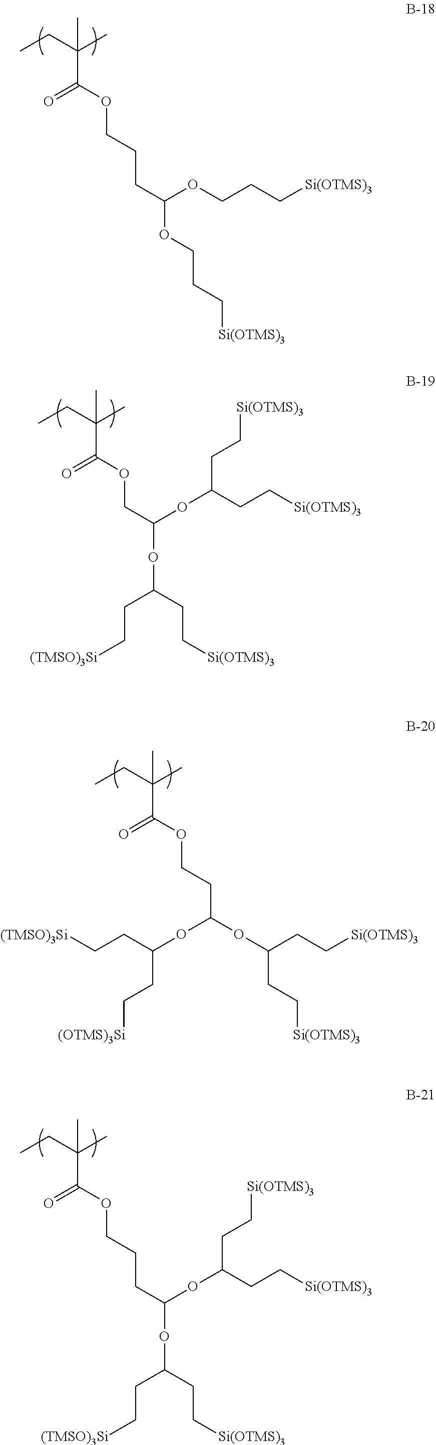

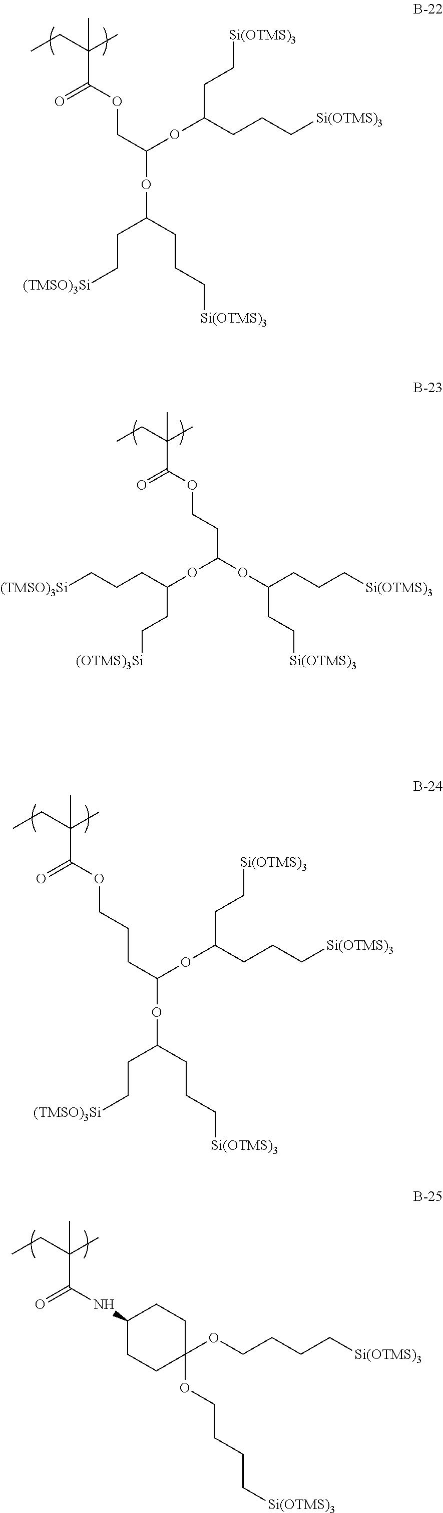

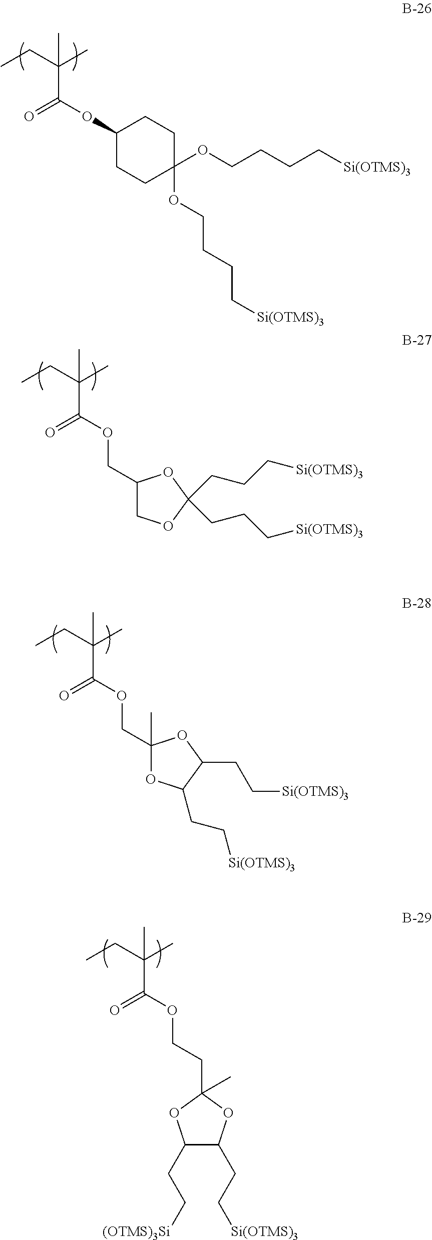

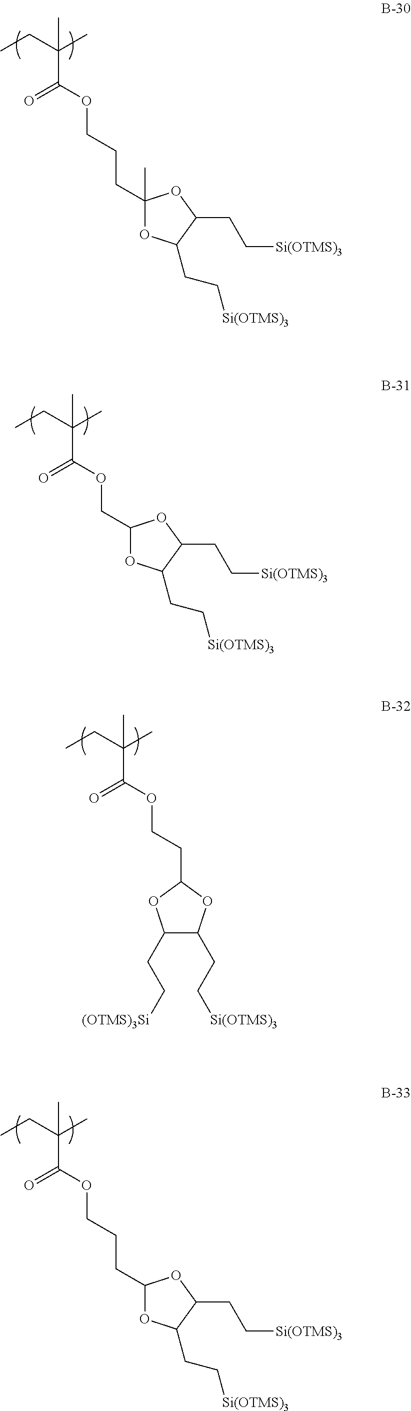

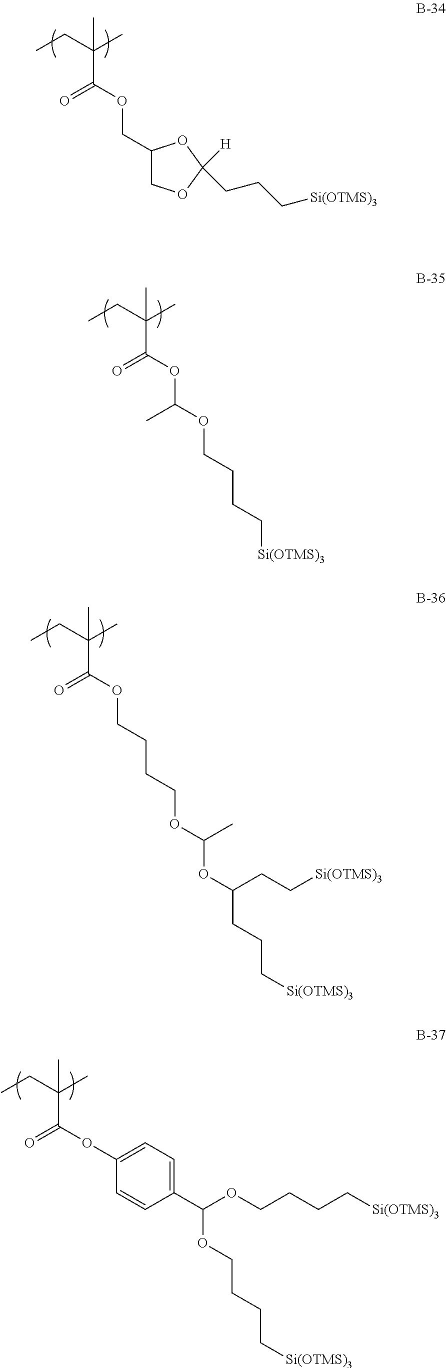

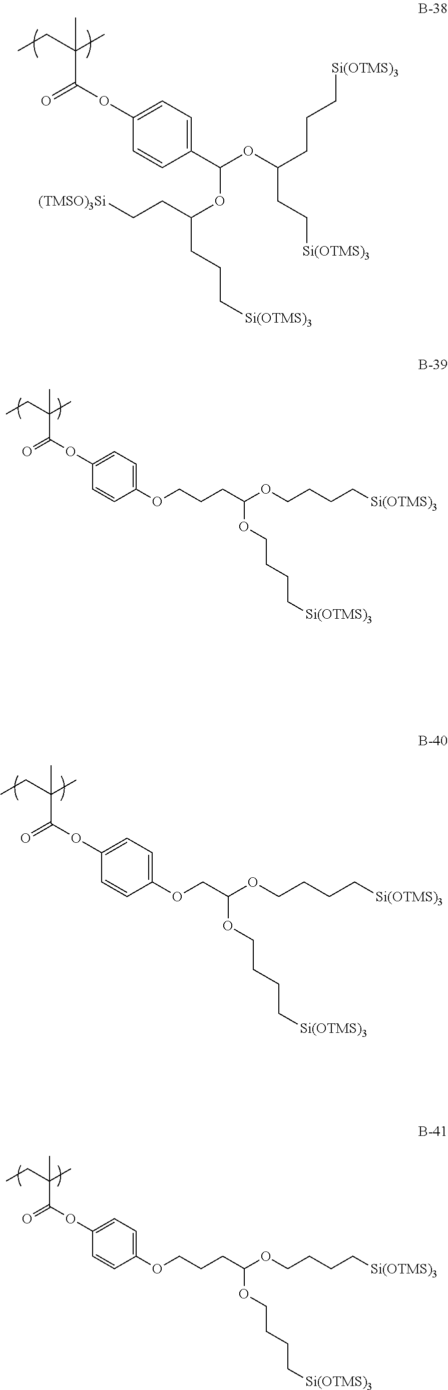

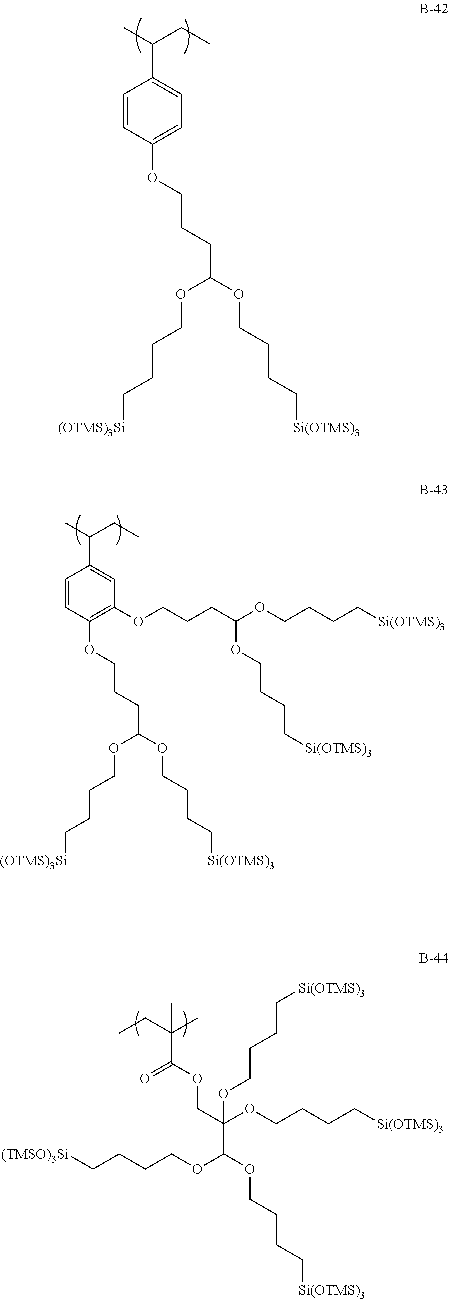

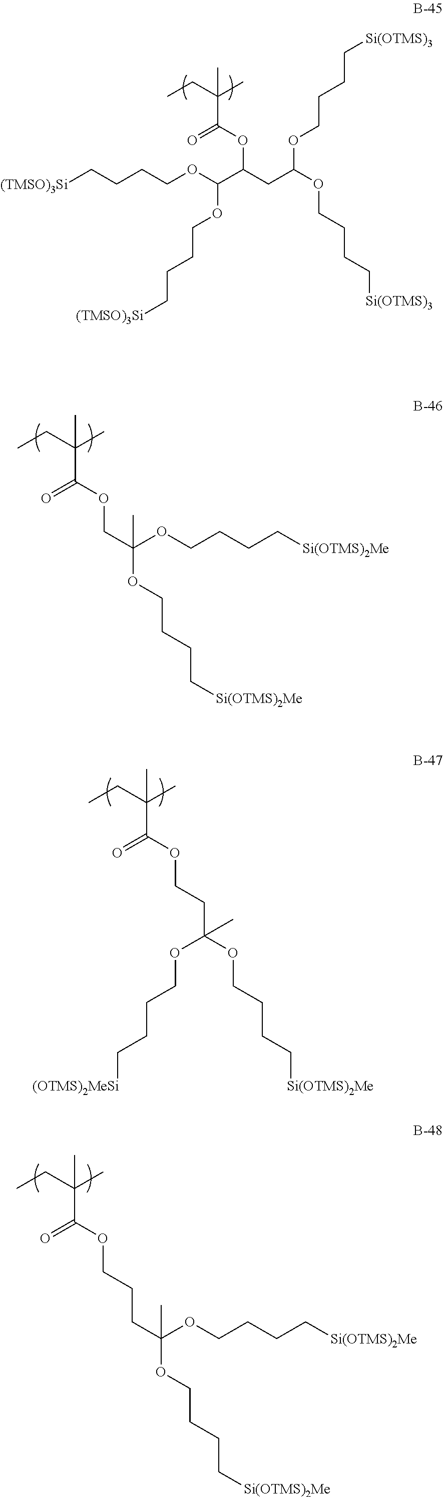

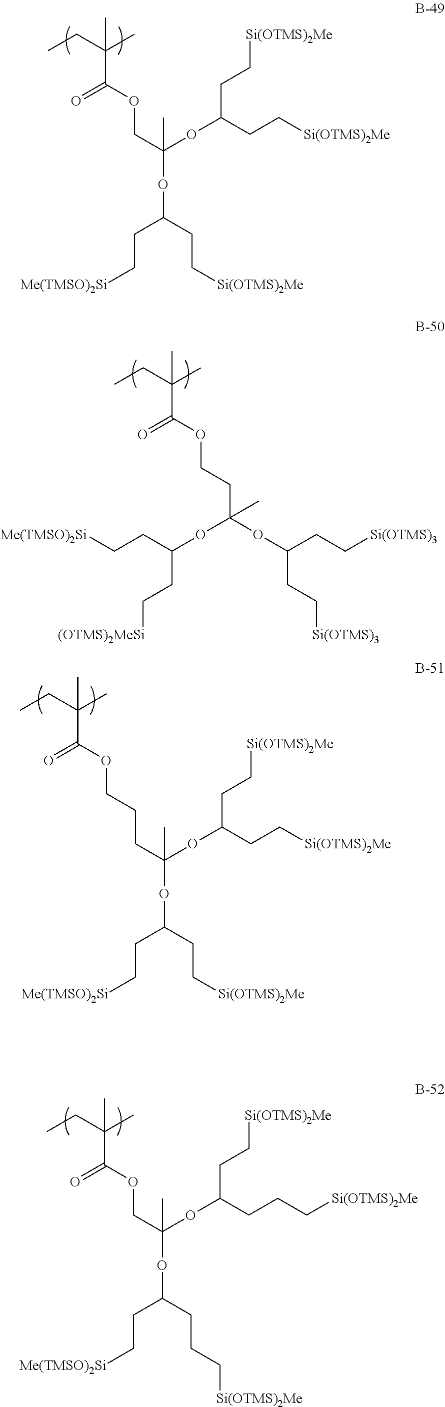

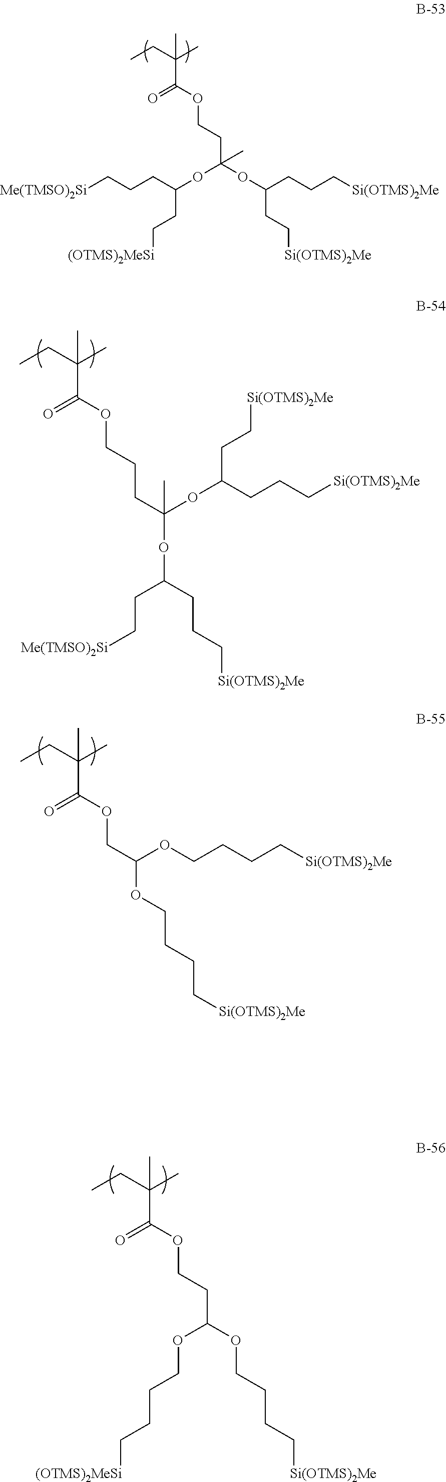

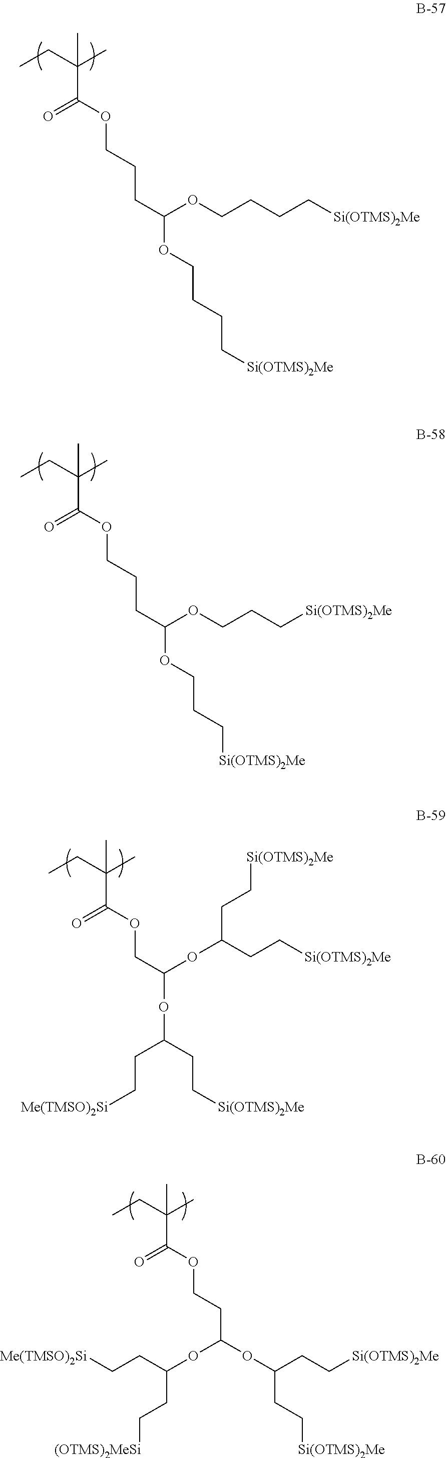

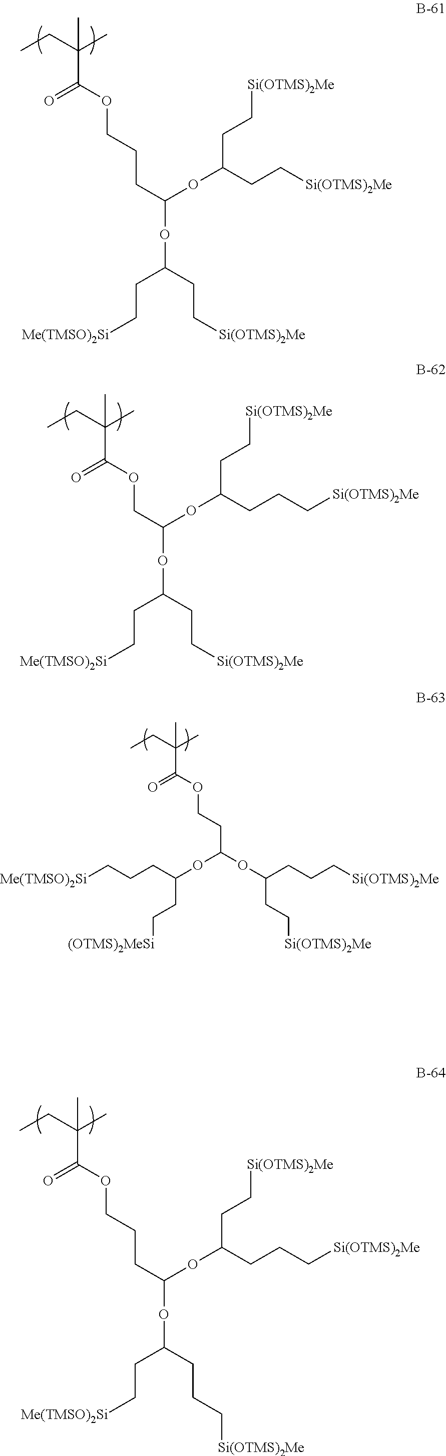

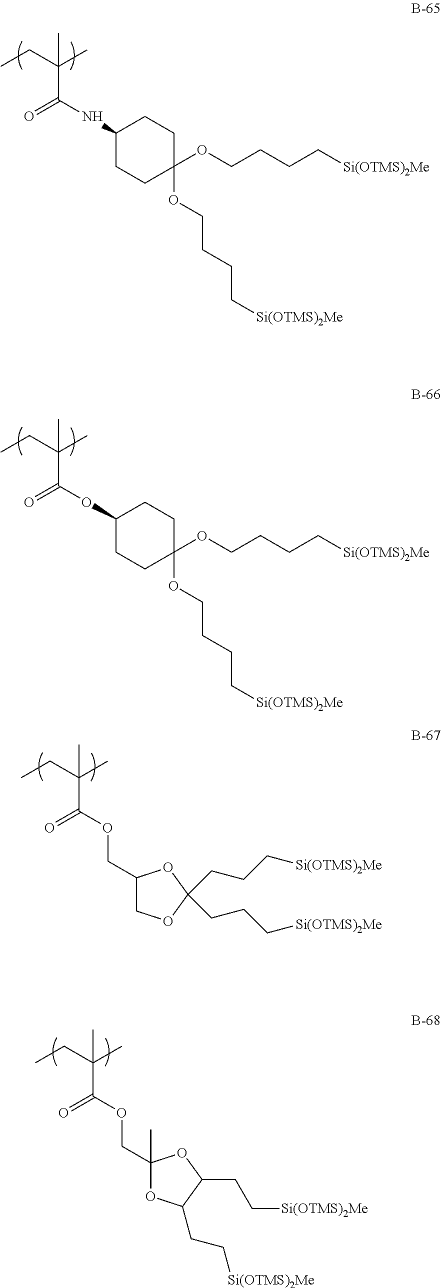

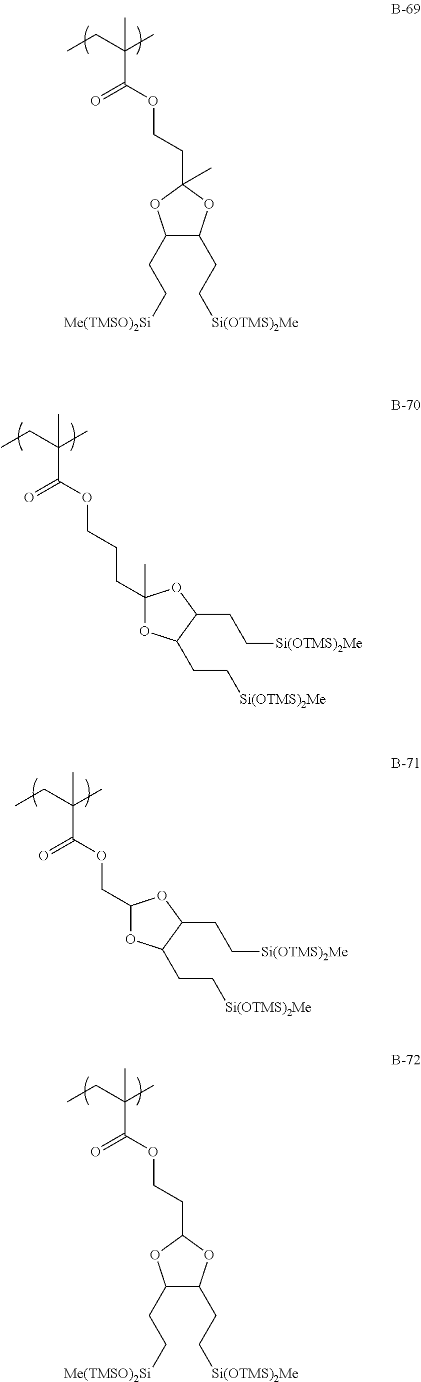

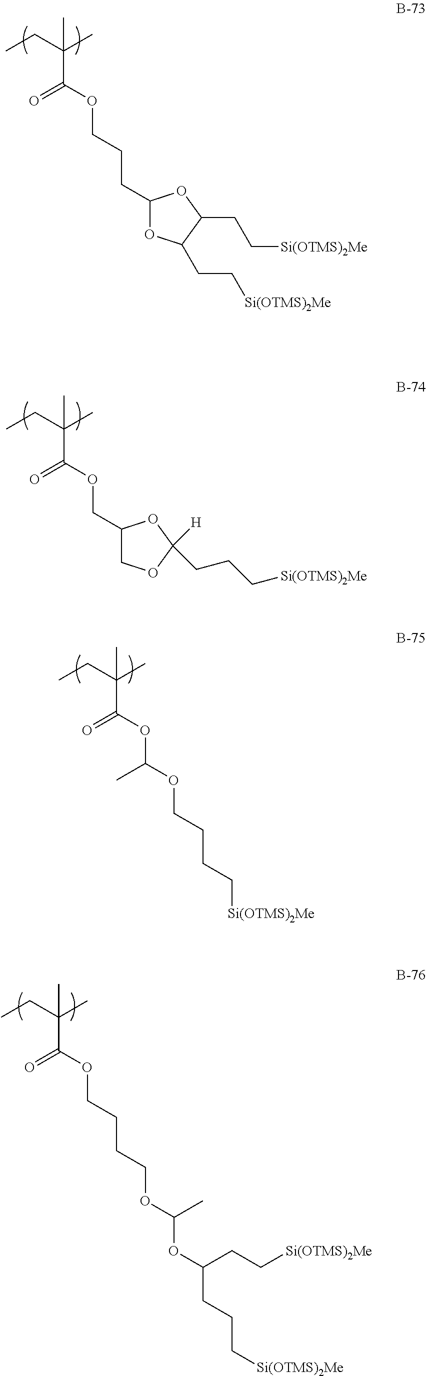

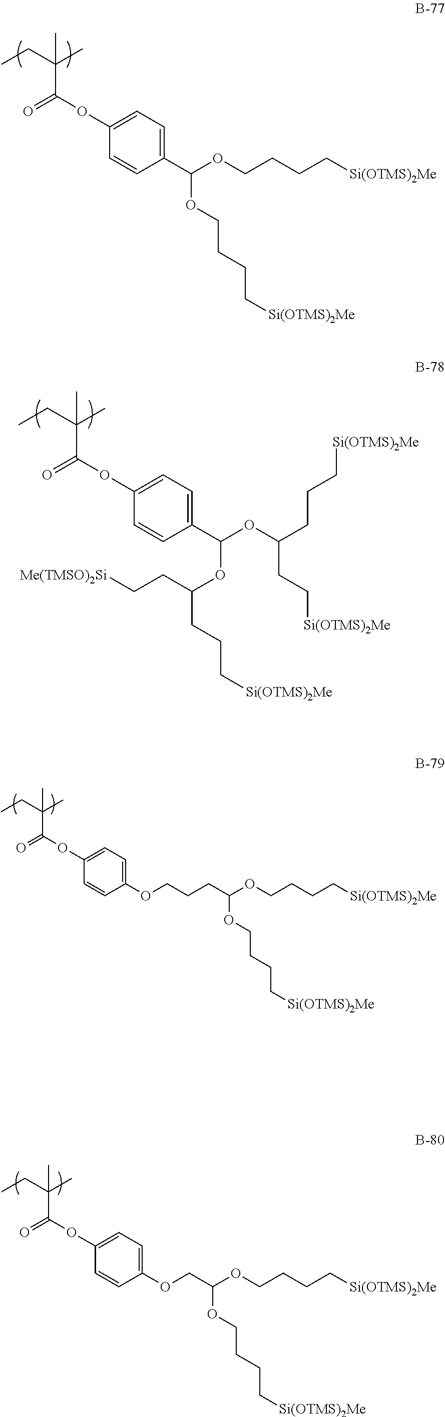

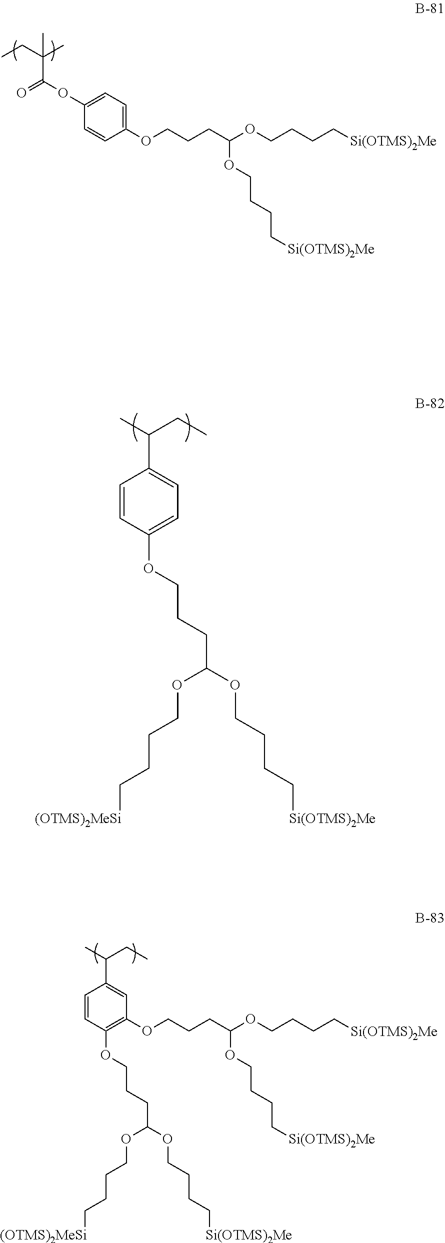

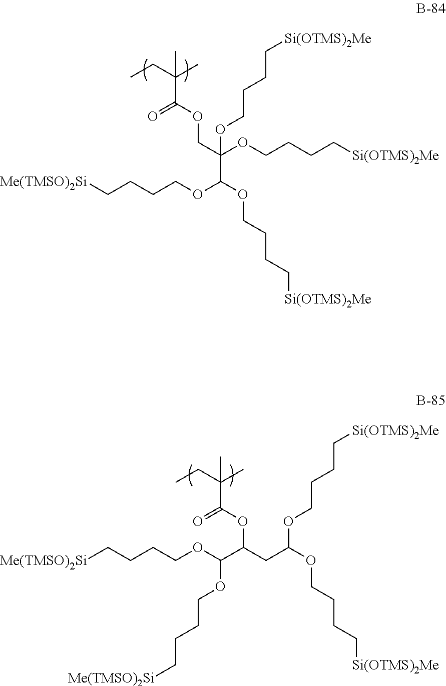

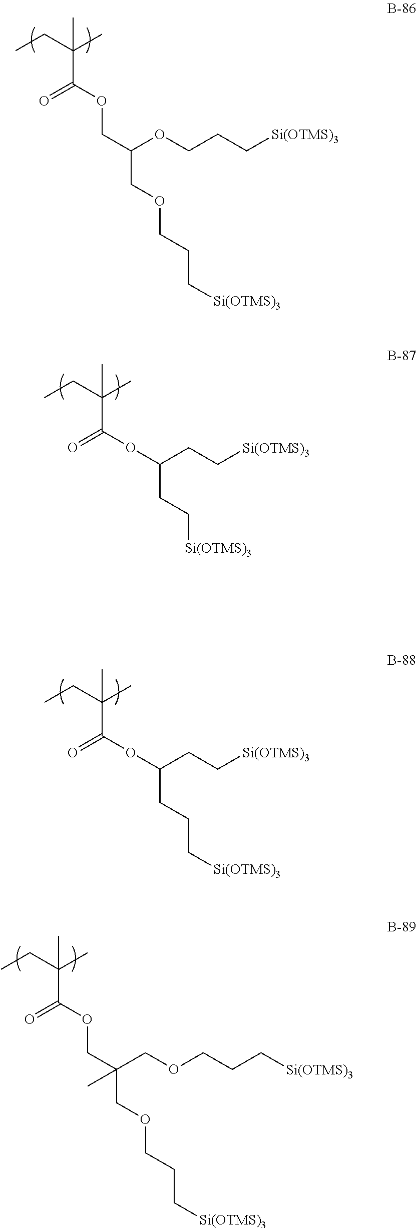

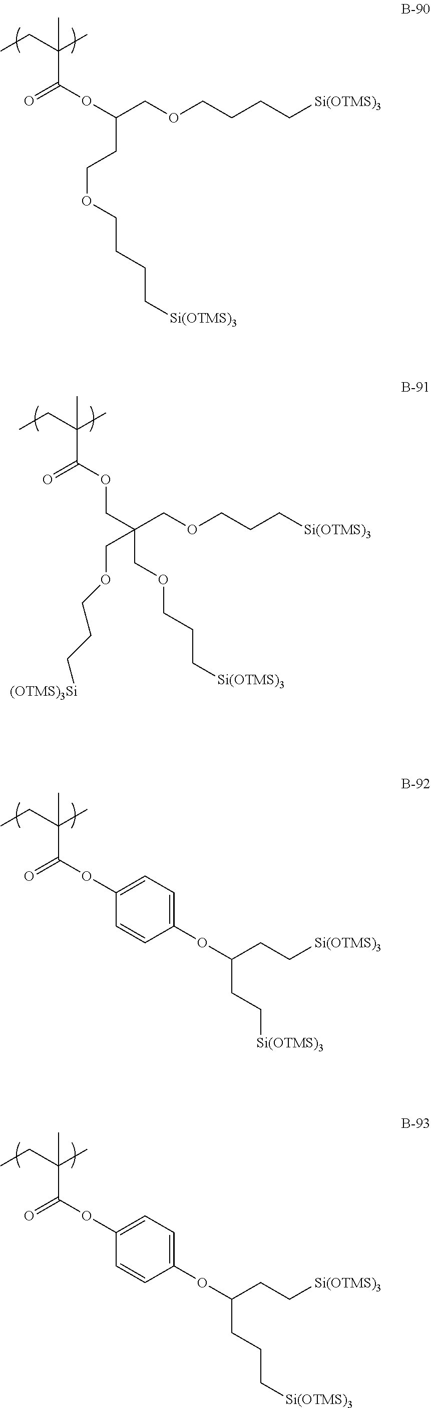

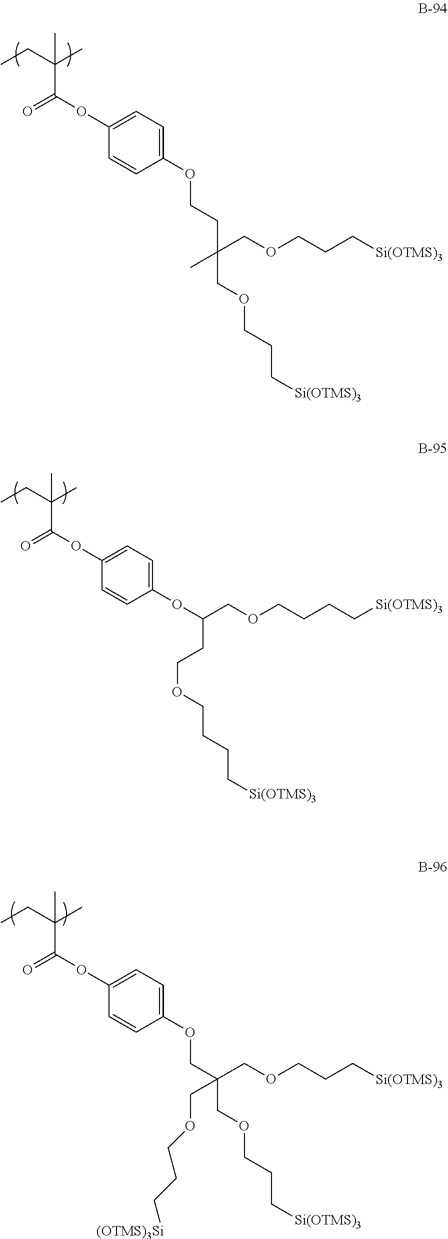

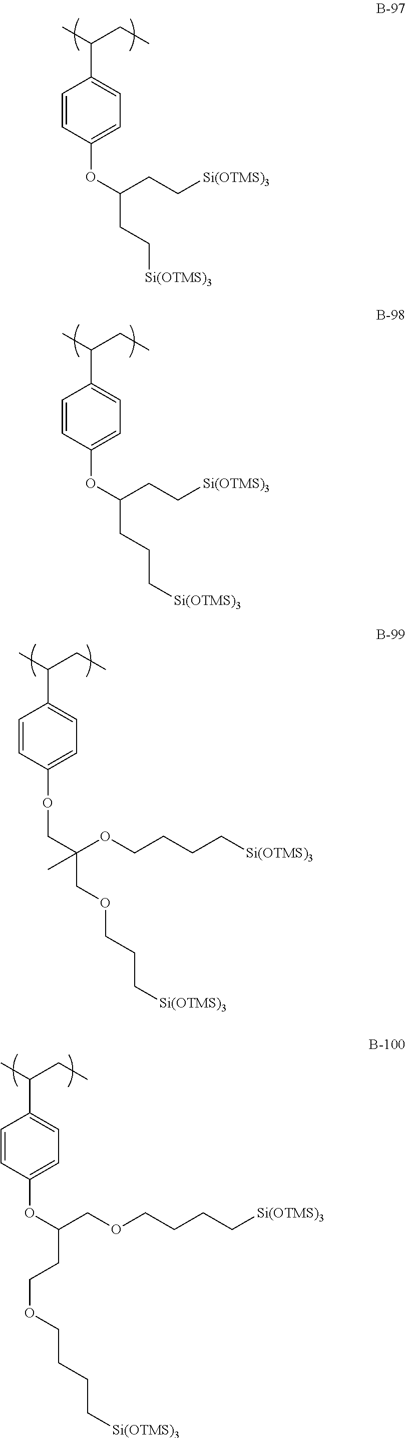

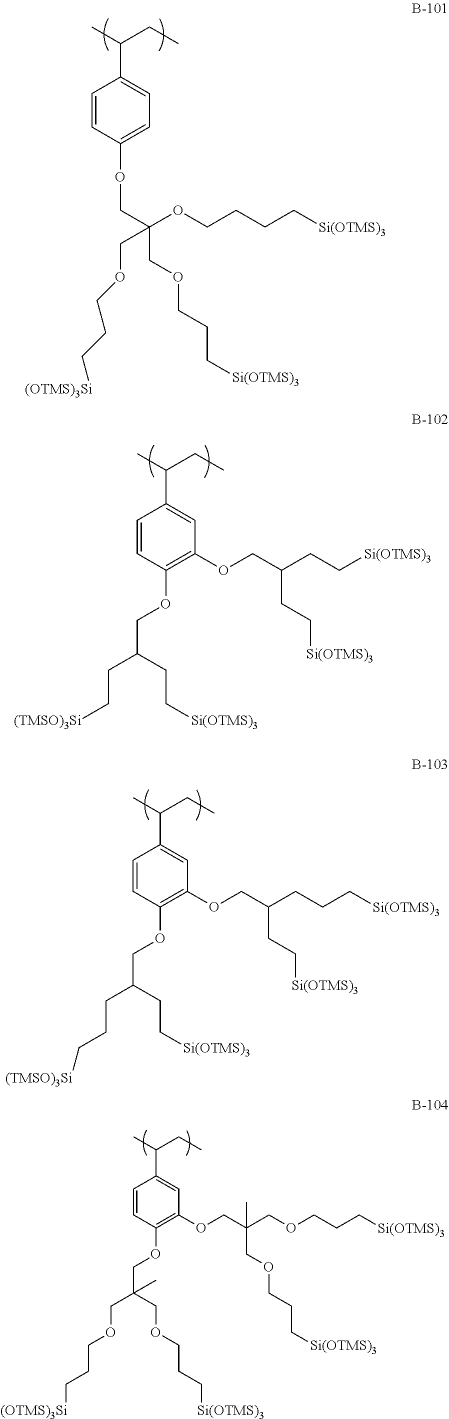

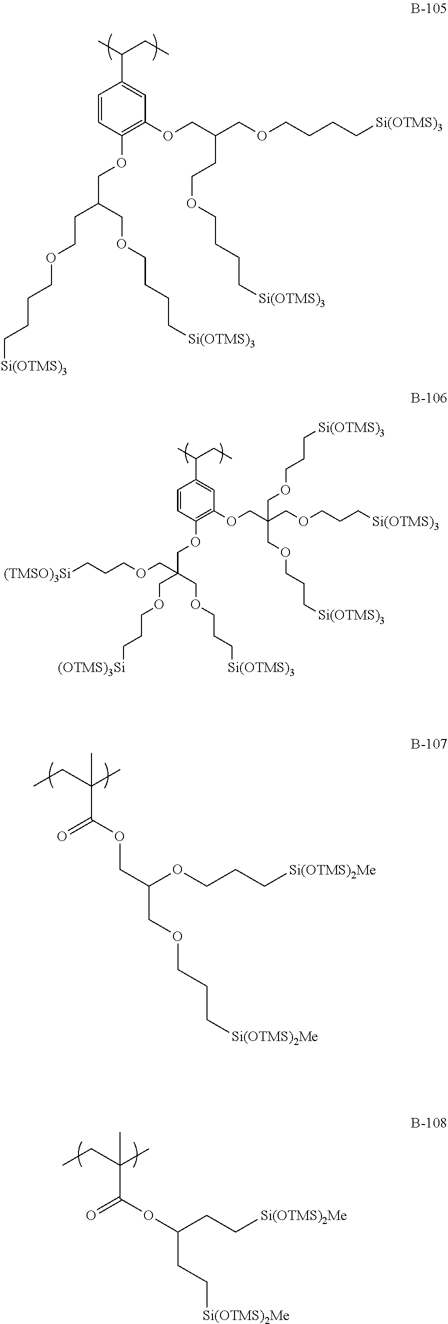

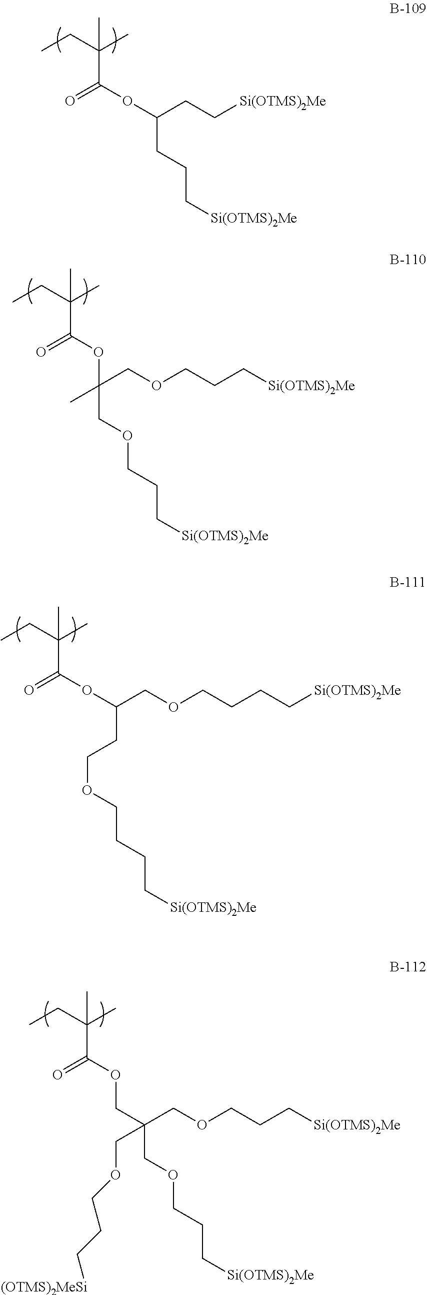

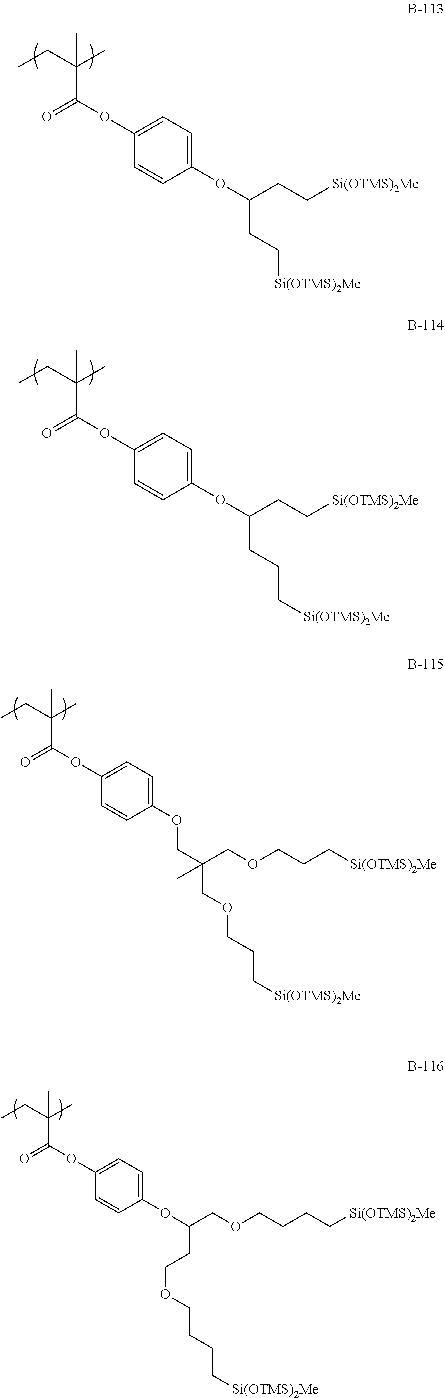

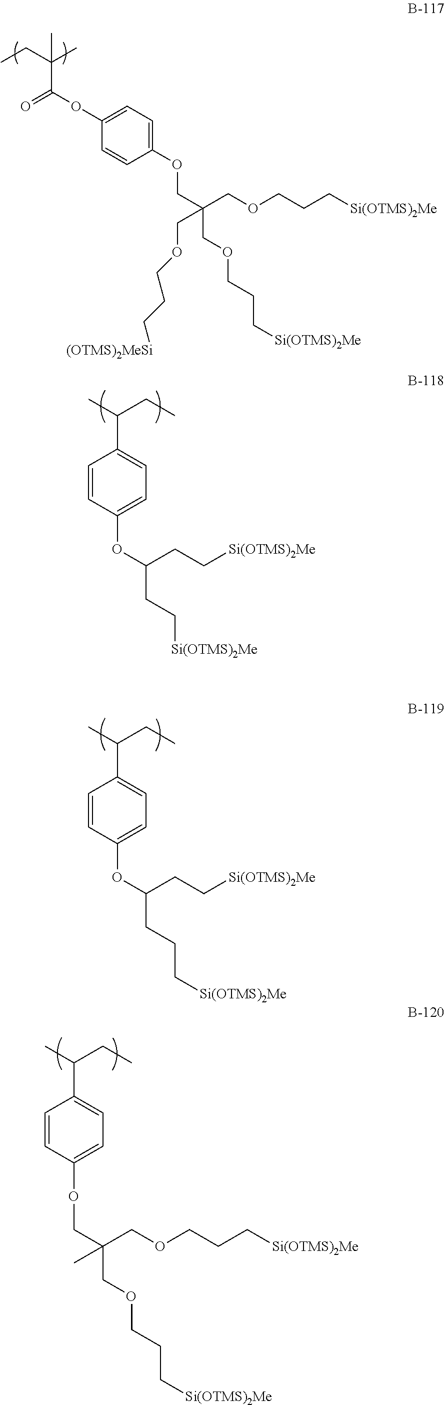

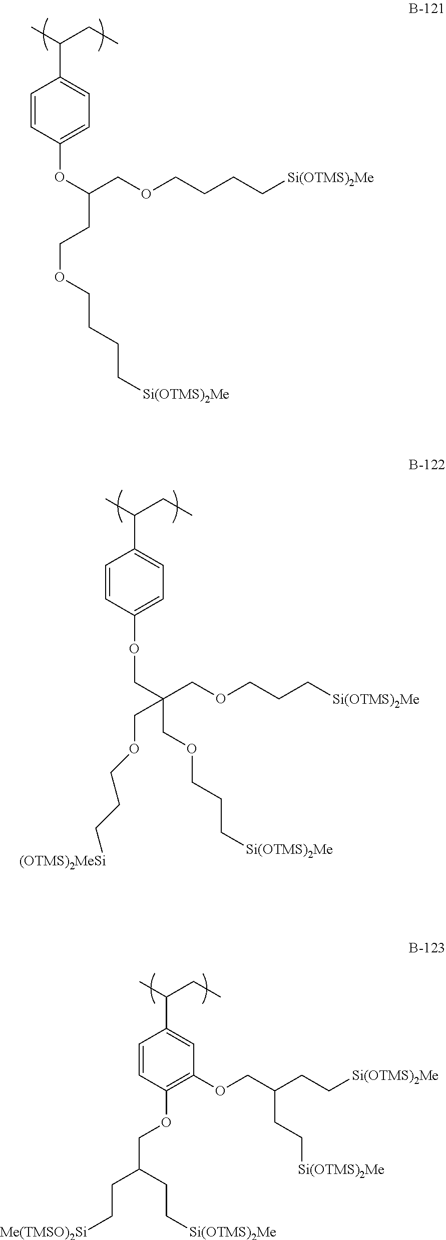

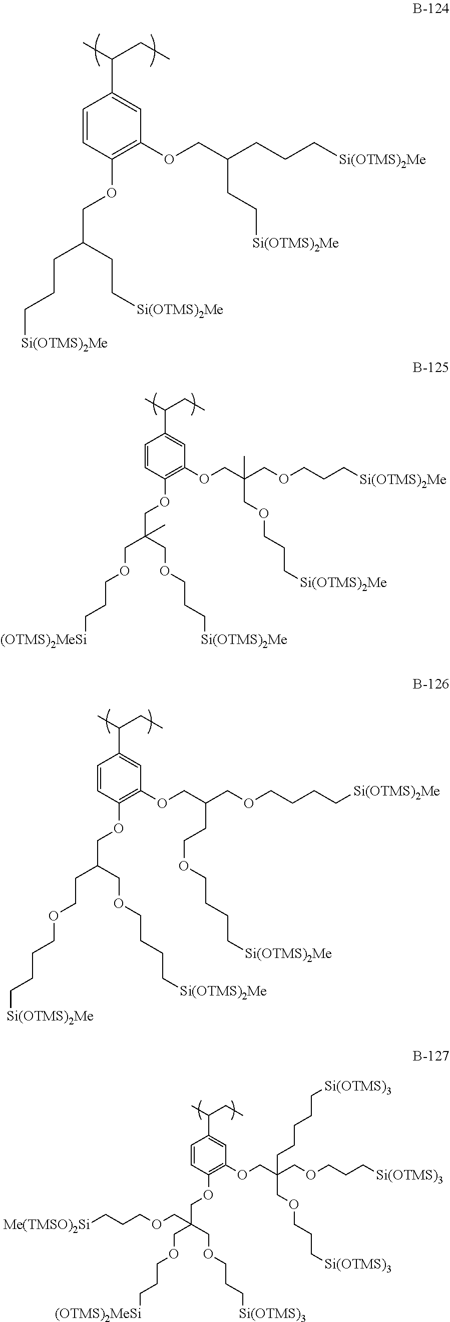

A content of the repeating unit B in the photo-alignment polymer of the present invention is preferably 5% to 60% by mass, and more preferably 10% to 50% by mass with respect to all the repeating units of the photo-alignment polymer.

In a case where the repeating unit B is the repeating unit BP, the content of the repeating unit represented by Formula (1) in the photo-alignment polymer of the present invention is preferably 50% to 99.99% by mass, more preferably 60% to 99% by mass, and still more preferably 70% to 95% by mass with respect to the total mass of the repeating unit BP.

### [Repeating Unit C]

The photo-alignment polymer of the present invention preferably includes the repeating unit C having a crosslinkable group from the viewpoint that the liquid crystal alignment properties are further improved due to the effect of suppressing alignment relaxation by improving solvent resistance.

The type of the crosslinkable group is not particularly limited, and examples thereof include known crosslinkable groups. Among these, from the viewpoint of excellent adhesiveness to the upper layer disposed on a binder layer, a cationically polymerizable group or a radically polymerizable group is preferable.

Examples of the cationically polymerizable group include an epoxy group, an epoxycyclohexyl group, and an oxetanyl group.

Examples of the radically polymerizable group include an acryloyl group, a methacryloyl group, a vinyl group, a styryl group, and an allyl group, and a group represented by Formula (C4) is preferable.

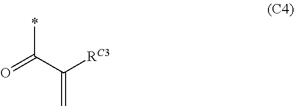

In Formula (C4), * represents a bonding position.

R^{c3} represents a hydrogen atom or a methyl group.

The structure of the main chain of the repeating unit C having a crosslinkable group is not particularly limited, and examples thereof include known structures.

Among these, as the structure of the main chain of the repeating unit C having a crosslinkable group, a skeleton selected from the group consisting of a (meth)acrylic skeleton, a styrene-based skeleton, a siloxane-based skeleton, a cycloolefin-based skeleton, a methylpentene-based skeleton, an amide-based skeleton, and an aromatic ester-based skeleton is preferable, a skeleton selected from the group consisting of a (meth)acrylic skeleton, a siloxane-based skeleton, and a cycloolefin-based skeleton is more preferable, and a (meth)acrylic skeleton is still more preferable.

From the reason that the liquid crystal alignment properties are further improved, the repeating unit having a crosslinkable group is preferably a repeating unit represented by Formula (C).

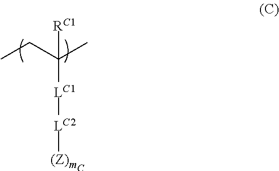

In Formula (C), R^{C1} represents a hydrogen atom or a substituent.

L^{C1} represents a single bond or a divalent linking group.

L^{C2} represents an (m_{C}+1)-valent linking group.

Z represents a crosslinkable group.

m_{C} represents an integer of 1 or more. In a case where m_{C} is an integer of 2 or more, a plurality of Z's may be the same as or different from each other.

The type of the substituent represented as one aspect of R^{C1} is not particularly limited, examples thereof include known substituents, specifically groups exemplified for the substituent represented as one aspect of R^{A1} in Formula (A) described above. Among these, an alkyl group having 1 to 6 carbon atoms is preferable, and methyl is more preferable.

Examples of the divalent linking group represented by one aspect of Le include those exemplified as the divalent linking group represented by one aspect of L^{A1} in Formula (A).

Among these, as the divalent linking group represented by one aspect of L_{C1}, from the viewpoint of further improving the liquid crystal alignment properties, a divalent linking group obtained by combining at least two (preferably 2 to 8) groups selected from the group consisting of a linear alkylene group having 1 to 10 carbon atoms, which may have a substituent, a branched or cyclic alkylene group having 3 to 10 carbon atoms, which may have a substituent, an arylene group having 6 to 12 carbon atoms, which may have a substituent, —O—, —CO—, and —N(Qc)- is preferable, and —CO—O— is more preferable. Qc represents a hydrogen atom or a substituent.

The definition of each specific group of the divalent linking group represented by one aspect of L^{C1} is the same as the definition of each group described in the divalent linking group represented by L^{A1} described above.

From the viewpoint of further improving the liquid crystal alignment properties, the (m_{C}+1)-valent linking group represented by L^{C2} is preferably an (m_{C}+1)-valent hydrocarbon group having 1 to 24 carbon atoms, which may have a substituent, and may be a hydrocarbon group in which some of the carbon atoms constituting the hydrocarbon group may be substituted with heteroatoms, more preferably an aliphatic hydrocarbon group which may contain an oxygen atom or a nitrogen atom and has 1 to 10 carbon atoms, and still more preferably an aliphatic hydrocarbon group having 1 to 5 carbon atoms.

The number of carbon atoms included in the (m_{C}+1)-valent linking group is not particularly limited, and from the reason that the liquid crystal alignment properties are further improved, the number of carbon atoms is preferably 1 to 24, more preferably 1 to 10, and still more preferably 1 to 5.

Z represents a crosslinkable group. The definition of the crosslinkable group is as described above.

As mₑ, from the reason that the liquid crystal alignment properties are further improved, an integer of 1 to 5 is preferable, an integer of 1 to 3 is more preferable, and 1 is still more preferable.

Examples of the repeating unit C having a crosslinkable group include the following repeating units.

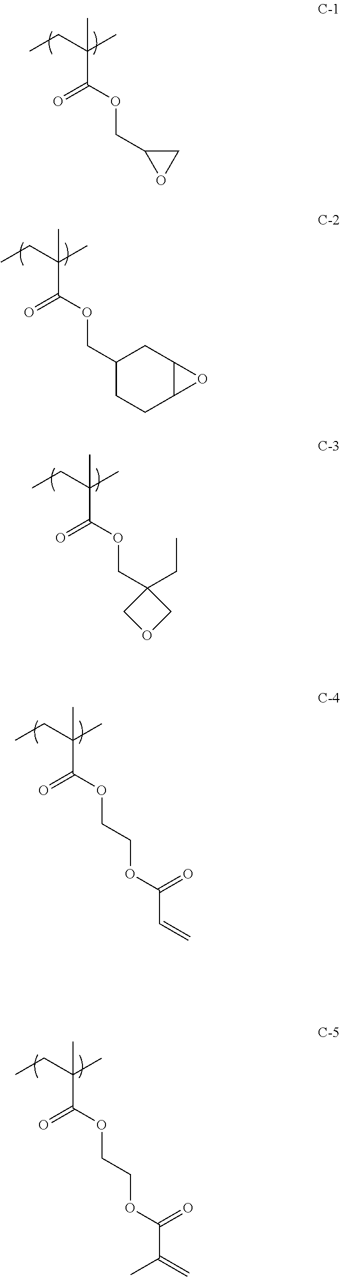

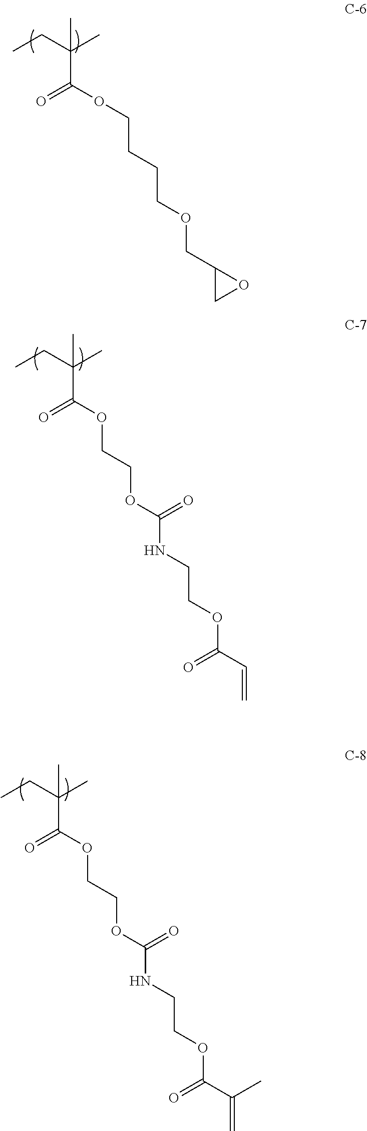

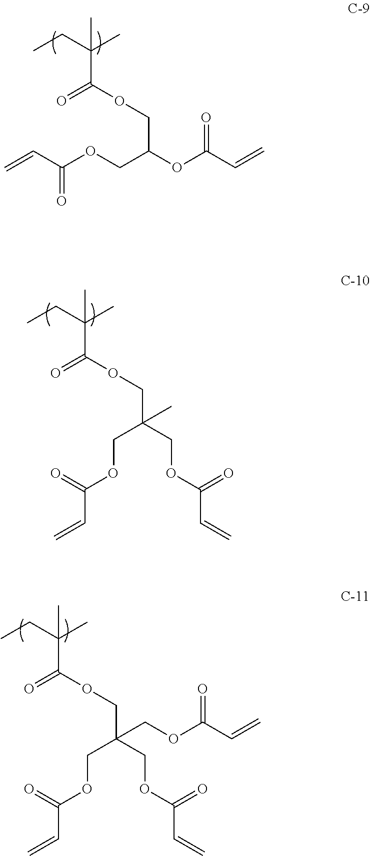

From the viewpoint of further improving the liquid crystal alignment properties, the content of any repeating unit C in the photo-alignment polymer of the present invention is preferably in a range of 10% to 60% by mass and more preferably in a range of 20% to 60% by mass with respect to all the repeating units of the photo-alignment polymer.

The photo-alignment polymer of the present invention may include other repeating units in addition to the above-described repeating units.

Examples of a monomer (radically polymerizable monomer) forming a repeating unit other than the above-described repeating units include an acrylic acid ester compound, a methacrylic acid ester compound, a maleimide compound, an acrylamide compound, acrylonitrile, maleic acid anhydride, a styrene compound, and a vinyl compound.

As the photo-alignment polymer of the present invention, a photo-alignment polymer including a repeating unit represented by Formula (A) or a repeating unit represented by Formula (AK2) is also preferable.

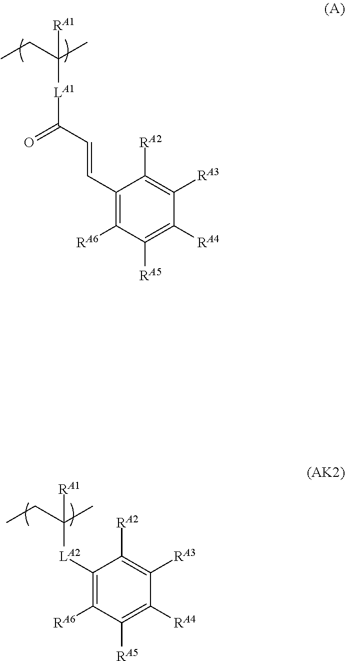

In Formula (A) and Formula (AK2), R^{A1}'s each independently represent a hydrogen atom or a substituent.

L^{A}1 and L^{A2} each independently represent a single bond or a divalent linking group.

R^{A2}, R^{A3}, R^{A4}, R^{A5}, and R^{A6} each independently represent a hydrogen atom or a substituent. Two adjacent groups of R^{A2}, R^{A3}, R^{A4}, R^{A5}, and R^{A6} may be bonded to each other to form a ring.

However, at least one of R^{A2}, . . . , or R^{A6} in Formula (A) is a substituent having -L¹¹-(Rh)ₙ.

However, at least one of R^{A2}, . . . , or R^{A6} in Formula (AK2) is a substituent having —CH═CH—CO—O-L¹¹-(Rh)ₙ or —CH═CH—CO—NH-L¹¹-(Rh)ₙ.

L¹¹ represents a single bond or an (n+1)-valent linking group. However, in a case where there are a plurality of L¹¹'s, the plurality of L¹¹'s may be the same as or different from each other.

n represents an integer of 1 to 4. However, in a case where there are a plurality of n's, the plurality of n's may be the same as or different from each other.

Rh represents the above-described substituent having two or more groups represented by Formula (S). However, in a case where there are a plurality of Rh's, the plurality of Rh's may be the same as or different from each other.

The definitions and preferred aspects of the respective notations in Formula (A) and Formula (AK2) are as described above.

The method for synthesizing the photo-alignment polymer of the embodiment of the present invention is not particularly limited, and for example, the photo-alignment polymer can be synthesized by mixing the monomer forming the above-described repeating unit A and the monomer forming the above-described repeating unit B, and polymerizing the mixture in an organic solvent using a radical polymerization initiator.

The weight-average molecular weight (Mw) of the photo-alignment polymer of the present invention is not particularly limited, and is preferably in a range of 10,000 to 500,000, more preferably in a range of 10,000 to 300,000, and still more preferably in a range of 30,000 to 150,000 from the viewpoint of further improving the liquid crystal alignment properties.

Here, in the present invention, the weight-average molecular weight and the number-average molecular weight are values measured by gel permeation chromatography (GPC) under the following conditions.
Solvent (eluent): tetrahydrofuran
Device name: TOSOH HLC-8320GPC
Column: Use three TOSOH TSKgel Super HZM-H (4.6 mm×15 cm) connected in series
Column Temperature: 40° C.
Sample Concentration: 0.1 mass %
Flow Rate: 1.0 ml/min
Calibration Curve: Use a calibration curve made by 7 samples of TSK standard polystyrene manufactured by TOSOH Corporation, Mw of which is 2800000 to 1050 (Mw/Mn=1.03 to 1.06)

### [Binder Composition]

The binder composition according to the embodiment of the present invention is a composition including the photo-alignment polymer according to the embodiment of the present invention and a binder.

Here, a content of the photo-alignment polymer included in the binder composition according to the embodiment of the present invention is preferably 0.1 to 10 parts by mass, and more preferably 0.5 to 7 parts by mass with respect to 100 parts by mass of the binder described later.

The type of the binder included in the binder composition according to the embodiment of the present invention is not particularly limited. The binder itself maybe a resin (hereinafter, also referred to as a “resin binder”) which is formed only of a resin having no polymerization reactivity and simply dried and solidified, or a polymerizable compound.

In addition, it is preferable that the binder is different from the above-described photo-alignment polymer.

### [Resin Binder]

Examples of the resin binder include an epoxy resin, a diallyl phthalate resin, a silicone resin, a phenol resin, an unsaturated polyester resin, a polyimide resin, a polyurethane resin, a melamine resin, an urea resin, an ionomer resin, an ethylene ethyl acrylate resin, an acrylonitrile acrylate styrene copolymer resin, an acrylonitrile styrene resin, an acrylonitrile chloride polyethylene styrene copolymer resin, an ethylene-vinyl acetate resin, an ethylene vinyl alcohol copolymer resin, an acrylonitrile butadiene styrene copolymer resin, a vinyl chloride resin, a chlorinated polyethylene resin, a polyvinylidene chloride resin, a cellulose acetate resin, a fluororesin, a polyoxymethylene resin, a polyamide resin, a polyarylate resin, a thermoplastic polyurethane elastomer, a polyether ether ketone resin, a polyether sulfone resin, polyethylene, polypropylene, a polycarbonate resin, polystyrene, a polystyrene maleic acid copolymer resin, a polystyrene acrylic acid copolymer resin, a polyphenylene ether resin, a polyphenylene sulfide resin, a polybutadiene resin, a polybutylene terephthalate resin, an acrylic resin, a methacrylic resin, a methylpentene resin, a polylactic acid, a polybutylene succinate resin, a butyral resin, a formal resin, polyvinyl alcohol, polyvinylpyrrolidone, ethyl cellulose, carboxymethyl cellulose, gelatin, and a copolymer resin thereof.

### [Polymerizable Compound]

Examples of the polymerizable compound include an epoxy-based monomer, a (meth)acrylic monomer, and an oxetanyl-based monomer, and an epoxy-based monomer or a (meth)acrylic monomer is preferable.

In addition, a polymerizable liquid crystal compound or a urethane acrylate monomer may be used as the polymerizable compound.

Examples of an epoxy group-containing monomer which is the epoxy-based monomer include a bisphenol A epoxy resin, a bisphenol F epoxy resin, a brominated bisphenol A epoxy resin, a bisphenol S epoxy resin, a diphenyl ether epoxy resin, a hydroquinone epoxy resin, a naphthalene epoxy resin, a biphenyl epoxy resin, a fluorene epoxy resin, a phenol novolac epoxy resin, an orthocresol novolac epoxy resin, a trishydroxyphenylmethane epoxy resin, a trifunctional epoxy resin, a tetraphenylolethane epoxy resin, a dicyclopentadiene phenol epoxy resin, a hydrogenated bisphenol A epoxy resin, a bisphenol A nucleus-containing polyol epoxy resin, a polypropylene glycol epoxy resin, a glycidyl ester epoxy resin, a glycidylamine epoxy resin, a glyoxal epoxy resin, an alicyclic epoxy resin, and a heterocyclic epoxy resin.

Examples of an acrylic monomer and a methacrylic monomer, which are the (meth)acrylic monomer, include trifunctional monomers such as trimethylolpropane triacrylate, trimethylolpropane propylene oxide (PO)-modified triacrylate, trimethylolpropane ethylene oxide (EO)-modified triacrylate, trimethylolpropane trimethacrylate, and pentaerythritol triacrylate. In addition, examples thereof further include tetrafunctional or higher-functional monomers such as pentaerythritol tetraacrylate, pentaerythritol tetramethacrylate, dipentaerythritol pentaacrylate, dipentaerythritol pentamethacrylate, dipentaerythritol hexaacrylate, and dipentaerythritol hexamethacrylate.

The polymerizable liquid crystal compound is not particularly limited, and examples thereof include a compound in which any one of homeotropic alignment, homogeneous alignment, hybrid alignment, or cholesteric alignment can be performed.

Here, in general, liquid crystal compounds can be classified into a rod-like type and a disk-like type according to the shape thereof. Furthermore, each type includes a low-molecular-type and a high-molecular-type. The term high molecular generally refers to a compound having a degree of polymerization of 100 or more (Polymer Physics-Phase Transition Dynamics, written by Masao Doi, p. 2, published by Iwanami Shoten, 1992).

In the present invention, any liquid crystal compound can be used, and a rod-like liquid crystal compound or a discotic liquid crystal compound (disk-like liquid crystal compound) is preferable. In addition, a liquid crystal compound which is a monomer or has a relatively low molecular weight with a degree of polymerization of less than 100 is preferable.

In addition, examples of the polymerizable group of the polymerizable liquid crystal compound include an acryloyl group, a methacryloyl group, an epoxy group, and a vinyl group.

By polymerizing such a polymerizable liquid crystal compound, the alignment of the liquid crystal compound can be immobilized. After immobilizing the liquid crystal compound by polymerization, it is no longer necessary to exhibit liquid crystallinity.

As the rod-like liquid crystal compound, for example, compounds described in claim 1 of JP1999-513019A (JP-H11-513019A) or paragraphs [0026] to [0098] of JP2005-289980A are preferable, and as the discotic liquid crystal compound, for example, compounds described in paragraphs [0020] to [0067] of JP2007-108732A or paragraphs [0013] to [0108] of JP2010-244038A are preferable.

A liquid crystal compound having reverse wavelength dispersibility can be used as the above-described polymerizable liquid crystal compound.

Here, in the present specification, the liquid crystal compound having “reverse wavelength dispersibility” denotes that in the measurement of an in-plane phase difference (Re) value at a specific wavelength (visible light range) of a phase difference film manufactured using the liquid crystal compound, the Re value is the same or increased as the measurement wavelength increases.

The liquid crystal compound having reverse wavelength dispersibility is not particularly limited as long as a film having reverse wavelength dispersibility can be formed as described above, and examples thereof include compounds represented by Formula (I) described in JP2008-297210A (particularly, compounds described in paragraphs [0034] to [0039]), compounds represented by Formula (1) described in JP2010-084032A (particularly, compounds described in paragraphs [0067] to [0073]), and compounds represented by Formula (1) described in JP2016-081035A (particularly, compounds described in paragraphs [0043] to [0055]).

Further examples include the compounds described in paragraphs [0027] to [0100] of JP2011-006360A, paragraphs [0028] to [0125] of JP2011-006361A, paragraphs [0034] to [0298] of JP2012-207765A, paragraphs [0016] to [0345] of JP2012-077055A, paragraphs [0017] to [0072] of WO2012/141245A, paragraphs [0021] to [0088] of WO2012/147904A, and paragraphs [0028] to [0115] of WO2014/147904A.

The binder composition according to the embodiment of the present invention may include other components in addition to the photo-alignment polymer and the binder described above.

### [Polymerization Initiator]

In a case where the photo-alignment polymer includes the repeating unit C or in a case where a polymerizable compound is used as the binder, it is preferable that the binder composition according to the embodiment of the present invention further includes a polymerization initiator.

The polymerization initiator is not particularly limited, and examples thereof include a thermal polymerization initiator and a photopolymerization initiator depending on the method of a polymerization reaction.

The polymerization initiator is preferably a photopolymerization initiator capable of initiating a polymerization reaction by ultraviolet irradiation.

Examples of the photopolymerization initiator include an α-carbonyl compound, acyloin ether, an α-hydrocarbon-substituted aromatic acyloin compound, a polynuclear quinone compound, a combination of a triarylimidazole dimer and p-aminophenyl ketone, acridine and a phenazine compound, an oxadiazole compound and an acylphosphine oxide compound, and an oxime ester compound.

### [Solvent]

From the viewpoint of workability of forming a binder layer, the binder composition according to the embodiment of the present invention preferably contains a solvent.

Examples of the solvent include ketones (for example, acetone, 2-butanone, methyl isobutyl ketone, cyclopentanone, and cyclohexanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide).

### [Binder Layer]

A binder layer according to the embodiment of the present invention is formed of the above-described binder composition according to the embodiment of the present invention, and is a layer in which a surface has an alignment controllability. More specifically, the binder layer is a layer formed by subjecting a coating film of a binder composition to a photo-alignment treatment.

That is, it is preferable that the method of forming the binder layer includes a step (step 1) of subjecting a coating film formed of the above-described binder composition to a photo-alignment treatment to form a binder layer.

The expression “has an alignment controllability” means having a function of aligning the liquid crystal compound disposed on the binder layer in a predetermined direction.

In a case where the binder composition includes a polymerizable compound or a photo-alignment polymer including the repeating unit C, in the above-described step 1, it is preferable that a coating film obtained using the binder composition is subjected to a curing treatment and then a photo-alignment treatment to form a binder layer.

Hereinafter, the method of performing the above-described curing treatment will be described in detail.

The method of forming a coating film of the binder composition is not particularly limited, and examples thereof include a method including performing coating on a support with the binder composition and optionally performing a drying treatment.

The support will be described in detail later.

In addition, an alignment layer may be disposed on the support.

The method of performing coating with the binder composition is not particularly limited, and examples of the coating method include a spin coating method, an air knife coating method, a curtain coating method, a roller coating method, a wire bar coating method, a gravure coating method, and a die coating method.

Next, the coating film of the binder composition is subjected to a curing treatment. Examples of the curing treatment include a light irradiation treatment and a heating treatment.

The conditions of the curing treatment are not particularly limited, and ultraviolet rays are preferably used in polymerization by light irradiation. An irradiation amount is preferably 10 mJ/cm² to 50 J/cm², more preferably 20 mJ/cm² to 5 J/cm², still more preferably 30 mJ/cm² to 3 J/cm², and particularly preferably 50 to 1000 mJ/cm². In order to promote the polymerization reaction, the treatment may be performed under heating conditions.

The method for the photo-alignment treatment to be performed on the coating film of the binder composition formed as described above (including a cured film of the binder composition subjected to the curing treatment) is not particularly limited, and examples thereof include known methods.

Examples of the photo-alignment treatment include a method of irradiating the coating film of the binder composition (including the cured film of the binder composition subjected to the curing treatment) with polarized light or irradiating the surface of the coating film with unpolarized light from an oblique direction.

In the photo-alignment treatment, the polarized light to be irradiated is not particularly limited. Examples thereof include linearly polarized light, circularly polarized light, and elliptically polarized light, and linearly polarized light is preferable.

In addition, the “oblique direction” in which irradiation with unpolarized light is performed is not particularly limited as long as it is a direction inclined at a polar angle θ (0°<θ<90°) with respect to a normal direction of the surface of the coating film. θ can be appropriately selected according to the purpose, and is preferably 20° to 80°.

The wavelength of polarized light or unpolarized light is not particularly limited as long as it is light that is exposed to the photo-aligned group of the photo-alignment polymer, and examples thereof include ultraviolet rays, near-ultraviolet rays, and visible rays. Among these, near-ultraviolet rays having a wavelength of 250 to 450 nm are preferable.

In addition, examples of a light source for the irradiation with polarized light or unpolarized light include a xenon lamp, a high-pressure mercury lamp, an ultra-high pressure mercury lamp, and a metal halide lamp. By using an interference filter, a color filter, or the like with respect to ultraviolet rays or visible rays obtained from the light source, the wavelength range of the irradiation can be restricted. In addition, linearly polarized light can be obtained by using a polarization filter or a polarization prism with respect to the light from the light source.

An integrated quantity of the polarized light or the unpolarized light is not particularly limited, and is preferably 1 to 300 mJ/cm² and more preferably 5 to 100 mJ/cm². An illuminance of the polarized light or the unpolarized light is not particularly limited, and is preferably 0.1 to 300 mW/cm² and more preferably 1 to 100 mW/cm².

In the above description, the aspect in which the curing treatment is performed before the photo-alignment treatment has been described, but the present invention is not limited to this aspect, and the curing treatment may be performed at the same time as the photo-alignment treatment.

A thickness of the binder layer is not particularly limited, but from the reason that the liquid crystal alignment properties are further improved, the thickness thereof is preferably 0.1 to 10 m and more preferably 0.3 to 3 μm.

### [Optical Laminate]

An optical laminate according to the embodiment of the present invention has the binder layer according to the embodiment of the present invention and an optically-anisotropic layer provided on the binder layer.

A suitable aspect of the optical laminate according to the embodiment of the present invention is that the optically-anisotropic layer provided on the binder layer is formed of a polymerizable liquid crystal composition containing a polymerizable liquid crystal compound, and the binder layer and the optically-anisotropic layer are laminated adjacent to each other.

In addition, the optical laminate according to the embodiment of the present invention preferably has a support which supports the binder layer.

Hereinafter, suitable aspects of the optical laminate according to the embodiment of the present invention will be described in detail.

### [Support]

Examples of the support include a glass substrate and a polymer film.

Examples of the material for the polymer film include cellulose-based polymers; acrylic polymers having an acrylic ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile styrene copolymer; polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

A thickness of the support is not particularly limited, but is preferably 5 to 200 m, more preferably 10 to 100 m, and still more preferably 20 to 90 m.

In addition, the support is preferably peelable.

### [Binder Layer]

The binder layer is the above-described binder layer according to the embodiment of the present invention.

### [Optically-Anisotropic Layer]

The optically-anisotropic layer is preferably formed of a polymerizable liquid crystal composition containing a polymerizable liquid crystal compound.

Here, examples of the polymerizable liquid crystal composition for forming the optically-anisotropic layer include a composition obtained by blending the polymerizable liquid crystal compound, the polymerization initiator, the solvent, and the like described as optional components in the binder composition according to the embodiment of the present invention.

A thickness of the optically-anisotropic layer is not particularly limited, and is preferably 0.1 to 10 μm and more preferably 0.5 to 5 μm.

### [Optical Laminate Manufacturing Method]

The optical laminate manufacturing method according to the embodiment of the present invention is a method for producing the above-described suitable aspect of the optical laminate according to the embodiment of the present invention, and includes a step (step 1) of subjecting a coating film obtained using the above-described binder composition to a photo-alignment treatment to form a binder layer, and a step (step 2) of applying a polymerizable liquid crystal composition containing a polymerizable liquid crystal compound onto the binder layer to form an optically-anisotropic layer.

### [Step 1]

Step 1 is a step of subjecting a coating film formed of the above-described binder composition to a photo-alignment treatment to form a binder layer.

The procedure of Step 1 is as described above.

### [Step 2]

Step 2 is a step of performing coating on the binder layer with a polymerizable liquid crystal composition containing a polymerizable liquid crystal compound to form an optically-anisotropic layer.

The method of performing coating with the polymerizable liquid crystal composition is not particularly limited, and examples thereof include the coating method exemplified in Step 1.

Examples of the method of forming the optically-anisotropic layer include a method in which a coating film of the polymerizable liquid crystal composition is subjected to a heating treatment and then subjected to a curing treatment. The polymerizable liquid crystal compound can be aligned by the above-described heating treatment.

In the above description, the heating treatment and the curing treatment are separately performed. However, a method in which the curing treatment is performed under heating conditions may also be carried out.

In a case where the polymerizable liquid crystal compound is aligned without performing the heating treatment depending on the type of the polymerizable liquid crystal compound, the heating treatment may not be performed.

After being heated, the coating film may be optionally cooled before the curing treatment described later.

The conditions of the heating treatment are not particularly limited, and the temperature may be adjusted so that the polymerizable liquid crystal compound is aligned. Usually, the heating temperature is preferably 30° C. to 100° C. and more preferably 50° C. to 80° C. The heating time is preferably 0.5 to 20 minutes, and more preferably 1 to 5 minutes.

The method for the curing treatment is not particularly limited. Examples thereof include a light irradiation treatment and a heating treatment, and a light irradiation treatment is preferable. Ultraviolet rays are preferable as light in the light irradiation treatment.

The conditions for a case where the light irradiation is performed are not particularly limited, and an irradiation amount is preferably 10 mJ/cm² to 50 J/cm², more preferably 20 mJ/cm² to 5 J/cm², and still more preferably 30 mJ/cm² to 3 J/cm².

In order to promote the polymerization reaction, the treatment may be performed under heating conditions.

### [Image Display Device]

The image display device according to the embodiment of the present invention is an image display device having the binder layer according to the embodiment of the present invention or the optical laminate according to the embodiment of the present invention.

A display element used in the image display device according to the embodiment of the present invention is not particularly limited, and examples thereof include a liquid crystal cell, an organic electroluminescence (hereinafter abbreviated as “EL”) display panel, and a plasma display panel.

Among these, a liquid crystal cell or an organic EL display panel is preferable, and a liquid crystal cell is more preferable. That is, the image display device according to the embodiment of the present invention is preferably a liquid crystal display device using a liquid crystal cell as a display element or an organic EL display device using an organic EL display panel as a display element.

### [Liquid Crystal Display Device]

A liquid crystal display device as an example of the image display device according to the embodiment of the present invention has the optically-anisotropic layer according to the present invention or the optical laminate according to the embodiment of the present invention described above, and a liquid crystal cell.

The liquid crystal cell used in a liquid crystal display device is preferably in a vertical alignment (VA) mode, an optically compensated bend (OCB) mode, an in-plane-switching (IPS) mode, a fringe-field switching (FFS) mode, or a twisted nematic (TN) mode, but the present invention is not limited thereto.

### [Organic EL Display Device]

Suitable examples of the organic EL display device as an example of the image display device according to the embodiment of the present invention include a device having an aspect in which it has a polarizer, the optically-anisotropic layer according to the present invention or the optical laminate according to the embodiment of the present invention, and an organic EL display panel in this order from the viewing side.

### [Polarizer]

The above-described polarizer is not particularly limited as long as it is a member having a function of converting light into specific linearly polarized light. An absorption-type polarizer or a reflective-type polarizer which has been known can be used.

Examples of the absorption-type polarizer include an iodine-based polarizer, a dye-based polarizer using a dichroic dye, and a polyene-based polarizer. The iodine-based polarizer and the dye-based polarizer include a coating-type polarizer and a stretching-type polarizer, and any of these is applicable.

Examples of the method of obtaining a polarizer by performing stretching and dyeing in a state in which a laminate film is obtained by forming a polyvinyl alcohol layer on a base material include JP5048120B, JP5143918B, JP4691205B, JP4751481B, and JP4751486B.

Examples of the reflective-type polarizer include a polarizer obtained by laminating thin films having different birefringences, a wire grid-type polarizer, and a polarizer obtained by combining a cholesteric liquid crystal having a selective reflection range and a ¼ wavelength plate.

Among these, from the viewpoint of more excellent adhesiveness, a polarizer including a polyvinyl alcohol-based resin (a polymer including —CH₂—CHOH— as a repeating unit, in particular, at least one selected from the group consisting of a polyvinyl alcohol and an ethylene-vinyl alcohol copolymer) is preferable.

A thickness of the polarizer is not particularly limited, and is preferably 3 to 60 m, more preferably 5 to 30 m, and still more preferably 5 to 15 m.

### [Organic EL Display Panel]

The organic EL display panel is a member in which a light emitting layer or a plurality of organic compound thin films including a light emitting layer is formed between a pair of electrodes of an anode and a cathode. In addition to the light emitting layer, a hole injection layer, a hole transport layer, an electron injection layer, an electron transport layer, a protective layer, and the like may be provided, and each of these layers may have a different function. Various materials can be used to form the respective layers.

### EXAMPLES

Hereinafter, the present invention will be described in more detail based on Examples.

Materials, used amounts, ratios, treatment contents, and treatment procedures shown in the following examples are able to be suitably changed unless the changes cause deviance from the gist of the invention. Therefore, the scope of the present invention is not to be construed as limiting by Examples shown below.

### [Raw Material Synthesis]

[Synthesis of mA-13]

mA-13 is a monomer from which the repeating unit A-13 is derived.

1,4-Cyclohexanediol (300 g), dibutylhydroxytoluene (0.6 g), 4-dimethylaminopyridine (31.6 g), triethylamine (248 g), and dimethylacetamide (400 mL) were stirred at room temperature for 30 minutes in a 2000 mL eggplant flask to obtain a reaction solution. The obtained reaction solution was cooled to 0° C., and methacrylic acid anhydride (398 g) was added dropwise thereto over 30 minutes. Thereafter, the mixture was stirred at room temperature for 3 hours, and 15 mass % saline (500 mL) was added thereto. Thereafter, the mixture was cooled to 30° C. in a water bath, hexane (500 mL) and ethyl acetate (2000 mL) were added thereto, and the mixture was subjected to liquid separation and washing. Furthermore, the obtained organic layer was subjected to liquid separation and washing using 15 mass % saline (2000 mL), 5 mass % sodium bicarbonate water (1000 mL), and ion exchange water (500 mL) in this order. The obtained organic layer was concentrated to obtain a mixture (336 g) of the mA-13 precursor and the dimethacrylate body as a light yellow liquid.

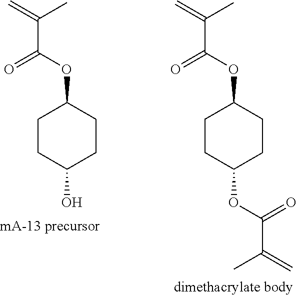 [SMILES: C=C(C)C(=O)O[C@H]1CC[C@H](O)CC1 ; C=C(C)C(=O)O[C@H]1CC[C@H](OC(=O)C(=C)C)CC1]

Next, (E)-3-[4-(octyloxy)phenyl]methacrylic acid (248 g), 4-dimethylaminopyridine (52 g), 1-ethyl-3-(3-dimethylaminopropyl) carbodiimide hydrochloride (246 g), mA-13 precursor (336 g), and dimethylacetamide (357 mL) were weighed in a 3,000 mL eggplant flask, heated to 50° C., and stirred for 3 hours. Methanol (1070 mL) was introduced three times at intervals of 5 minutes, and the temperature was lowered to an internal temperature of 30° C. over 1 hour. The mixture was stirred at 25° C. to 30° C. for 30 minutes, the precipitated target substance was separated by suction filtration, and the obtained crystals were dried in a blast dryer at 40° C. for 12 hours to obtain mA-13 (133 g).

Each of the monomers other than mA-13 was synthesized with reference to the above-described synthesis procedure of mA-13.

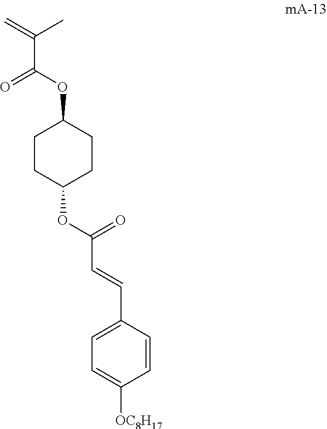

### Example 1

### [Synthesis of Photo-Alignment Polymer P-1]

Cyclopentanone (30 parts by mass) as a solvent, the following repeating units and respective monomers having the content thereof, and 2,2′-azobis(isobutyronitrile) (0.1 parts by mass) as a polymerization initiator were charged into a flask equipped with a cooling pipe, a thermometer, and a stirrer, and the mixture was stirred while maintaining a reflux state for 7 hours by heating in a water bath with nitrogen flowing into the flask at 15 mL/min.

After completion of the reaction, the mixture was allowed to cool to room temperature, the obtained polymer solution was poured into a large excess of methanol to precipitate a polymer, the recovered precipitate was separated by filtration, washed with a large amount of methanol, and then subjected to vacuum drying at 40° C. for 6 hours to obtain a photo-alignment polymer P-1.

### [Production of Optical Laminate]

### <Preparation of Cellulose Acylate Film (Substrate)>

As a support, a cellulose acylate film prepared by the following method was used.

### (Preparation of Core Layer Cellulose Acylate Dope)

The following various components were put into a mixing tank and stirred to dissolve the various components, thereby preparing a cellulose acetate solution used as a core layer cellulose acylate dope.

Core layer cellulose acylate dope

| | | |
|---|---|---|
| Cellulose acetate having acetyl substitution | 100 | parts by mass |
| degree of 2.88 | | |
| Polyester compound B (described in Examples of | 12 | parts by mass |
| JP2015-227955A) | | |
| Compound G | 2 | parts by mass |
| Methylene chloride (first solvent) | 430 | parts by mass |
| Methanol (second solvent) | 64 | parts by mass |

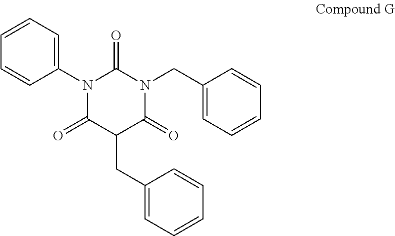 [SMILES: O=C1C(Cc2ccccc2)C(=O)N(c2ccccc2)C(=O)N1Cc1ccccc1]

### (Preparation of Outer Layer Cellulose Acylate Dope)

10 parts by mass of the matte agent solution was added to 90 parts by mass of the core layer cellulose acylate dope to prepare a cellulose acetate solution to be used as an outer layer cellulose acylate dope.

Matting agent solution

| | | |
|---|---|---|
| Silica particles with average particle size | 2 | parts by mass |
| of 20 nm(AEROSIL R972, manufactured by | | |
| NIPPON AEROSIL CO., LTD.) | | |
| Methylene chloride (first solvent) | 76 | parts by mass |
| Methanol (second solvent) | 11 | parts by mass |
| Core layer cellulose acylate dope | 1 | part by mass |
| described above | | |

The core layer cellulose acylate dope and the outer layer cellulose acylate dope were filtered through filter paper having an average hole diameter of 34 m and a sintered metal filter having an average pore size of 10 m, and three layers which were the core layer cellulose acylate dope and the outer layer cellulose acylate dopes provided on both sides of the core layer cellulose acylate dope were simultaneously cast from a casting port onto a drum at 20° C. (band casting machine).

Peeling was performed in the state where the solvent content was 20% by mass, and the both ends of the film in the width direction were fixed with a tenter clip and dried while stretching the film at a stretching ratio of 1.1 times in the transverse direction. Then, the obtained film was further dried by being transported between the rolls of a heat treatment device, thereby preparing an optical film having a thickness of 40 m, which was used as a cellulose acylate film.

In the obtained cellulose acylate film, the thickness of the core layer was 36 m and the thickness of each of the outer layers arranged on the both sides of the core layer was 2 m. The obtained cellulose acylate film had an in-plane retardation of 0 nm at a wavelength of 550 nm.

### <Formation of Binder Layer>

A binder composition having the following composition was prepared.

Binder Composition

| | | |
|---|---|---|
| The photo-alignment polymer P-1 | 6.5 | parts by mass |
| The following compound E-1 (binder) | 93.5 | parts by mass |
| The following thermal acid generator B | 0.6 | parts by mass |
| (polymerization initiator) | | |
| Diisopropylethylamine | 0.06 | parts by mass |
| Butyl acetate | 594.0 | parts by mass |
| Methyl Ethyl Ketone | 306.0 | parts by mass |

Compound E-1: polyorganosilsesquioxane compound (A) described in Examples of WO20/110966A

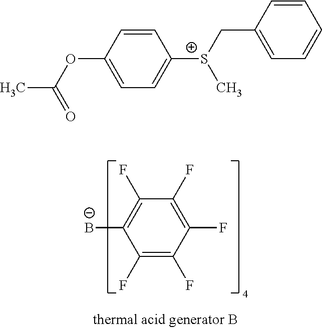

The binder composition was continuously applied onto the air interface of the cellulose acylate film with a Geeser coating machine. After the application, the coating film was dried in a heating zone at 130° C. for 1 minute to remove the solvent, thereby forming a coating film having a thickness of 0.5 m. Subsequently, the binder layer was formed by irradiating the layer with ultraviolet light (10 mJ/cm², light source: ultra-high pressure mercury lamp, measurement wavelength: 313 nm) through a wire grid polarizer. In this case, the transmission axis of the wire grid polarizer was set to an angle of 14° with respect to the film longitudinal direction.

### <Formation of Optically-Anisotropic Layer>

A coating liquid for forming an optically-anisotropic layer containing a disk-like liquid crystal compound having the following composition was applied onto the binder layer prepared above using a geeser coating machine to form a composition layer, thereby obtaining a film.

Thereafter, the obtained composition layer was heated with hot air for 2 minutes such that the temperature of the film was 90° C., for drying the solvent and aligning and aging the disk-like liquid crystal compound. Subsequently, the obtained composition layer was irradiated with ultraviolet rays (100 mJ/cm², light source: metal halide, measurement wavelength: 365 nm) at 80° C. to immobilize the alignment of the liquid crystal compound, thereby forming an optically-anisotropic layer.

A thickness of the optically-anisotropic layer A was 1.5 μm. In addition, the optically-anisotropic layer (4 h) had a retardation of 168 nm at a wavelength of 550 nm. It was confirmed that the average tilt angle of the disc plane of the disk-like liquid crystal compound with respect to the film surface was 90°, and the disk-like liquid crystal compound was aligned vertically to the film surface. In addition, the angle of the slow axis of the optically-anisotropic layer was −76° (perpendicular to the transmission axis of the wire grid polarizer) with respect to the film longitudinal direction.

Composition for forming optically-anisotropic layer

| | | |
|---|---|---|
| Disk-like liquid crystal compound 1 shown below | 80 | parts by mass |
| Disk-like liquid crystal compound 2 shown below | 20 | parts by mass |
| Alignment film interface alignment agent | 2.0 | parts by mass |
| 1 shown below | | |
| Fluorine-containing compound A shown below | 0.10 | parts by mass |
| Fluorine-containing compound B shown below | 0.09 | parts by mass |
| Fluorine-containing compound C shown below | 0.21 | parts by mass |
| Ethylene oxide-modified trimethylolpropane | 5 | parts by mass |
| triacrylate (V#360, manufactured by Osaka | | |
| Organic Chemical Industry Ltd.) | | |
| Photopolymerization initiator (IRGACURE 907, | 3.0 | parts by mass |
| manufactured by BASF SE) | | |
| Methyl ethyl ketone | 250 | parts by mass |

Disk-like Liquid Crystal Compound 1

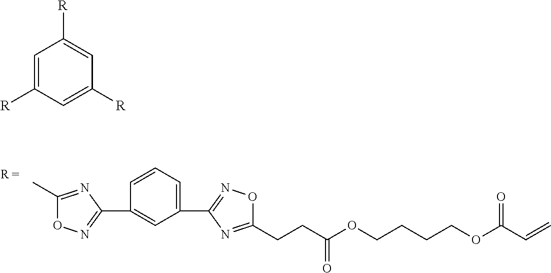

Disk-like Liquid Crystal Compound 2

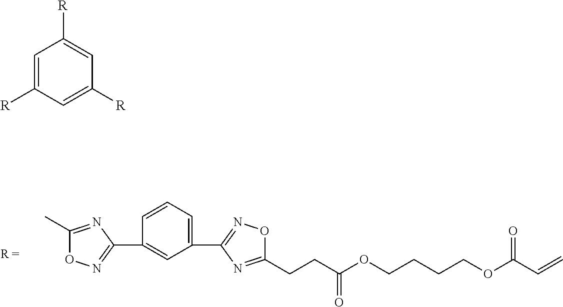

Alignment Film Interface Alignment Agent 1

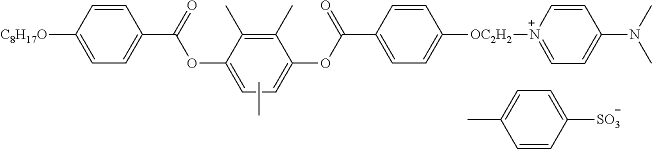

Fluorine-containing compound A (in the following formula, a and b represents a content (% by mass) of each repeating unit with respect to all repeating units, and a was 90% by mass and b was 10% by mass; in addition, a weight-average molecular weight was 15,000)

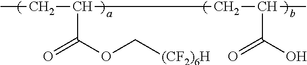

Fluorine-containing compound B (numerical value in each repeating unit represents a content (% by mass) with respect to all repeating units; in addition, a weight-average molecular weight was 12,500)

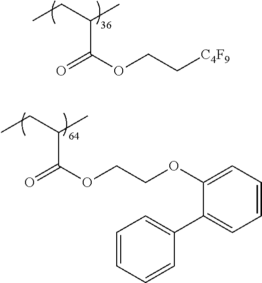

Fluorine-containing compound C (numerical value in each repeating unit represents a content (% by mass) with respect to all repeating units; in addition, a weight-average molecular weight was 12,500)

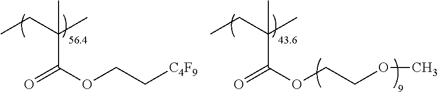

### Examples 2 to 9 and Comparative Examples 1 to 2

An optical laminate was prepared by the same method as in Example 1, except that the photo-alignment polymers P-2 to P-9 and the polymers H-1 and H-2 were used instead of the photo-alignment polymer P-1.

Hereinafter, the repeating units contained in each polymer are shown.

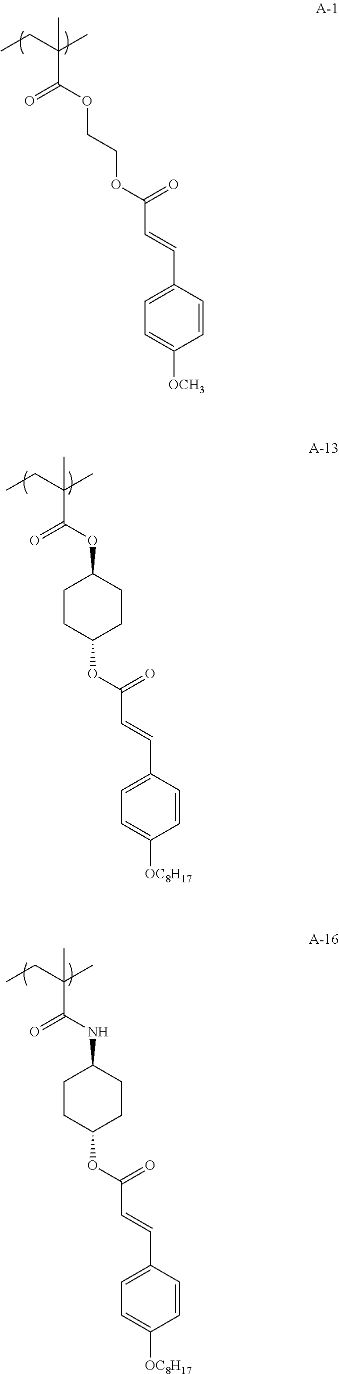

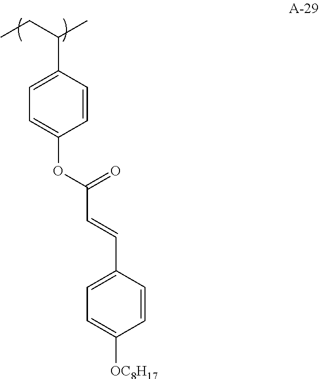

A-34 (see below)

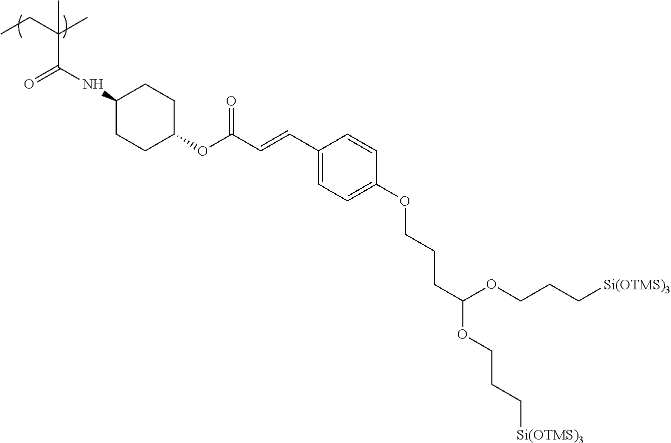

A-45 (a repeating unit obtained by polymerizing a monomer mA-45)

A monomer mA-45 represented by the following formula mA-45 was synthesized according to the following scheme.

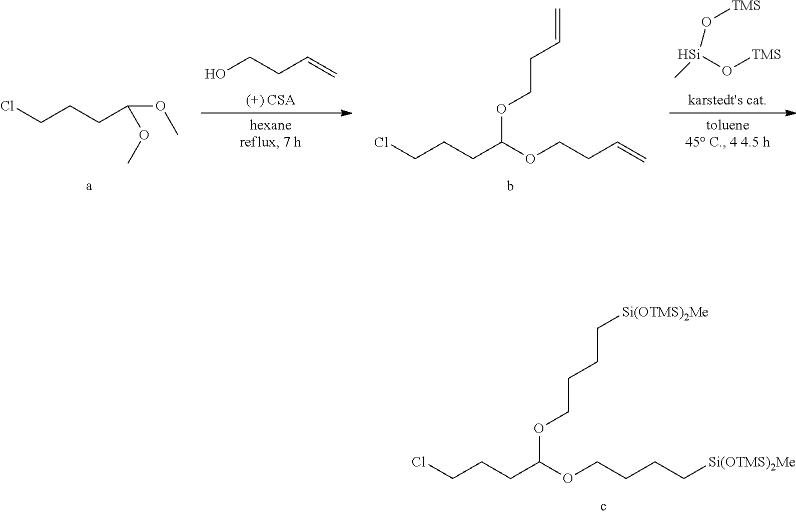

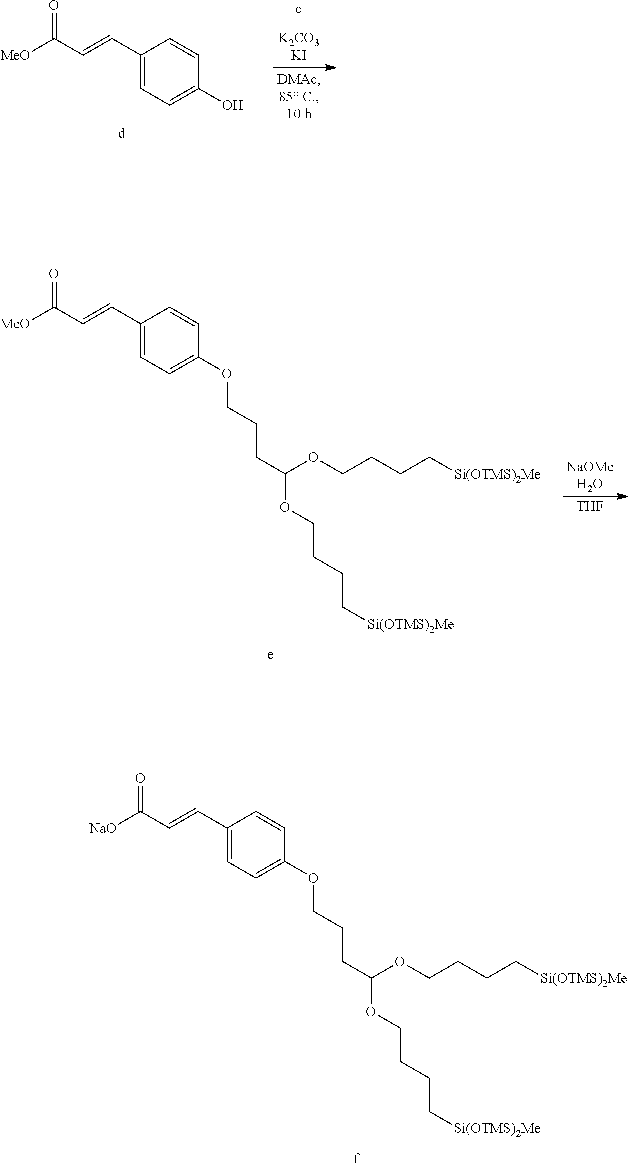

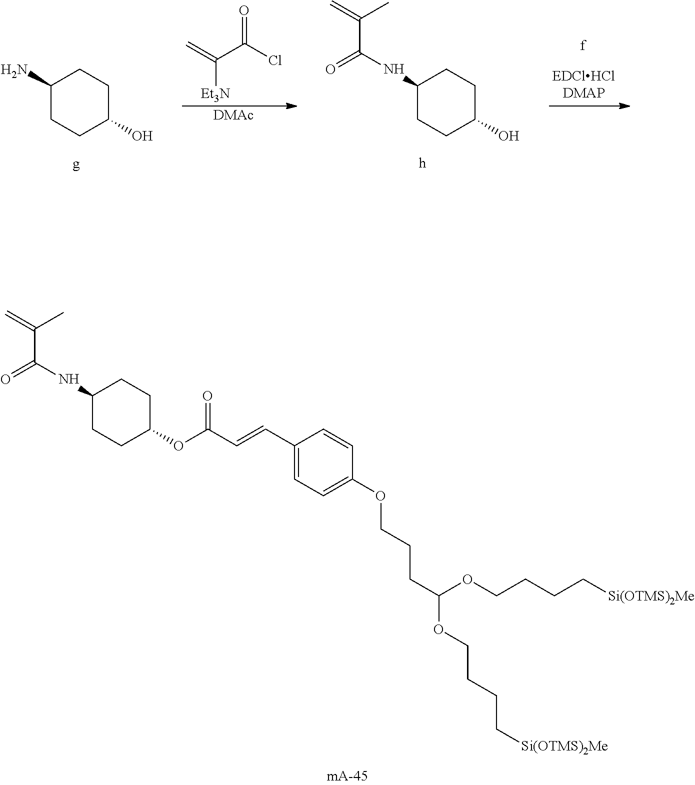

<Synthesis of b>

100 g of 4-chlorobutylaldehyde dimethyl acetal (the compound represented by Formula a in the above scheme), 118.1 g of 3-butene-1-ol, 1.52 g of (+)-10-camphorsulfonic acid, and 197 mL of hexane were weighed in a 2000 mL eggplant flask equipped with a cooling pipe, a thermometer, and a stirrer, and stirred at 75° C. outside the device for 30 minutes under a nitrogen atmosphere. The temperature of the exterior was raised to 78° C., Dean-Stark was mounted, and 1075 mL of hexane was added dropwise thereto over 3 to 4.5 hours using a dropping pump. Next, 70.9 g of 3-butene-1-ol was added thereto, the mixture was stirred for 30 minutes, and 1075 mL of hexane was added dropwise thereto using a dropping pump over 3 to 4.5 hours. Thereafter, the mixture was stirred for 1 hour, the internal temperature was lowered to 50° C., and 2 mL of diisopropylethylamine was added thereto. The mixture was subjected to liquid separation and washing using hexane, acetonitrile, water, and triethylamine, and the obtained organic layer was concentrated to obtain 260.0 g of a compound b (a compound represented by Formula b in the above scheme) as a colorless and transparent liquid.

<Synthesis of c>

130 g of the compound b, 1,300 μL of the Kallestad catalyst, and 1,300 mL of toluene were weighed into a 2,000 mL eggplant flask equipped with a cooling pipe, a thermometer, and a stirrer, and the mixture was stirred for 30 minutes under a nitrogen atmosphere. The temperature was raised to 45° C., and 237.3 g of heptamethyltrisiloxane was added dropwise thereto over 2 hours using a dropping pump. The mixture was cooled to 25° C. and filtered through a Nutsche filled with activated carbon/celite. 350.0 g of a compound c (a compound represented by Formula c in the above scheme) as a brown liquid was obtained by concentrating the filtrate.

<Synthesis of e>

100.0 g of the compound c, 21.9 g of the compound d (methyl p-hydroxycinnamate), 24.5 g of potassium carbonate, 7.3 g of potassium iodide, and 55.0 mL of N,N-dimethylacetamide were weighed into a 500 mL eggplant flask equipped with a cooling pipe, a thermometer, and a stirrer, and the mixture was stirred at 85° C. for 8 hours. The mixture was subjected to liquid separation and washing using hexane, ethyl acetate, water, and a 5% saline solution, and the obtained organic layer was concentrated to obtain 90.0 g of a compound e (a compound represented by Formula e in the above scheme).

<Synthesis of f>

300.0 g of the compound e, 21.5 g of sodium methoxide, 20.5 g of water, and 300 mL of tetrahydrofuran were weighed into a 500 mL eggplant flask equipped with a cooling pipe, a thermometer, and a stirrer, and the mixture was stirred at 60° C. for 6 hours. 150 mL of ethyl acetate was added and added dropwise to 3300 mL of ethyl acetate cooled to 0° C. in a separate flask, and the obtained crystals were filtered to obtain 251.2 g of a compound f (a compound represented by Formula f in the above scheme).

<Synthesis of mA-45>

41.4 g of 4-aminocyclohexanol (the compound represented by Formula g in the above scheme), 39.6 g of triethylamine, and 337.0 mL of N,N-dimethylacetamide were weighed in a 2000 mL eggplant flask equipped with a cooling pipe, a thermometer, and a stirrer, cooled to 0° C. with stirring, and methacrylic acid chloride was added dropwise thereto. In this case, the internal temperature was maintained at 25° C. or lower. The temperature was raised to 40° C. and the mixture was stirred for 2 hours. Next, after cooling to 25° C., 19.10 g of dimethylaminopyridine, 250 g of the compound f, and 89.9 g of 1-(3-dimethylaminopropyl)-3-ethylcarbodiimide hydrochloride were added thereto, and the mixture was stirred at 45° C. for 3 hours. 250 mL of methanol was added thereto, and 750 mL of water was added dropwise thereto over 30 minutes. The solution was cooled to 20° C., and the generated crystals were filtered to obtain 210 g of a white crystal monomer mA-45. mp represents a number of 2 or more.

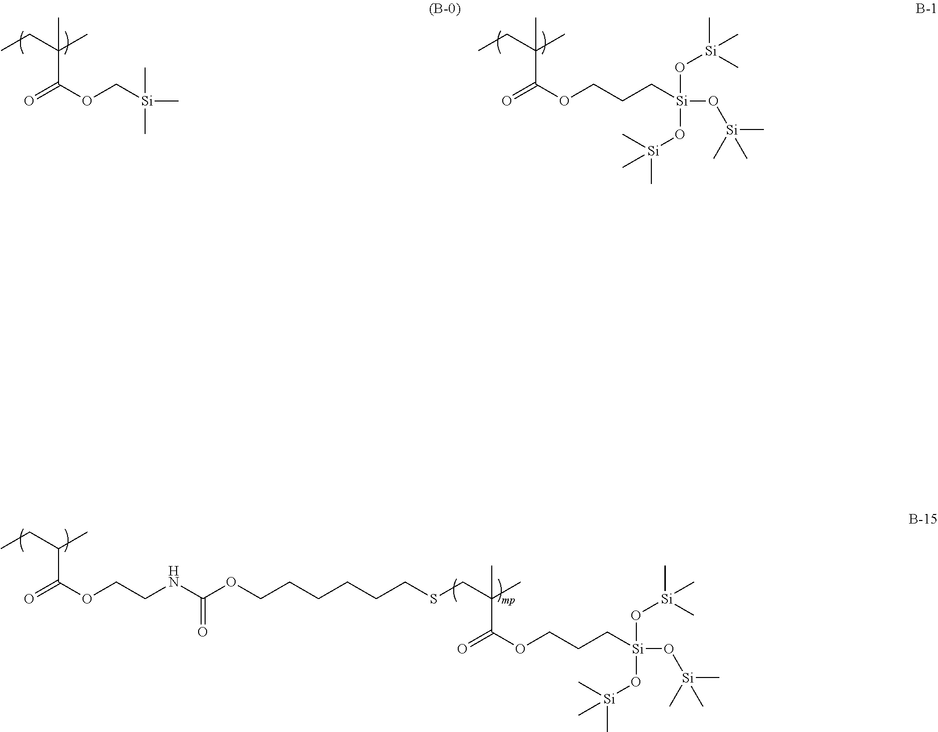

B-5 is a repeating unit obtained by polymerizing the following monomer mB-5. In Formula B-5, * represents a bonding position. In addition, the synthesis method of B-5 is shown below.

22.0 g of cyclohexanone was placed in a 200 mL three-neck flask equipped with a stirrer, a cooling pipe, a nitrogen introduction pipe, and a thermometer, and heated to 80° C.

Next, a mixed solution of 100.0 g of the monomer K-1 (CILAPLANE TM-0701T, manufactured by JNC Corporation), 1.6 g of dimethyl 2,2′-azobisisobutyrate, 3.2 g of 6-mercapto-1-hexanol, and 22.0 g of cyclohexanone was added dropwise thereto over 2 hours under a nitrogen flow.

After aging for 2 hour, a mixed solution of 0.2 g of dimethyl 2,2′-azobis(isobutyrate) and 2.0 g of cyclohexanone was added thereto, and the internal temperature was adjusted to 100° C. for further aging for 3 hours.

Thereafter, the mixture was allowed to cool, 0.2 g of NEOSTANN U-600 (product name, manufactured by Nitto Kasei Co., Ltd.), 0.3 g of 4-methoxyphenol (manufactured by FUJIFILM Wako Pure Chemical Corporation), 3.6 g of Karenz AOI (product name, manufactured by SHOWA DENKO K.K.), and 8.6 g of cyclohexanone were added thereto, and the mixture was reacted at 80° C. for 6 hours in the atmosphere to obtain a monomer mB-5.

The weight-average molecular weight of the monomer mB-5 was 4,600, and the molecular weight distribution (dispersity) was 1.5. The above-described weight-average molecular weight and molecular weight distribution were calculated in terms of polystyrene by gel permeation chromatography (EcoSEC HLC-8320GPC (manufactured by Tosoh Corporation), using THF as an eluent, a flow rate of 0.35 ml/min, and a temperature of 40° C., and using TSKgel SuperHZM-H, TSKgel SuperHZ4000, and TSKgel SuperHZ200 (manufactured by Tosoh Corporation) as a column.
B-18 (see below)

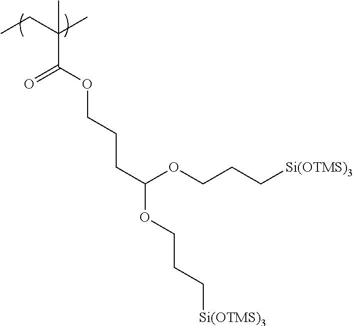

B-57 (a repeating unit obtained by polymerizing a monomer mB-57)

A monomer mB-57 represented by Formula mB-57 was synthesized according to the following scheme.

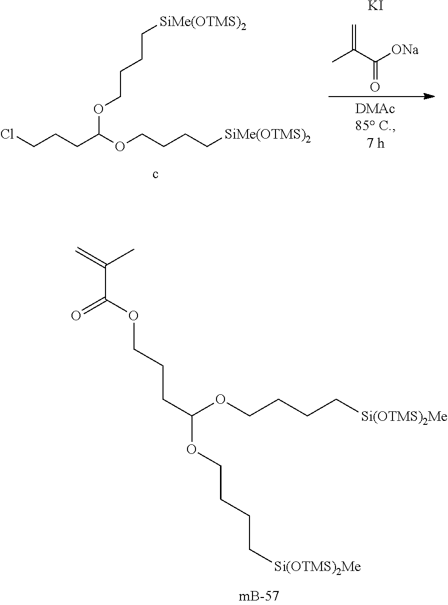

A compound c was obtained by the same method as the method for synthesizing the monomer mA-45 described above. Next, 330 g of the compound c, 63.1 g of sodium methacrylate, 165 mg of BHT, 121.2 g of potassium iodide (KI), and 1650 mL of N,N-dimethylacetamide (DMAc) were weighed in a 3000 mL eggplant flask equipped with a cooling pipe, a thermometer, and a stirrer, and the mixture was stirred at 85° C. for 7 hours. The obtained organic phase was concentrated after liquid separation washing with heptane, ethyl acetate, and water to obtain 350.0 g of a monomer mB-57 as a colorless and transparent liquid.

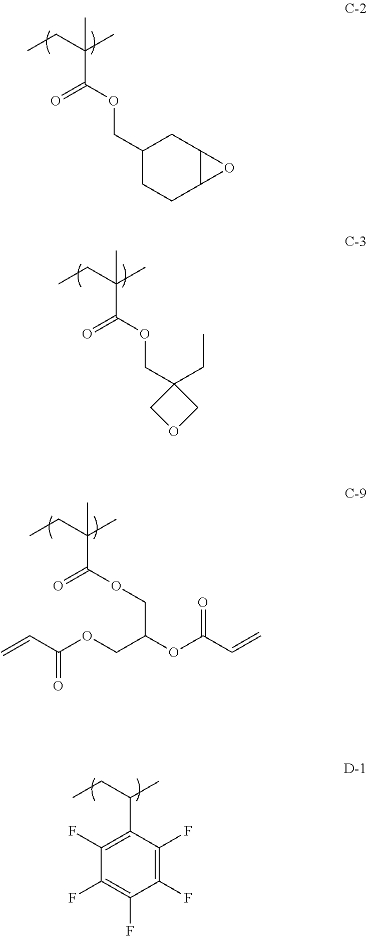

### Example 10

### [Synthesis of Photo-Alignment Polymer KP-1]

Cyclopentanone (30 parts by mass) as a solvent, the repeating units shown in Table 1 and each monomer having the content thereof, and 2,2′-azobis(isobutyronitrile) (0.1 parts by mass) as a polymerization initiator were charged into a flask equipped with a cooling pipe, a thermometer, and a stirrer, and the mixture was stirred while maintaining a reflux state for 7 hours by heating in a water bath with nitrogen flowing into the flask at 15 mL/min. After completion of the reaction, the mixture was allowed to cool to room temperature, the obtained polymer solution was poured into a large excess of methanol to precipitate a polymer, the recovered precipitate was separated by filtration and washed with a large amount of methanol, and then the mixture was vacuum-dried at 40° C. for 6 hours to obtain a photo-alignment polymer KP-1.

An optical laminate was prepared in the same manner as in Example 1, except that the photo-alignment polymer P-1 was replaced with the photo-alignment polymer KP-1.

### Example 11

### [Synthesis of Photo-Alignment Polymer KP-2]

Cyclopentanone (30 parts by mass) as a solvent, the repeating units shown in Table 1 and each monomer having the content thereof, and 2,2′-azobis(isobutyronitrile) (0.1 parts by mass) as a polymerization initiator were charged into a flask equipped with a cooling pipe, a thermometer, and a stirrer, and the mixture was stirred while maintaining a reflux state for 7 hours by heating in a water bath with nitrogen flowing into the flask at 15 mL/min.

After completion of the reaction, the mixture was allowed to cool to room temperature, the obtained polymer solution was poured into a large excess of methanol to precipitate a polymer, the recovered precipitate was separated by filtration, washed with a large amount of methanol, and then vacuum-dried at 40° C. for 6 hours to obtain a photo-alignment polymer KP-2.

An optical laminate was prepared by the same procedure as in Example 1, except that the photo-alignment polymer P-1 was replaced with the photo-alignment polymer KP-2.

### Example 12

### (Preparation of Cellulose Acylate Film)

The following composition was put into a mixing tank, stirred, and further heated at 90° C. for 10 minutes. Then, the obtained composition was filtered through a filter paper having an average pore diameter of 34 m and a sintered metal filter having an average pore diameter of 10 m to prepare a dope. The concentration of solid contents of the dope is 23.5% by mass, and the solvent of the dope is methylene chloride/methanol/butanol=81/18/1 (mass ratio).

Cellulose acylate dope

| | | |
|---|---|---|
| Cellulose acylate (acetyl substitution degree: | 100 | parts by mass |
| 2.86, viscosity average polymerization | | |
| degree: 310) | | |
| Sugar ester compound 1 (represented by | 6.0 | parts by mass |
| Formula (S4)) | | |
| Sugar ester compound 2 (represented by | 2.0 | parts by mass |
| Formula (S5)) | | |
| Silica particle dispersion (AEROSIL R972, | 0.1 | parts by mass |

manufactured by Nippon Aerosil Co., Ltd.)
Solvent (methylene chloride/methanol/butanol)

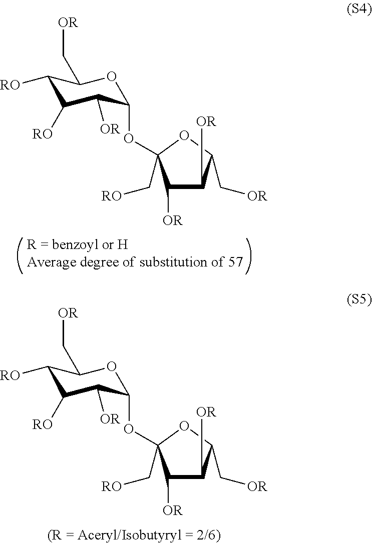

The dope prepared above was cast using a drum film forming machine. The dope was cast from a die such that the dope was in contact with a metal support cooled to 0° C., and then the resulting web (film) was stripped off. The drum was made of SUS.

The web (film) obtained by casting was peeled off from the drum, and then dried in a tenter device for 20 minutes at 30° C. to 40° C. during film transport, and the tenter device transported the web by clipping both ends of the web. Subsequently, the web was post-dried by zone heating while being rolled and transported. The obtained web was subjected to knurling and wound up.

The thickness of the obtained cellulose acylate film was 40 m.

### (Formation of Laminated Film (1a))

A composition (1-1) for forming an optically-anisotropic layer containing a disk-like liquid crystal compound having the following composition was applied onto the above-described cellulose acylate film using a geeser coating machine to form a composition layer. The film on which the composition layer was formed was heated with hot air at 116° C. for 1 minute, and irradiated with ultraviolet rays at an irradiation amount of 150 mJ/cm² using a 365 nm UV-LED (ultraviolet light-emitting diode) while purging with nitrogen to create an atmosphere with an oxygen concentration of 100 ppm by volume or less at a temperature of 78° C. Then, the obtained coating film was annealed with hot air at 115° C. for 25 seconds to form an optically-anisotropic layer (1-1) (which corresponds to a negative C plate and also to the binder layer of the present invention) corresponding to the first optically-anisotropic layer.

The obtained optically-anisotropic layer (1-1) was irradiated with UV light (ultra-high pressure mercury lamp; UL750, manufactured by HOYA Corporation) passing through a wire grid polarizer at room temperature at an irradiation dose of 7.9 mJ/cm² (wavelength: 313 nm), whereby an elongated film 1 was obtained in which the surface of the optically-anisotropic layer (1-1) was endowed with an alignment controllability.

The film thickness of the formed optically-anisotropic layer (1-1) was 0.9 m. An in-plane retardation Re at a wavelength of 550 nm was 0 nm, and a retardation Rth in a thickness direction at a wavelength of 550 nm was 40 nm. It was confirmed that an average tilt angle of a disc plane of the disk-like liquid crystal compound with respect to the film surface was 0°, and the disk-like liquid crystal compound was horizontally aligned with respect to the film surface.

Composition (1-1) for forming optically-anisotropic layer

| | | |
|---|---|---|
| Disk-like liquid crystal compound 1 described | 4 | parts by mass |
| above | | |
| Disk-like liquid crystal compound 2 described | 1 | parts by mass |
| above | | |
| Disk-like liquid crystal compound 3 shown below | 95.0 | parts by mass |
| Ethylene oxide-modified trimethylolpropane | 12.0 | parts by mass |
| triacrylate (V#360, manufactured by Osaka | | |
| Organic Chemical Industry Ltd.) (V#360, | | |
| manufactured by Osaka Organic Chemical | | |
| Industry Ltd.) | | |
| Polymerization initiator S-1 (oxime type) | 3.0 | parts by mass |
| shown below | | |
| Photoacid generator D-1 shown below | 3.0 | parts by mass |
| Photo-alignment polymer KP-1 | 0.6 | parts by mass |
| Diisopropylethylamine | 0.2 | parts by mass |
| o-xylene | 475 | parts by mass |

Disk-like Liquid Crystal Compound 3

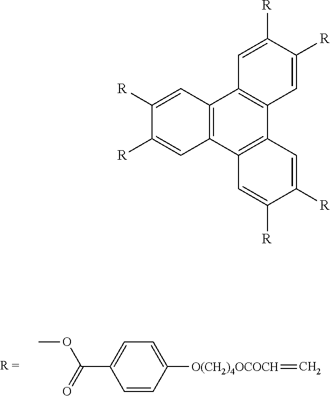

Polymerization Initiator S-1

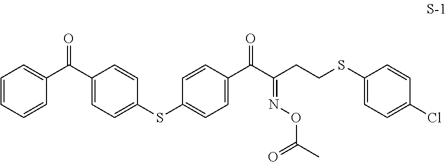 [SMILES: CC(=O)O/N=C(\CCSc1ccc(Cl)cc1)C(=O)c1ccc(Sc2ccc(C(=O)c3ccccc3)cc2)cc1]

Photo-Acid Generator D-1

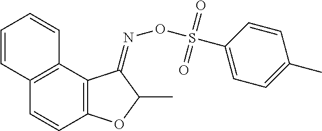 [SMILES: Cc1ccc(S(=O)(=O)O/N=C2/c3c(ccc4ccccc34)OC2C)cc1]

While continuously transporting the elongated film 1 without being wound up, a composition (1-2) for forming an optically-anisotropic layer containing a rod-like liquid crystal compound having the following composition was applied onto the optically-anisotropic layer (1-1) by using a geeser coating machine, and heated with hot air at 95° C. for 120 seconds. Subsequently, the obtained composition layer was irradiated with UV (100 mJ/cm²) at 95° C. to immobilize the alignment of the liquid crystal compound to form an optically-anisotropic layer (1-2) (which corresponds to a negative A plate) corresponding to the second optically-anisotropic layer.

The optically-anisotropic layer (1-2) had a thickness of 1.5 m and an in-plane retardation of 153 nm at a wavelength of 550 nm. It was confirmed that the average tilt angle of the disc plane of the disk-like liquid crystal compound with respect to the film surface was 90°, and the disk-like liquid crystal compound was aligned vertically to the film surface.

Assuming that the width direction of the film is defined as 0° (the counterclockwise direction is defined as 90° and the clockwise direction is defined as −90° in a longitudinal direction), the in-plane slow axis direction of the optically-anisotropic layer (1-2) was −14° in a case of viewing from the optically-anisotropic layer (1-2) side.

Composition (1-2) for forming optically-anisotropic layer

| | | |
|---|---|---|
| Disk-like liquid crystal compound 1 | 80 | parts by mass |
| described above | | |
| Disk-like liquid crystal compound 2 | 20 | parts by mass |
| described above | | |
| Alignment film interface alignment agent 1 | 1.8 | parts by mass |
| described above | | |
| Ethylene oxide-modified trimethylolpropane | 10.0 | parts by mass |
| triacrylate (V#360, manufactured by Osaka | | |
| Organic Chemical Industry Ltd.) (V#360, | | |
| manufactured by Osaka Organic Chemical | | |
| Industry Ltd.) | | |
| Polymerization initiator S-1 (oxime type) | 5.0 | parts by mass |
| described above | | |
| Fluorine-containing compound A described above | 0.1 | parts by mass |
| Fluorine-containing compound D shown below | 0.21 | parts by mass |
| Fluorine-containing compound B described above | 0.06 | parts by mass |
| Antifoaming agent 1 shown below | 2.1 | parts by mass |
| Methyl ethyl ketone | 299 | parts by mass |

Fluorine-containing compound D (The numerical value in each repeating unit represents the content with respect to all the repeating units and the weight-average molecular weight was 12,500)

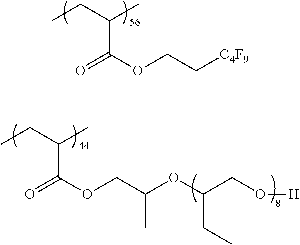

Anti-foaming agent 1

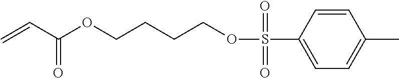 [SMILES: C=CC(=O)OCCCCOS(=O)(=O)c1ccc(C)cc1]

An optical laminate including the optically-anisotropic layer (1-1) and the optically-anisotropic layer (1-2) was prepared on a long cellulose acylate film by the above-described procedure.

### Example 13

An optical laminate was prepared by the same procedure as in Example 12, except that the photo-alignment polymer KP-1 was replaced with the photo-alignment polymer KP-2.

### Example 14

### (Formation of Optically-Anisotropic Layer (1c))

An optically-anisotropic layer coating liquid (1c) containing a rod-like liquid crystal compound having the following composition was applied onto the cellulose acylate film prepared in Example 12 using a geeser coating machine to form a composition layer. After that, both ends of the film were held, a cooling plate (9° C.) was installed on the side of the surface on which the coating film of the film was formed so that the distance from the film was 5 mm, and a heater (75° C.) was installed on the side opposite to the surface on which the coating film of the film was formed so that the distance from the film was 5 mm, followed by drying for 2 minutes.

Next, the film was heated with hot air at 60° C. for 1 minute, and irradiated with ultraviolet rays at an irradiation amount of 100 mJ/cm² using a 365 nm UV-LED while purging with nitrogen so as to have an atmosphere having an oxygen concentration of 100 ppm or less. This was followed by annealing with hot air at 120° C. for 1 minute to form a precursor layer.

The obtained precursor layer was irradiated with UV light (ultra-high pressure mercury lamp; UL750; manufactured by HOYA Corporation) passing through a wire grid polarizer at room temperature at 7.9 mJ/cm² (wavelength: 313 nm) to form an optically-anisotropic layer (1c) (which corresponds to a positive C-plate and also to the binder layer of the present invention) having an alignment controllability on the surface thereof.

The film thickness of the formed optically-anisotropic layer (1c) was 0.5 m. The in-plane retardation Re at a wavelength of 550 nm was 0 nm, and the retardation Rth at a wavelength of 550 nm in the thickness direction was −68 nm. It was confirmed that the average tilt angle of the major axis direction of the rod-like liquid crystal compound with respect to the film plane was 90° and the rod-like liquid crystal compound was aligned vertically to the film plane.

Composition (1c) for forming optically-anisotropic layer

| | | |
|---|---|---|
| Rod-like liquid crystal compound (A) shown | 100 | parts by mass |
| below | | |
| Polymerizable monomer (A-400, manufactured by | 4.0 | parts by mass |
| Shin-Nakamura Chemical Co., Ltd.) | | |
| Polymerization initiator S-1 (oxime type) | 5.0 | parts by mass |
| described above | | |
| Photoacid generator D-1 described above | 3.0 | parts by mass |
| Polymer M-1 shown below | 2.0 | parts by mass |
| Vertical alignment agent S01 shown below | 2.0 | parts by mass |
| Photo-alignment polymer KP-1 | 2.0 | parts by mass |
| Methyl ethyl ketone | 42.3 | parts by mass |
| Methyl isobutyl ketone | 627.5 | parts by mass |

Rod-like liquid crystal compound (A) (hereinafter, a mixture of compounds)

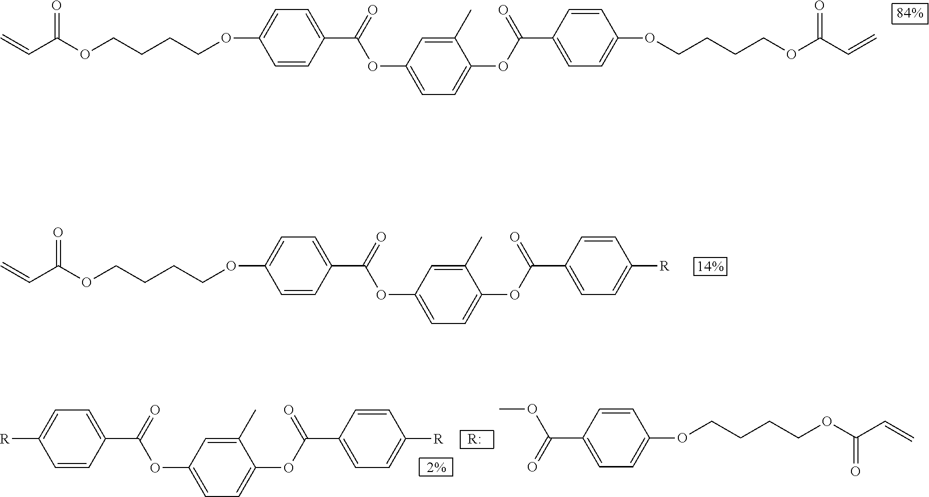

Polymer M-1 (weight-average molecular weight was 60,000)

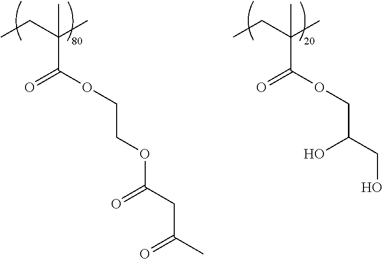

Vertical alignment agent S01

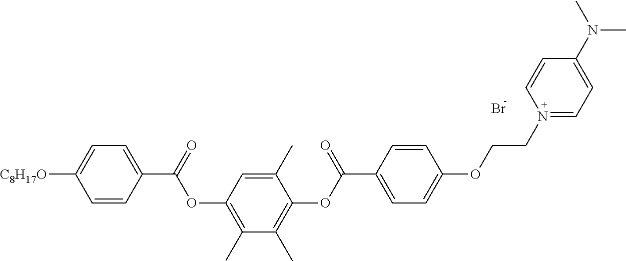

### (Formation of Optically-Anisotropic Layer (1b))

Next, an optically-anisotropic layer coating liquid (1b) containing a rod-like liquid crystal compound having the following composition was applied onto the above prepared optically-anisotropic layer (1c) using a geeser coating machine, and heated with hot air at 80° C. for 60 seconds. Subsequently, the obtained composition layer was irradiated with UV (500 mJ/cm²) at 80° C. to immobilize the alignment of the liquid crystal compound to form an optically-anisotropic layer (1b ) corresponding to the optically-anisotropic layer (B1.

The optically-anisotropic layer (1b) had a thickness of 1.2 m, And of 164 nm at a wavelength of 550 nm, and a twisted angle of the liquid crystal compound of 81°. In a case where the width direction of the film was set to 0° (the longitudinal direction was set to −90°), the angle of the alignment axis of the liquid crystal compound was −14° on the air side and was −95° on the side in contact with the optically-anisotropic layer (1c) as viewed from the side of the optically-anisotropic layer (1b).

The alignment axial angle of the liquid crystal compound contained in the optically-anisotropic layer is expressed as negative in a case where it is clockwise (right-handed turning) and positive in a case where it is counterclockwise (left-handed turning) with the width direction of the substrate as a reference of 0°, upon observing the substrate from the surface side of the optically-anisotropic layer.

In addition, the twisted angle of the liquid crystal compound is expressed as negative in a case where the alignment axis direction of the liquid crystal compound on the substrate side (back side) is clockwise (right-handed turning) and positive in a case where it is counterclockwise (left-handed turning) with reference to the alignment axis direction of the liquid crystal compound on the surface side (front side), upon observing the substrate from the surface side of the optically-anisotropic layer.

In this manner, an optical laminate including the optically-anisotropic layer (1c) and the optically-anisotropic layer (1b) was prepared.

Composition (1b) for Forming Optically-Anisotropic Layer

| | | |
|---|---|---|
| Rod-like liquid crystal compound (A) | 100 | parts by mass |
| Ethylene oxide-modified trimethylolpropane | 4 | parts by mass |
| triacrylate (V#360, manufactured by Osaka | | |
| Organic Chemical Industry Ltd.) (V#360, | | |
| manufactured by Osaka Organic Chemical | | |
| Industry Ltd.) | | |
| Photopolymerization initiator (Irgacure 819, | 3 | parts by mass |
| manufactured by BASF SE) | | |
| Left-handed twisting chiral agent (L1) shown | 0.60 | parts by mass |
| below | | |
| Fluorine-containing compound F shown below | 0.08 | parts by mass |
| Methyl ethyl ketone | 156 | parts by mass |

Left-handed twisting chiral agent (L1)

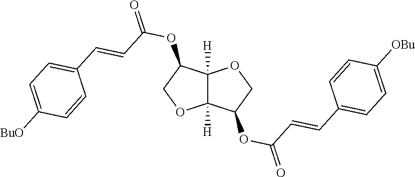

Fluorine-containing compound F (the numerical value in each repeating unit represents the content (% by mass) with respect to all the repeating units, the content of the repeating unit on the left side was 25% by mass, the content of the repeating unit in the middle was 25% by mass, and the content of the repeating unit on the right side was 50% by mass. The weight-average molecular weight was 12,800.)

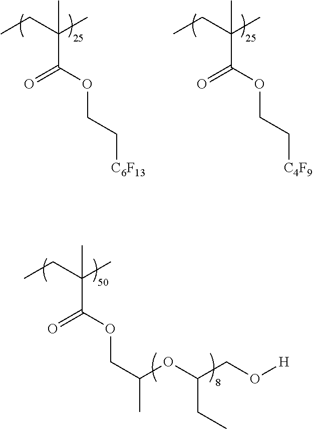

### Example 15

An optical laminate was prepared by the same procedure as in Example 14, except that the photo-alignment polymer KP-1 was replaced with the photo-alignment polymer KP-2.

### Example 17

A polymer KP-3c which is a precursor of a photo-alignment polymer KP-3 was obtained by the following method, and a photo-alignment polymer KP-3 was synthesized using the obtained polymer KP-3c. An optical laminate was prepared in the same manner as in Example 1, except that the photo-alignment polymer P-1 was replaced with the photo-alignment polymer KP-3.

A method of synthesizing a polymer KP-3c will be described in detail. 1-Methoxy-2-propanol (284.6 parts by mass) as a solvent, the following monomer mA-16 (27.7 parts by mass), the following monomer mB-57 (28.1 parts by mass), and the following monomer mC-4C1 (44.2 parts by mass) were weighed into a flask equipped with a cooling pipe, a thermometer, and a stirrer, and the mixture was heated in a water bath at 70° C. while flowing nitrogen into the flask at 15 mL/min, a mixed solution of 2,2′-azobis(isobutyric acid) dimethyl (1.74 parts by mass) and 1-methoxy-2-propanol (16.2 parts by mass) was added dropwise thereto for 20 minutes, and the mixture was stirred while maintaining a reflux state for 9 hours.

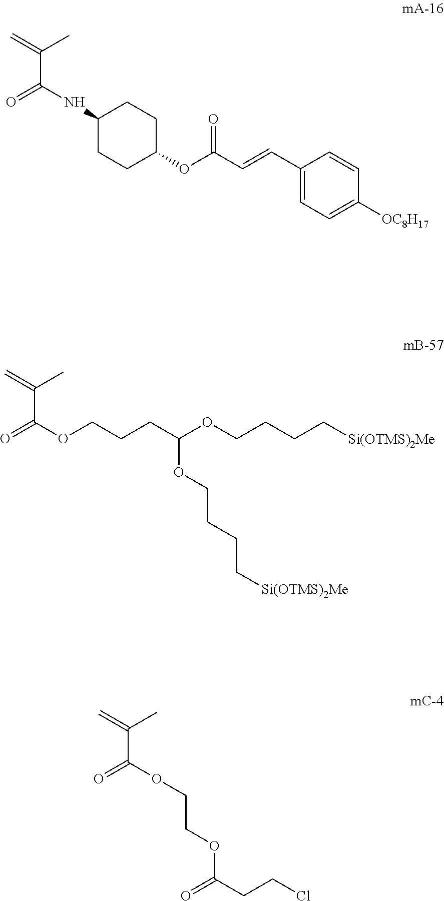

After completion of the reaction, the mixture was allowed to cool to room temperature, the obtained polymer solution was poured into a large excess of a mixed solution of methanol/water to precipitate a polymer, the recovered precipitate was separated by filtration, washed with a large amount of methanol/water, and then vacuum-dried at 40° C. for 12 hours to obtain the following polymer KP-3c having the above-described repeating unit A-16, the repeating unit B-57, and the repeating unit C-4C1.

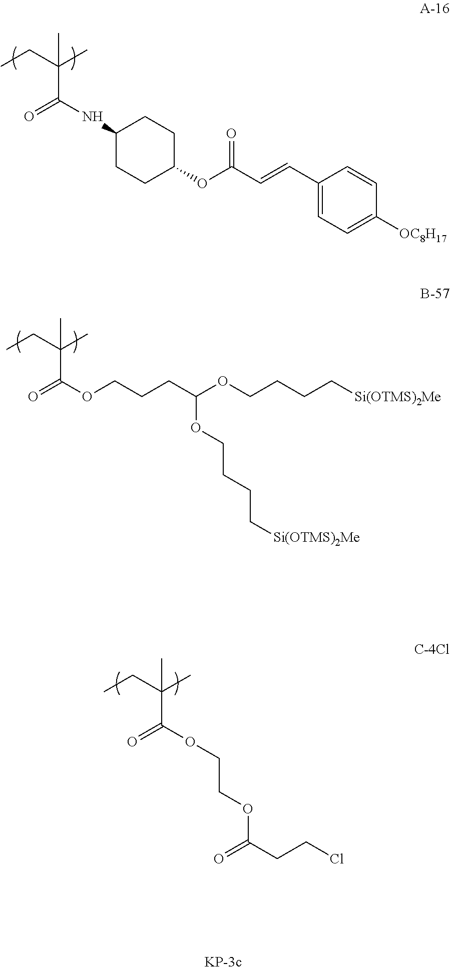

Subsequently, a flask equipped with a cooling pipe, a thermometer, and a stirrer was charged with a polymer KP-3c (90.0 parts by mass), 4-methoxyphenol (0.18 parts by mass), triethylamine (65.9 parts by mass), acetone (110 parts by mass), and dimethylacetamide (110 parts by mass), and the mixture was stirred at 60° C. for 2 hours by heating in a water bath. After completion of the reaction, the mixture was allowed to cool to room temperature. The obtained reaction solution was poured into a large excess of methanol/water (1/3) to precipitate the polymer, and the collected precipitate was separated by filtering and washed with a large amount of methanol/water (1/3). Next, the resultant was blast-dried at 40° C. for 12 hours to obtain the following photo-alignment polymer P-3.

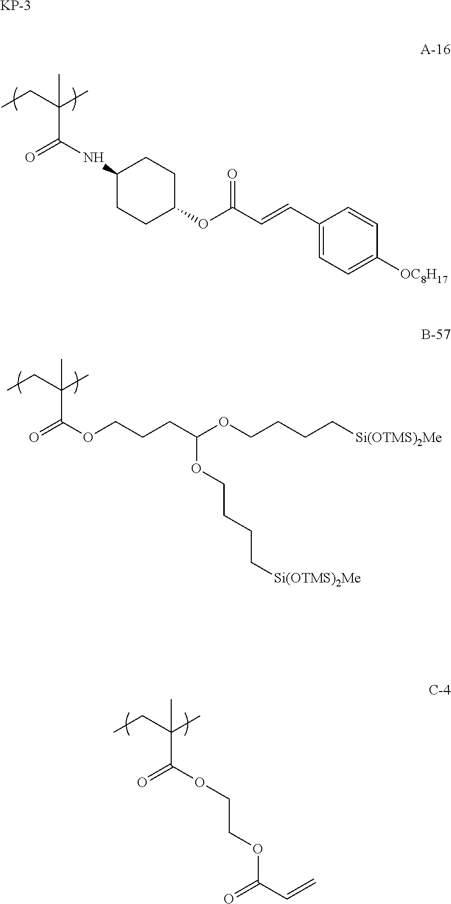

### Examples 18 to 23

Photo-alignment polymers KP-4 to KP-9 were synthesized in the same manner as in the synthesis of the photo-alignment polymer KP-3, except that the content of the monomer forming the repeating unit shown in Table 1 below was changed. An optical laminate was prepared by the same procedure as in Example 14, except that the photo-alignment polymer KP-1 was changed to each of the photo-alignment polymers KP-4 to KP-9 obtained above as shown in Table 1.

### Example 16

### (Formation of Optically-Anisotropic Layer (2c))

The above-described rod-like liquid crystal compound (A) (100 parts by mass), an acrylate monomer (A-400, manufactured by Shin-Nakamura Chemical Co., Ltd.) (4.2 parts by mass), the above-described polymer M-1 (2 parts by mass), a vertical alignment agent S01 (1.9 parts by mass), the above-described photopolymerization initiator S-1 (5.1 parts by mass), the above-described photoacid generator D-1 (3 parts by mass), and the above-described photo-alignment polymer KP-1 (0.8 parts by mass) were dissolved in 567 parts by mass of methyl isobutyl ketone to prepare an optically-anisotropic layer coating solution (2c).

The prepared optically-anisotropic layer coating liquid (2c) was applied onto the cellulose acylate film prepared in Example 12 with a #3.0 wire bar, heated at 70° C. for 2 minutes, and irradiated with ultraviolet rays of 150 mJ/cm² at an oxygen concentration of less than 100 ppm. Thereafter, the laminate was annealed at 120° C. for 1 minute to form a second optically-anisotropic layer (corresponding to the binder layer of the present invention).

The second optically-anisotropic layer was a positive C plate satisfying Expression (C1) nz>nx≈ny, and had a film thickness of about 0.5 μm.

The obtained second optically-anisotropic layer was irradiated with 7.9 mJ/cm² of UV light (ultra-high pressure mercury lamp; UL750; manufactured by HOYA CANDEO OPTRONICS CORPORATION) (wavelength: 313 nm) passing through a wire grid polarizer at room temperature to impart an alignment function.

### (Formation of Optically-Anisotropic Layer (1a))

The rod-like liquid crystal compound (A) (8.5 parts by mass), the rod-like liquid crystal compound D (21.2 parts by mass), the rod-like liquid crystal compound E (26.1 parts by mass), the rod-like liquid crystal compound F (29.0 parts by mass), the compound G (15.3 parts by mass), the polymerizable compound M1 (5 parts by mass), the photopolymerization initiator S-1 (0.5 parts by mass), and the polymer C (0.1 parts by mass) were dissolved using cyclopentanone (175 parts by mass), methyl ethyl ketone (50 parts by mass), and ethyl laurate (10 parts by mass) as solvents to prepare a composition 1 for forming a first optically-anisotropic layer (hereinafter, also abbreviated as “liquid crystal composition A-1”).

The first optically-anisotropic layer forming composition 1 was coated on the previously formed second optically-anisotropic layer with a wire bar coater #7 to form a composition layer. The formed composition layer was first heated on a hot plate to 120° C. and then cooled to 60° C. to stabilize the alignment. Then, using an ultra-high pressure mercury lamp and in a nitrogen atmosphere (oxygen concentration of less than 100 ppm), first ultraviolet irradiation (80 mJ/cm²) was carried out at a film temperature kept at 60° C., and then second ultraviolet irradiation (300 mJ/cm²) was carried out at a film temperature kept at 100° C. to immobilize the alignment. A first optically-anisotropic layer having a thickness of 2.8 m was formed, and a laminate was prepared. The first optically-anisotropic layer was a positive A plate satisfying Expression (A1) nx>ny≈nz.

In this manner, an optical laminate including the positive C-plate and the positive A-plate was prepared.
Rod-Like Liquid Crystal Compound D

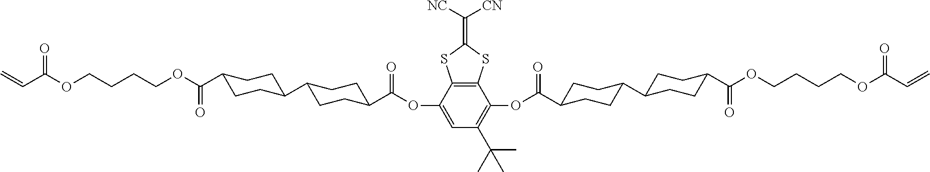 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]

Rod-Like Liquid Crystal Compound E

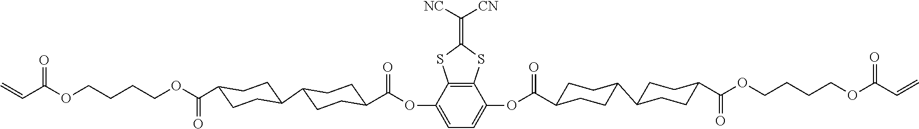 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]

Rod-Like Liquid Crystal Compound F

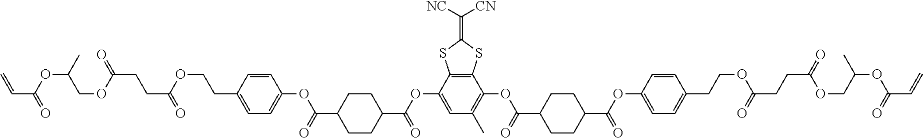 [SMILES: C=CC(=O)OC(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)OC(=O)C=C)cc5)CC4)c4c3SC(=C(C#N)C#N)S4)CC2)cc1]

Compound G

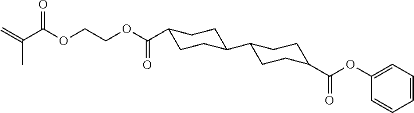 [SMILES: C=C(C)C(=O)OCCOC(=O)C1CCC(C2CCC(C(=O)Oc3ccccc3)CC2)CC1]

Polymerizable compound M1

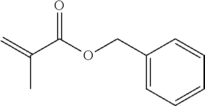

Polymer C (weight-average molecular weight was 25,000)

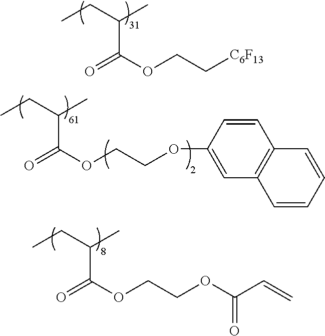

### <Production of Circularly Polarizing Plate>

### (Production of Linearly Polarizing Plate 1)

The surface of a support of a cellulose triacetate film TJ25 (manufactured by FUJIFILM Corporation, thickness: 25 m) was subjected to an alkali saponification treatment. Specifically, the support was immersed in a 1.5 N sodium hydroxide aqueous solution at 55° C. for 2 minutes, washed in a water washing bath at room temperature, and further neutralized with 0.1 N sulfuric acid at 30° C. After neutralization, the support was washed in the water washing bath at room temperature and further dried with hot air at 100° C. to obtain a polarizer protective film.

A roll-like polyvinyl alcohol (PVA) film having a thickness of 60 m was continuously stretched in an iodine aqueous solution in a longitudinal direction and dried to obtain a polarizer having a thickness of 13 m. The luminosity corrected single transmittance of the polarizer was 43%. At this time, the absorption axis direction and the longitudinal direction of the polarizer coincided.

The above-described polarizer protective film was bonded to one surface of the above-described polarizer using the following PVA adhesive to produce a linearly polarizing plate 1.

### (Preparation of PVA Adhesive)

100 parts by mass of a polyvinyl alcohol-based resin having an acetoacetyl group (average degree of polymerization: 1200, degree of saponification: 98.5 mol %, and degree of acetoacetylation: 5 mol %) and 20 parts by mass of methylol melamine were dissolved in pure water under a temperature condition of 30° C. to prepare a PVA adhesive as an aqueous solution adjusted to a concentration of solid contents of 3.7% by mass.

### Creation Example 1

The surface of the optically-anisotropic layer (1a) of the optical laminate prepared in Example 16 and the surface of the polarizer of the prepared elongated linearly polarizing plate 1 (the surface opposite to the polarizer protective film) were continuously bonded to each other using an ultraviolet curable adhesive. Subsequently, the cellulose acylate film on the optically-anisotropic layer (2c) side was peeled off to expose the surface of the optically-anisotropic layer (2c) in contact with the cellulose acylate film.

In this manner, a circularly polarizing plate (P1) consisting of an optical laminate and a linearly polarizing plate 1 was prepared. In this case, the polarizer protective film, the polarizer, the optically-anisotropic layer (1a), and the optically-anisotropic layer (2c) were laminated in this order, and the angle between the absorption axis of the polarizer and the slow axis of the optically-anisotropic layer (1a) was 45°.

### Creation Example 2

The surface side of the optically-anisotropic layer (1-2) of the optical laminate prepared in Example 13 and the surface side of the optically-anisotropic layer (1b) of the optical laminate prepared in Example 14 were continuously bonded to each other using an ultraviolet curable adhesive.

Subsequently, the cellulose acylate film of the optical laminate prepared in Example 13 was peeled off to expose the surface of the optically-anisotropic layer (1-1) in contact with the cellulose acylate film. In this manner, an optical film (1c-1b-1-2-1-1) in which the optically-anisotropic layer (1c), the optically-anisotropic layer (1b), the optically-anisotropic layer (1-2), and the optically-anisotropic layer (1-1) were laminated in this order on a long cellulose acylate film was obtained.

The surface of the optically-anisotropic layer (1-1) of the above prepared elongated optical film (1c-1b-1-2-1-1) and the surface of the polarizer of the above prepared elongated linearly polarizing plate 1 (the surface opposite to the polarizer protective film) were continuously bonded to each other using an ultraviolet curable adhesive. Subsequently, the cellulose acylate film on the optically-anisotropic layer (1c) side was peeled off to expose the surface of the optically-anisotropic layer (1c) in contact with the cellulose acylate film.

In this way, a circularly polarizing plate (P2) consisting of the optical film (1c-1b-1-2-1-1) and the linearly polarizing plate 1 was prepared. In this case, the polarizer protective film, the polarizer, the optically-anisotropic layer (1-1), the optically-anisotropic layer (1-2), the optically-anisotropic layer (1b), and the optically-anisotropic layer (1c) were laminated in this order, and the angle between the absorption axis of the polarizer and the slow axis of the optically-anisotropic layer (1-2) was 76°. In addition, the alignment axial angle of the liquid crystal compound on the optically-anisotropic layer (1-2) side of the optically-anisotropic layer (1b) was 140 with the width direction as a reference of 0°, which coincided with the slow axis direction of the optically-anisotropic layer (1-2).

### Creation Example 3

### (Alkali Saponification Treatment)

After passing the above-mentioned cellulose acylate film through a dielectric heating roll at a temperature of 60° C. to raise the film surface temperature to 40° C., an alkaline solution having the composition shown below was applied onto a band surface of the film using a bar coater at a coating amount of 14 mL/m², followed by heating to 110° C., and transportation under a steam type far-infrared heater manufactured by Noritake Co., Limited for 10 seconds. Subsequently, pure water was applied at 3 mL/m² using the same bar coater. Next, after repeating washing with water by a fountain coater and draining by an air knife three times, the film was transported to a drying zone at 70° C. for 10 seconds and dried to produce a cellulose acylate film subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Surfactant (C₁₄H₂₉O(CH₂CH₂O)₂₀H) | 1.0 | part by mass |
| Propylene glycol | 14.8 | parts by mass |

### (Formation of Alignment Film)

An alignment film coating liquid having the following composition was continuously applied onto the surface of the cellulose acylate film that had been subjected to the alkali saponification treatment with a #14 wire bar. The film was dried with hot air at 60° C. for 60 seconds and further with hot air at 100° C. for 120 seconds.

Alignment Film Coating Liquid

| | | |
|---|---|---|
| Polyvinyl alcohol shown below | 10 | parts by mass |
| Water | 371 | parts by mass |
| Methanol | 119 | parts by mass |
| Glutaraldehyde (crosslinking agent) | 0.5 | parts by mass |
| Citric acid ester (manufactured by | 0.175 | parts by mass |
| Sankyo Chemical Co., Ltd.) | | |

### (Polyvinyl Alcohol)

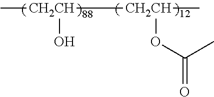

### (Formation of Optically-Anisotropic Layer (a))

The above prepared alignment film was continuously subjected to a rubbing treatment. At this time, the longitudinal direction and the transport direction of the elongated film were parallel, and the angle formed by the longitudinal direction (transport direction) of the film and the rotation axis of the rubbing roller was 76°. In a case where the longitudinal direction (transport direction) of the film is defined as 90° and the clockwise direction is represented by a positive value with the width direction of the film as a reference (0°) upon observation from the film side, the rotation axis of the rubbing roller is 14°. That is, the position of the rotation axis of the rubbing roller is a position rotated counterclockwise by 76° with the longitudinal direction of the film as a reference.

An optically-anisotropic layer coating liquid (2a) containing a disk-like liquid crystal compound having the following composition was applied onto the rubbing-treated alignment film using a geeser coating machine to form a composition layer. Then, the obtained composition layer was heated with hot air at 110° C. for 2 minutes for drying of the solvent and alignment aging of the disk-like liquid crystal compound. Subsequently, the obtained composition layer was irradiated with UV (500 mJ/cm²) at 80° C. to immobilize the alignment of the liquid crystal compound to form an optically-anisotropic layer (2a) corresponding to the optically-anisotropic layer (A).

The thickness of the optically-anisotropic layer (2a) was 1.1 m. Further, the retardation at a wavelength of 550 nm was 168 nm. It was confirmed that the average tilt angle of the disc plane of the disk-like liquid crystal compound with respect to the film surface was 90°, and the disk-like liquid crystal compound was aligned vertically to the film surface. Further, the angle of the slow axis of the optically-anisotropic layer (2a) was parallel to the rotation axis of the rubbing roller, and in a case where the width direction of the film was set to 0° (in the longitudinal direction, the counterclockwise direction was 90° and the clockwise direction was −90°), the slow axis was 14° as viewed from the side of the optically-anisotropic layer (2a).

Composition (2a) for Forming Optically-Anisotropic Layer

| | | |
|---|---|---|
| Disk-like liquid crystal compound 1 described | 80 | parts by mass |
| above | | |
| Disk-like liquid crystal compound 2 described | 20 | parts by mass |
| above | | |
| Alignment film interface alignment agent 1 | 0.55 | parts by mass |
| described above | | |
| Fluorine-containing compound A described above | 0.1 | parts by mass |
| Fluorine-containing compound B described above | 0.05 | parts by mass |
| Fluorine-containing compound C described above | 0.21 | parts by mass |
| Ethylene oxide-modified trimethylolpropane | 10 | parts by mass |
| triacrylate (V#360, manufactured by Osaka | | |
| Organic Chemical Industry Ltd.) | | |
| (V#360, manufactured by Osaka Organic | | |
| Chemical Industry Ltd.) | | |
| Photopolymerization initiator (IRGACURE 907, | 3.0 | parts by mass |
| manufactured by BASF SE) | | |
| Methyl ethyl ketone | 200 | parts by mass |

The surface side of the optically-anisotropic layer (2a) of the above-prepared optical laminate and the surface side of the optically-anisotropic layer (1b) of the optical laminate prepared in Example 14 were continuously bonded to each other using an ultraviolet curable adhesive.

Subsequently, the cellulose acylate film of the prepared optical laminate was peeled off to expose the surface of the optically-anisotropic layer (2a) in contact with the cellulose acylate film. In this manner, an optical film (1c-1b-2a) in which the optically-anisotropic layer (1c), the optically-anisotropic layer (1b), and the optically-anisotropic layer (2a) were laminated in this order on an elongated cellulose acylate film was obtained.

The surface of the optically-anisotropic layer (2a) of the above prepared elongated optical film (1c-1b-2a) and the surface of the polarizer of the above prepared elongated linearly polarizing plate 1 (the surface opposite to the polarizer protective film) were continuously bonded to each other using an ultraviolet curable adhesive. Subsequently, the cellulose acylate film on the optically-anisotropic layer (1c) side was peeled off to expose the surface of the optically-anisotropic layer (1c) in contact with the cellulose acylate film.

In this way, a circularly polarizing plate (P3) consisting of the optical film (1c-1b-2a) and the linearly polarizing plate 1 was prepared. At this time, the polarizer protective film, the polarizer, the optically-anisotropic layer (2a), the optically-anisotropic layer (1b), and the optically-anisotropic layer (1c) were laminated in this order, and the angle formed by the absorption axis of the polarizer and the slow axis of the optically-anisotropic layer (2a) was 76°. In addition, the alignment axial angle of the liquid crystal compound on the optically-anisotropic layer (2a) side of the optically-anisotropic layer (1b) was 140 with the width direction as a reference of 0°, which coincided with the slow axis direction of the optically-anisotropic layer (2a).

### [Evaluation]

### [Liquid Crystal Alignment Properties]

Two polarizing plates were arranged in crossed nicols, and the obtained optical laminate was disposed therebetween to observe the degree of light leakage and to observe the surface state with a polarization microscope.

AA: there was no light leakage, liquid crystal directors were uniformly oriented and aligned, and the surface state was very stable.

A: there was no light leakage, there was no disorder of liquid crystal directors, and the surface state was stable.

B: there was no light leakage, there was partial disorder of liquid crystal directors, and the surface state was stable.

C: there was no light leakage, but the surface state was not stable due to disorder of liquid crystal directors.

D: light leakage was observed, and the surface state was not stable due to disorder of liquid crystal directors.

### [Wind Streak Resistance]

Two polarizing plates were placed on crossed nicols, the prepared binder layer was placed between the two polarizing plates, and the presence or absence of streak-like unevenness was observed to evaluate suppression of wind streak according to the following standard.

A: unevenness was invisible.

B: unevenness was almost invisible.

C: unevenness was visible.

### [Upper Layer Coating Properties]

The surface region of the prepared binder layer having an A4 size was examined, and the defect that appeared to be circular or elliptical was regarded as cissing to evaluate the upper layer coating property.

A: 0 to 1 cissing was observed.

B: 2 to 4 cissing were observed.

C: 5 or more cissing were observed.

In the following table, the evaluation results are shown.

The “weight-average molecular weight” indicates the weight-average molecular weight of each polymer, and the method of measuring the weight-average molecular weight is as described above.

The content of the repeating unit BP having the polymer chain B in the repeating unit B-5 of the photo-alignment polymers P-8 and P-9 was 90% by mass with respect to the total mass of the repeating unit B.

TABLE 1

| | | | | | | | | | | | liquid crystal | | Upper layer |
|---|---|---|---|---|---|---|---|---|---|---|---|---|---|
| | | Repeating unit | | | | Content※ | | | | Weight-average | alignment | Wind-streak | coating |
| | Polymer | A | B | C | D | a | b | c | d | molecular weight | property | resistance | property |
| Example 1 | P-1 | A-1 | B-1 | C-2 | — | 25 | 35 | 40 | — | 50,000 | B | A | A |
| Example 2 | P-2 | A-13 | B-1 | C-2 | — | 25 | 35 | 40 | — | 50,000 | AA | A | A |
| Example 3 | P-3 | A-16 | B-1 | C-2 | — | 25 | 35 | 40 | — | 50,000 | AA | A | A |
| Example 4 | P-4 | A-13 | B-1 | C-3 | — | 25 | 35 | 40 | — | 50,000 | AA | A | A |
| Example 5 | P-5 | A-13 | B-1 | C-2 | — | 15 | 40 | 45 | — | 35,000 | AA | A | A |
| Example 6 | P-6 | A-16 | B-1 | C-2 | — | 20 | 45 | 35 | — | 100,000 | AA | A | A |
| Example 7 | P-7 | A-13 | B-5 | C-2 | — | 30 | 35 | 35 | — | 70,000 | AA | A | A |
| Example 8 | P-8 | A-13 | B-5 | C-2 | — | 25 | 35 | 40 | — | 50,000 | AA | A | A |
| Example 9 | P-9 | A-13 | B-5 | C-2 | — | 25 | 20 | 55 | — | 50,000 | AA | A | A |
| Comparative | P-10 | A-29 | B-0 | — | D-1 | 60 | 10 | — | 30 | 50,000 | D | B | C |
| Example 1 | | | | | | | | | | | | | |
| Comparative | P-11 | A-1 | B-0 | C-2 | — | 25 | 35 | 40 | — | 50,000 | C | B | A |
| Example 2 | | | | | | | | | | | | | |
| Example 10 | KP-1 | A-16 | B-18 | C-9 | — | 25 | 35 | 40 | — | 50,000 | AA | A | A |
| Example 11 | KP-2 | A-34 | — | C-9 | — | 50 | — | 50 | — | 50,000 | AA | A | A |
| Example 12 | KP-1 | A-16 | B-18 | C-9 | — | 25 | 35 | 40 | — | 50,000 | AA | A | A |
| Example 13 | KP-2 | A-34 | — | C-9 | — | 50 | — | 50 | — | 50,000 | AA | A | A |
| Example 14 | KP-1 | A-16 | B-18 | C-9 | — | 25 | 35 | 40 | — | 50,000 | AA | A | A |
| Example 15 | KP-2 | A-34 | — | C-9 | — | 50 | — | 50 | — | 50,000 | AA | A | A |
| Example 16 | KP-1 | A-16 | B-18 | C-9 | — | 25 | 35 | 40 | — | 50,000 | AA | A | A |
| Example 17 | KP-3 | A-16 | B-57 | C-4 | — | 27 | 30 | 43 | — | 90,000 | AA | A | A |
| Example 18 | KP-4 | A-16 | B-57 | C-4 | — | 30 | 35 | 35 | — | 150,000 | AA | A | A |
| Example 19 | KP-5 | A-16 | B-57 | C-9 | — | 30 | 35 | 35 | — | 100,000 | AA | A | A |
| Example 20 | KP-6 | A-13 | B-57 | C-4 | — | 27 | 30 | 43 | — | 100,000 | AA | A | A |
| Example 21 | KP-7 | A-13 | B-57 | C-9 | — | 30 | 35 | 35 | — | 60,000 | AA | A | A |
| Example 22 | KP-8 | A-45 | — | C-4 | — | 50 | — | 50 | — | 100,000 | AA | A | A |
| Example 23 | KP-9 | A-45 | — | C-9 | — | 50 | — | 50 | — | 100,000 | AA | A | A |

※The content of the “repeating unit A” is denoted by a, the content of the “repeating unit B” is denoted by b, the content of the “repeating unit C” is denoted by c, and the content of the “repeating unit D” is denoted by d. The unit is % by mass.

From the results shown in Table 1, it was found that in a case where the photo-alignment polymer of the present invention including the repeating unit A and the repeating unit B was used, the liquid crystal alignment properties were improved (Examples 1 to 15 and 17 to 23). On the other hand, it was found that in a case where a polymer that does not include at least one of the repeating unit A or the repeating unit B is used, the liquid crystal alignment properties are deteriorated (Comparative Examples 1 and 2).

From the comparison between Examples 1 and 2, it was found that in a case where L^{A1} in Formula (A) is a single bond or a divalent linking group selected from a cyclic alkylene group having 3 to 10 carbon atoms, which may have a substituent, a divalent heterocyclic group, —O—, —S—, —N(Q)- (Q represents a hydrogen atom or a substituent), —CO—, and a group obtained by combining these groups, the liquid crystal alignment properties are more excellent.

What is claimed is:

1. A photo-alignment polymer comprising:
a repeating unit A having a photo-aligned group; and
a repeating unit B,
wherein the repeating unit B is a repeating unit represented by Formula (1) or a repeating unit having a polymer chain including the repeating unit represented by Formula (1), 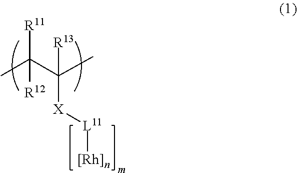
in Formula (1),
R¹¹ and R¹² each independently represent a hydrogen atom or an alkyl group,
R¹³ represents a hydrogen atom or a substituent,
X represents —COO—, —CONH—, or an (m+1)-valent aromatic ring,
in a case where m represents 1, X represents —COO—, —CONH—, or a divalent aromatic ring, and in a case where m represents an integer of 2 to 5, X represents an (m+1)-valent aromatic ring,
L¹¹ represents a single bond or an (n+1)-valent linking group,
in a case where there are a plurality of L¹¹'s, the plurality of L¹¹'s may be the same as or different from each other,
n represents an integer of 1 to 4,
in a case where there are a plurality of n's, the plurality of n's may be the same as or different from each other,
m represents an integer of 1 to 5,
Rh represents a substituent having two or more groups represented by Formula (S),
in a case where there are a plurality of Rh's, the plurality of Rh's may be the same as or different from each other, 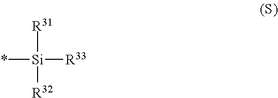
in Formula (S),
* represents a bonding position, and
R³¹, R³², and R³³ each independently represent an alkyl group, an alkenyl group, an aryl group, or an alkylene aryl group, and
in the substituent represented by Rh, a plurality of R³¹'s may be the same as or different from each other, a plurality of R³²'s may be the same as or different from each other, and a plurality of R³³'s may be the same as or different from each other.

2. The photo-alignment polymer according to claim 1,
wherein L¹¹ is a hydrocarbon group having 1 to 20 carbon atoms or a linking group selected from Formulae (B1) to (B6), and 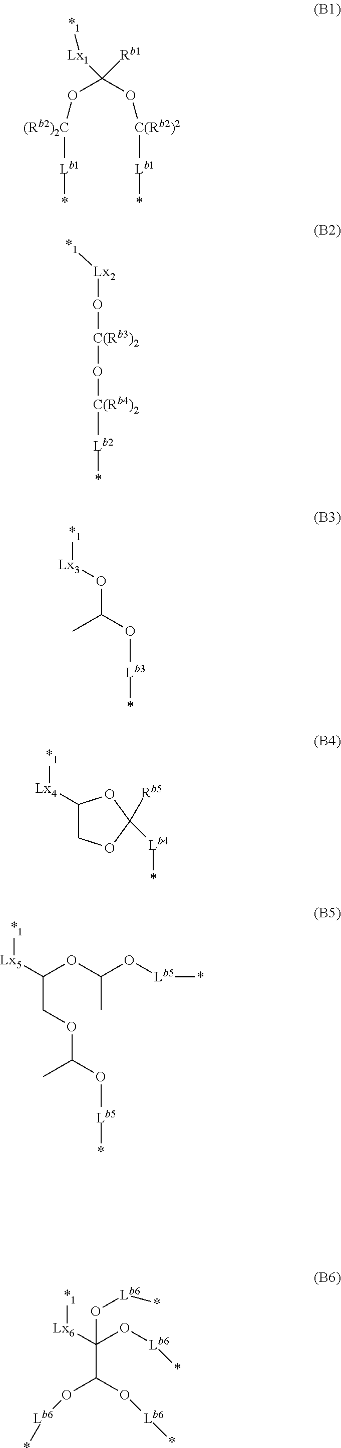
in Formulae (B1) to (B6),
*1 represents a bonding position to X,
* represents a bonding position to Rh,
Lx₁, Lx₂, Lx₃, Lx₄, Lx₅, and Lx₆ each independently represent a single bond, or a linking group selected from an alkylene group having 1 to 20 carbon atoms, which may have —O—, an aryl group having 6 to 18 carbon atoms, which may have —O—, and a group obtained by combining these groups,
R^{b1}, R^{b2}, R^{b3}, R^{b4}, and R^{b5} each independently represent a hydrogen atom or a substituent,
two R^{b3}'s may be bonded to each other to form a ring, a plurality of R^{b2}'s may be the same as or different from each other, a plurality of R^{b3}'s may be the same as or different from each other, and a plurality of R^{b4}'s may be the same as or different from each other,
L^{b1}, L^{b2}, L^{b3}, L^{b4}, L^{b5}, and L^{b6} each independently represent a divalent linking group, and
a plurality of L^{b1}'s may be the same as or different from each other, a plurality of L^{b5}'s may be the same as or different from each other, and a plurality of L^{b6}'s may be the same as or different from each other,
in a case where L¹¹ is Formula (B1) or Formula (B5), n in Formula (1) represents 2,
in a case where L¹¹ is Formula (B2), Formula (B3), or Formula (B4), n in Formula (1) represents 1, and
in a case where L¹¹ is Formula (B6), n represents 4.

3. The photo-alignment polymer according to claim 1,
wherein the repeating unit A is a repeating unit represented by Formula (A), and 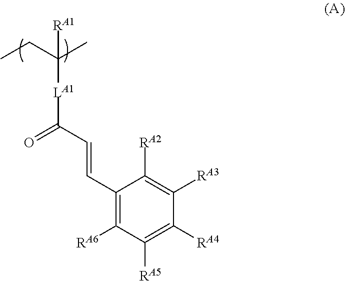
in Formula (A),
R^{A1} represents a hydrogen atom or a substituent,
L^{A1} represents a single bond or a divalent linking group,
R^{A2}, R^{A3}, R^{A4}, R^{A5}, and R^{A6} each independently represent a hydrogen atom or a substituent, and
two adjacent groups of R^{A2}, R^{A3}, R^{A4}, R^{A5}, and R^{A6} may be bonded to each other to form a ring.

4. The photo-alignment polymer according to claim 3,
wherein L^{A1} represents a single bond, or a divalent linking group selected from a cyclic alkylene group having 3 to 10 carbon atoms, which may have a substituent, a divalent heterocyclic group, —O—, —S—, —N(Q)-, —CO—, and a group obtained by combining these groups, where Q represents a hydrogen atom or a substituent.

5. The photo-alignment polymer according to claim 1, further comprising:
a repeating unit represented by Formula (C), 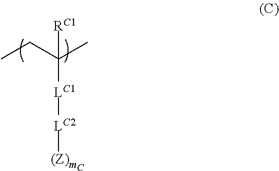
in Formula (C),
R^{C1} represents a hydrogen atom or a substituent,
L^{C1} represents a single bond or a divalent linking group,
L^{C2} represents an (m_{C}+1)-valent linking group,
Z represents a crosslinkable group,
m_{C} represents an integer of 1 or more, and
in a case where m_{C} is an integer of 2 or more, a plurality of Z's may be the same as or different from each other.

6. A photo-alignment polymer comprising:
a repeating unit represented by Formula (A) or a repeating unit represented by Formula (AK2), 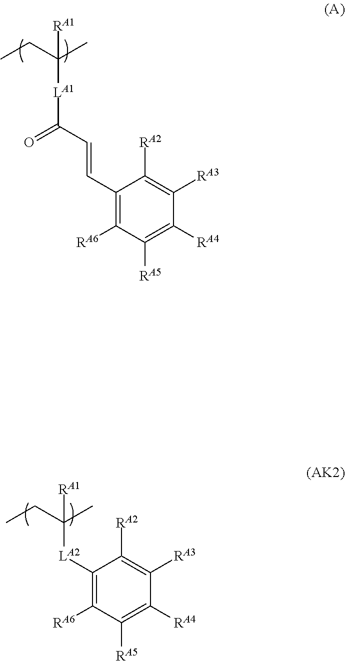
wherein in Formula (A) and Formula (AK2),
R^{A1}'s each independently represent a hydrogen atom or a substituent,
L^{A1} and L^{A2} each independently represent a single bond or a divalent linking group,
R^{A2}, R^{A3}, R^{A4}, R^{A5}, and R^{A6} each independently represent a hydrogen atom or a substituent,
two adjacent groups of R^{A2}, R^{A3}, R^{A4}, R^{A5}, and R^{A6} may be bonded to each other to form a ring,
at least one of R^{A2}, . . . , or R^{A6} in Formula (A) is a substituent having -L¹¹-(Rh)ₙ,
at least one of R^{A2}, . . . , or R^{A6} in Formula (AK2) is a substituent having —CH═CH—CO—O-L¹¹-(Rh)₁ or —CH═CH—CO—NH-L¹¹-(Rh)ₙ,
L¹¹ represents a single bond or an (n+1)-valent linking group,
in a case where there are a plurality of L¹¹'s, the plurality of L¹¹'s may be the same as or different from each other,
n represents an integer of 1 to 4,
in a case where there are a plurality of n's, the plurality of n's may be the same as or different from each other,
Rh represents a substituent having two or more groups represented by Formula (S),
in a case where there are a plurality of Rh's, the plurality of Rh's may be the same as or different from each other, 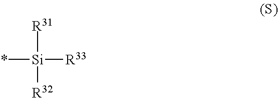
in Formula (S),
* represents a bonding position, and
R³¹, R³², and R³³ each independently represent an alkyl group, an alkenyl group, an aryl group, or an alkylene aryl group, and
in the substituent represented by Rh, a plurality of R³¹'s may be the same as or different from each other, a plurality of R³²'s may be the same or different from each other, and a plurality of R³³'s may be the same as or different from each other.

7. The photo-alignment polymer according to claim 1,
wherein a weight-average molecular weight of the photo-alignment polymer is 10,000 to 500,000.

8. A binder composition comprising:
the photo-alignment polymer according to claim 1; and
a binder.

9. The binder composition according to claim 8,
wherein the binder is a polymerizable liquid crystal compound.

10. A binder layer formed of the binder composition according to claim 8,
wherein a surface of the binder layer has an alignment controllability.

11. An optical laminate comprising:
the binder layer according to claim 10; and
an optically-anisotropic layer disposed on the binder layer.

12. An optical laminate manufacturing method comprising:
a step of subjecting a coating film formed of the binder composition according to claim 8 to a photo-alignment treatment to form a binder layer; and
a step of applying a polymerizable liquid crystal composition containing a polymerizable liquid crystal compound onto the binder layer to form an optically-anisotropic layer.

13. An image display device comprising:
the binder layer according to claim 10.
